(19) United States
(12) Patent Application Publication
(10) Pub. No.: US 2024/0314933 A1
(43) Pub. Date: Sep. 19, 2024

(54) VRM MODULE FOR REDUCING THE RESONANT FREQUENCY OF A POWER INPUT LOOP

(71) Applicant: SHANGHAI METAPWR ELECTRONICS CO., LTD, Shanghai (CN)

(72) Inventors: Mingzhun ZHANG, Shanghai (CN); Yayu LI, Shanghai (CN); Jianhong ZENG, Shanghai (CN)

(73) Assignee: SHANGHAI METAPWR ELECTRONICS CO., LTD, Shanghai (CN)

(21) Appl. No.: 18/608,948

(22) Filed: Mar. 19, 2024

(30) Foreign Application Priority Data
Mar. 19, 2023 (CN) 202310266907.1
Apr. 7, 2023 (CN) 202310375868.9
Oct. 29, 2023 (CN) 202311411290.4
Jan. 28, 2024 (CN) 202410114254.X

(51) Int. Cl. H05K 1/16; H01F 17/00; H01F 27/28; H05K 1/11

(52) U.S. Cl. CPC H05K 1/165; H01F 17/0006; H01F 27/2804; H05K 1/118

(57) ABSTRACT

The VRM module comprises an integrated inductor, a top assembly, a bottom assembly, a vertical plate, a first power electric connecting piece and a second power electric connecting piece, wherein the integrated inductor comprises a magnetic core, a first winding and a second winding; the top assembly comprises a semiconductor switching device; and an electric loop formed by the first power electric connecting piece, the second power electric connecting piece and the semiconductor switching device is arranged around at least a part of the magnetic core.

### CROSS-REFERENCE TO RELATED APPLICATIONS

This application claims the priority benefit of Chinese patent application 202410114254.X filed on Jan. 28, 2024, and Chinese patent application 202310266907.1 filed on Mar. 19, 2023, and Chinese patent application 202310375868.9 filed on Apr. 7, 2023, and Chinese patent application 202311411290.4 filed on Oct. 29, 2023. The entirety of each of the above-mentioned patent applications is hereby incorporated by reference herein and made a part of this specification.

### BACKGROUND

In recent years, with the development of the fields of data centers, artificial intelligence, supercomputers and etc, more and more powerful ASICs are applied, such as CPUs, GPUs, machine learning accelerators, network switches, servers and etc, which need to consume a large amount of current. The current reaches thousands of amps and its requirement jumps rapidly. This load is traditionally supplied using a voltage regulator module (VRM, Voltage Regulator Modules) comprising multiphase buck circuits (Buck).

Along with the progress of the semiconductor technology, the rated voltage of the loads is lower and lower and is now as low as 0.65 V, and the rated current of the load is continuously increased. In the VRM module of the low-voltage large current, how to improve the current efficiency is a key which meets the ASIC requirement and is also the core problem of the VRM module design.

On the other hand, along with the continuous increase of the load current, the heat dissipation problem of the VRM module is also a key problem needing to be considered. At present, in order to share the radiator with the load ASIC and reduce the thermal resistance of the top surface, the switch device serving as a heat source is arranged on the top surface of the VRM module and the filter inductor is arranged below the switch device; the input power current and the control signal need to be transmitted from the mainboard of the bottom surface to the switching device on the top surface of the VRM module, and signals such as current sampling data and temperature sampling in the working state of the switching device need to be transmitted from the top surface of the VRM module to the mainboard.

FIG. 1A shows a circuit diagram of a VRM module in the prior art in which there is a parasitic inductance in a power input loop formed by a power VIN pin, an input capacitor, a power GND pin (and a semiconductor switching device IPM); and if the resonant frequency of the power input loop is close to the equivalent working frequency of the two-phase buck circuit of the VRM module (according to different conditions, the equivalent working frequency is the switching frequency of the IPM or twice of the frequency of the IPM), the amplitude of the resonant current and the resonant voltage generated by the parallel resonance in the power input loop is increased, the normal work of the VRM module is interfered, and the efficiency of the power circuit is reduced.

Therefore, how to reduce the influence of the resonance of the power input loop on the efficiency of the VRM module is an urgent problem to be solved.

### SUMMARY

The application aims to provide the VRM module for reducing the resonant frequency of the power input loop, so that the parasitic inductance of the power input loop is increased, and the magnitude of the input capacitance value can be further increased, so that the parasitic inductance input capacitor forms the equivalent working frequency of the two-phase voltage reduction circuit with the resonance frequency far lower than that of the VRM module, the influence of resonance on the efficiency of the VRM module is eliminated, and the efficiency of the VRM module is greatly improved.

The application further aims to provide a manufacturing method of the VRM module capable of reducing the power input loop and the switch resonance.

In order to achieve the purpose, the application provides a VRM module, comprising: an integrated inductor, a top assembly and a vertical plate;
wherein the integrated inductor comprises a magnetic core, a first winding and a second winding, wherein the integrated inductor is provided with a first side surface, a second side surface, a third side surface and a fourth side surface, and the second side surface and the fourth side surface are adjacent to the third side surface respectively; the vertical plate comprises a signal electrical connector; the vertical plate is arranged on the third side surface of the integrated inductor;
wherein the first winding and the second winding are respectively provided with a first winding bonding pad on the top surface of the integrated inductor, and the first winding and the second winding are respectively provided with a second winding bonding pad on the bottom surface of the integrated inductor; the first winding bonding pad is arranged on the first side surface or close to the first side surface;
wherein the top assembly is arranged on the top surface of the integrated inductor and is electrically connected with the first winding bonding pad, the top assembly comprises a semiconductor switching device, and the first winding bonding pad is vertically corresponding to the connecting end of the corresponding semiconductor switching device;
wherein the VRM module further comprises a first power electric connecting piece and a second power electric connecting piece, the first power electric connecting piece and the second power electric connecting piece form a first connecting piece bonding pad on the top face of the integrated inductor respectively, and the first connecting piece bonding pad is connected with the corresponding semiconductor switching device; the first power electric connecting piece and the second power electric connecting piece form a second connecting piece bonding pad on the bottom face of the integrated inductor respectively, the second connecting piece bonding pad is used for connecting input terminals with different potentials, and the input terminals is a power input terminals;
wherein an electrical loop formed by the first power electric connecting piece, the second power electric connecting piece, and the semiconductor switching device is disposed about at least a portion of the magnetic core.

Optionally, wherein the device further comprises a bottom assembly;
wherein the bottom assembly is arranged on the bottom surface of the integrated inductor and is electrically connected with the second winding bonding pad and the second connecting piece bonding pad, and the bottom assembly is used for being connected with a load; the top assembly is in signal connection with the bottom assembly through a signal electric connecting piece;
wherein the first power electric connecting piece is arranged on the third side surface of the integrated inductor or is close to the third side surface of the magnetic core. The second power electric connecting piece is arranged on the second side surface and the fourth side surface, or the second power electric connecting piece is arranged at the position, close to the second side surface and close to the fourth side surface, of the magnetic core.

Optionally, the first power electric connecting piece is a VIN electric connecting piece, the second power electric connecting piece is a GND electric connecting piece, a cross-sectional area of the GND electric connecting piece is greater than a cross-sectional area of the VIN electric connecting piece, and a common potential pad of a signal electric connecting piece in the vertical panel comprises at least two discontinuous metal surfaces.

Optionally, an input capacitor and an output capacitor are further included, at least a part of the input capacitor is arranged on the top assembly and/or the vertical plate, and at least a part of the output capacitor is arranged on the bottom assembly and/or the vertical plate.

Optionally, at least a part of the output capacitor is arranged on the vertical plate, and the second winding pad is arranged close to the third side surface, or an output capacitor is not arranged on the vertical plate, and the second winding pad is arranged close to the first side surface.

Optionally, the bottom assembly comprises a plurality of copper columns, and the positions of the copper columns correspond to the positions of the second winding bonding pads and the second connection bonding pads respectively.

Optionally, the second winding bonding pad and the second connecting bonding pad protrude out of the bottom surface of the magnetic core, and pads or grooves corresponding to the positions of the second winding bonding pad and the second connecting bonding pad are formed in the bottom assembly.

Optionally, the device further comprises at least one flexible adapter plate, and the top assembly is electrically connected with the vertical plate through at least one flexible adapter plate;
wherein the bottom assembly is electrically connected with the vertical plate through at least one flexible adapter plate,
or, the VRM module further comprises a rigid adapter plate, the rigid adapter plate is electrically connected with the vertical plate through at least one flexible adapter plate, the rigid adapter plate is arranged between the magnetic core and the bottom assembly, and the rigid adapter plate is electrically connected with the bottom assembly.

Optionally, the second winding bonding pad is arranged on the first side surface or close to the first side surface, or the second winding bonding pad is arranged on the third side surface or close to the third side surface.

Optionally, the first winding bonding pad is arranged close to the first side surface, and the second winding bonding pad is arranged close to the first side surface so that any part of the first winding and the second winding is surrounded by the magnetic core; and the first winding bonding pad is arranged close to the first side surface, and the second winding bonding pad is arranged close to the third side surface, so that any part of the first winding and the second winding is surrounded by the magnetic core.

Optionally, the first power electric connecting piece is arranged at the position, close to the third side surface, of the magnetic core, that is, the first power electric connecting piece is arranged in the magnetic core and close to the third side surface.

Optionally, the first power electric connecting piece and the second power electric connecting piece are both rectangular copper sheets.

Optionally, the tail ends of the first connecting bonding pad and the second connecting bonding pad are arc-shaped.

Optionally, at least two bosses are arranged on the third side surface of the magnetic core, grooves are formed between the bosses, and the vertical plate and the magnetic core are assembled together through the bosses.

Optionally, the boss of the magnetic core is provided with a chamfer, a groove or an avoidance groove, and the groove and the avoidance groove are used for avoiding the side surface pad of the vertical plate.

Optionally, a solder resist interval is formed between the signal electric connecting pieces of the vertical plate by means of a PCB substrate, and the height of the PCB substrate is lower than the height of the signal electric connecting piece.

Optionally, the integrated inductor further comprises a first auxiliary winding and a second auxiliary winding, wherein the first winding and the first auxiliary winding are coupled to each other, and the second winding and the second auxiliary winding 224 are coupled to each other to implement a TLVR function.

Optionally, the magnetic core comprises at least two magnetic materials with different relative magnetic permeability, and the relative permeability of the magnetic material arranged in the first magnetic area is lower than that of other areas, wherein the first magnetic area is an area horizontally surrounding the first power electric connecting piece.

Optionally, the magnetic core comprises a magnetic core main body and a sheet-shaped magnetic core, the sheet-shaped magnetic core is arranged on the third side surface of the magnetic core main body, and one side wall of the first power electric connecting piece is exposed to the third side surface of the magnetic core main body.

Optionally, an air gap is formed between the sheet-shaped magnetic core and the magnetic core main body, and the air gap is used for adjusting the inductance of the first power electric connecting piece in the magnetic core by adjusting the size of the air gap.

Optionally, there are at least two first power electric connecting pieces, and the first power electric connecting pieces are connected in parallel.

Optionally, the ends at the same position between the first power electric connecting pieces are short-circuited together.

Optionally, there are two first power electric connecting pieces, which are respectively arranged close to the second side surface and the fourth side surface; and the second power electric connecting piece is also arranged in the magnetic core and close to the second side surface and the fourth side surface respectively.

Optionally, the vertical plate is only provided with a signal electric connecting piece, and the signal electric connecting piece is arranged on the third side surface by electroplating.

Optionally, the first end face and the second end face of the vertical plate are provided with signal pins, the first end face is used for being connected with the top assembly, the second end face is used for being connected with the bottom assembly, signal pins on the two end faces are connected through wiring in the vertical plate, and signal pins located on the first end face and the second end face extend to the side surface of the vertical plate from the end face to which the signal pins belong.

Optionally, the first end face and the second end face of the vertical plate further comprise a plurality of inner concave faces, and the inner concave faces are located between the signal pin specific electrodes and used for isolating adjacent signal pins and providing a good exhaust channel in the reflow soldering process.

Optionally, the vertical plate only comprises a signal electric connecting piece and an insulating layer, the insulating layer is arranged on the outer side of the first power electric connecting piece, and the signal electric connecting piece is arranged on the outer side of the insulating layer in an electroplating mode; and the first power electric connecting piece serves as a static potential connecting point.

Optionally, the integrated inductor is completely embedded in the PCB, and the first power electric connecting piece realizes the transmission between the top assembly and the bottom assembly by means of providing a through hole on the PCB; and the signal electric connecting piece implements signal transmission by means of a through hole.

Optionally, the signal electric connecting piece implements signal transmission by means of forming a through hole in the PCB, electroplating a metal shielding layer in the through hole, then providing an insulating layer on the surface of the metal shielding layer, and then electroplating a signal electric connecting piece on the surface of the insulating layer, wherein the metal shielding layer is connected to the static potential connecting point.

The application further provides a manufacturing method of the VRM module, the VRM module further comprises an input capacitor and an output capacitor;
wherein the first power electric connecting piece is arranged on the third side surface of the integrated inductor or arranged at the position, close to the third side surface, of the magnetic core, specifically, the first power electric connecting piece is arranged on the third side surface of the integrated inductor or arranged in the magnetic core or close to the third side surface;
wherein the manufacturing method comprises the following steps,
S1: preparing the integrated inductor, wherein the integrated inductor is integrally formed by a magnetic core, a first winding, a second winding, a first power electric connecting piece and a second power electric connecting piece;
The vertical plate is prepared, a signal electric connecting piece and a metal shielding layer are arranged on the vertical plate, a part of an input capacitor and/or an output capacitor are attached to the vertical plate, and the vertical plate is formed by depositing an upper passivation layer after copper foil is exposed through a PCB edge milling process;
S2: fixedly connecting the vertical plate and the integrated inductor through gluing, enabling at least one part of the metal shielding layer to be located between the signal electric connecting piece and the magnetic core, and controlling the flatness tolerance of the bonding pad assembled by the vertical plate and the integrated inductor to be within 50 μm;
S3: preparing a third PCB provided with at least part of an output capacitor, carrying out adhesive dispensing on the third PCB, welding an integrated inductor connected with a vertical plate obtained in the step S2 through reflow soldering, and fixing the integrated inductor on a third PCB in an adhesive manner;
   S4: de-paneling the third PCB into an integrated inductor connected with a vertical plate and a bottom assembly;
S5: preparing a second PCB board, and welding the semiconductor switch component and at least a part of the input capacitor to the top surface pad of the second PCB board;
S6: dispensing glue on the bottom surface of the second PCB, welding the integrated inductor connected with the vertical plate and the bottom assembly obtained in the step S4 through reflow soldering, and fixing the integrated inductor on the bottom surface of the second PCB in an adhesive manner;
S7: de-panaling the second PCB to obtain the VRM module.

The application further provides a manufacturing method of the VRM module,
wherein the VRM module further comprises an input capacitor, an output capacitor and a rigid adapter plate, the rigid adapter plate is electrically connected with the vertical plate through the at least one flexible adapter plate, the rigid adapter plate is arranged between the magnetic core and the bottom assembly, and the rigid adapter plate is electrically connected with the bottom assembly,
wherein the manufacturing method comprises the following steps:
S1: preparing a rigid-flexible combined plate, wherein the rigid-flexible combined plate comprises a second PCB, a first PCB, a rigid adapter plate and a flexible adapter plate, and the first PCB is provided with a signal electric connecting piece and a metal shielding layer;
The integrated inductor is prepared, and an accommodating space for accommodating a rigid adapter plate is formed in the bottom of the integrated inductor;
S2: mounting a semiconductor switching device and an input capacitor on the top surface of the rigid-flexible bonding plate;
S3: an integrated inductor is attached to the bottom surface of the rigid-flexible combined plate, and an input capacitor and/or an output capacitor are attached to the bottom surface of the rigid-flexible combined plate;
S4: de-paneling the first PCB and the second PCB to obtain an integrated inductor connected with the top assembly;
S5: bending the rigid-flexible combined assembly to enable the vertical plate to be attached to a third side surface of the integrated inductor and enable the rigid adapter plate to be limited in the containing space;
S6: preparing a third PCB provided with an output capacitor, and welding an integrated inductor to a third PCB;
S7: de-paneling the third PCB to obtain the VRM module.

The application further provides a manufacturing method of the VRM module, wherein the VRM module further comprises an input capacitor, an output capacitor and a rigid adapter plate, the rigid adapter plate is electrically connected with the vertical plate through the at least one flexible adapter plate, the rigid adapter plate is arranged between the magnetic core and the bottom assembly, and the rigid adapter plate is electrically connected with the bottom assembly,
wherein the manufacturing method comprises the following steps:
S1: preparing a rigid-flexible combined plate, wherein the rigid-flexible combined plate comprises a second PCB, a first PCB, a rigid adapter plate and a flexible adapter plate, and the first PCB is provided with a signal electric connecting piece and a metal shielding layer;
The integrated inductor is prepared, and an accommodating space for accommodating a rigid adapter plate is formed in the bottom of the integrated inductor;
S2: mounting a semiconductor switch device and an input capacitor on the top surface of the rigid-flexible combination plate, and welding a bottom assembly on the rigid adapter plate;
S3: mounting an integrated inductor on the bottom surface of the rigid-flexible combined plate, and mounting an input capacitor and/or an output capacitor on the bottom surface of the rigid-flexible combined plate;
S4: de-paneling the first PCB and the second PCB to obtain an integrated inductor connected with the top assembly;
S5: arranging solder at the bottom of the bottom assembly or the integrated inductor, bending the rigid-flexible combined assembly to enable the vertical plate to be attached to the third side surface of the integrated inductor, limiting the rigid adapter plate in the accommodating space, and completing welding.

### DESCRIPTION OF DRAWINGS

FIG. 1A is a schematic circuit diagram of a VRM module in the prior art;

FIG. 1B is a schematic diagram of pin layout of an IPM unit in the prior art;

FIG. 2A to FIG. 2L are schematic diagrams of Embodiment 1 of the present application;

FIG. 3A to FIG. 3C are schematic diagrams of Embodiment 2 of the present application;

FIG. 4A to FIG. 4C are schematic diagrams of Embodiment 3 of the present application;

FIG. 5A to FIG. 5J are schematic diagrams of Embodiment 4 of the present application;

FIG. 6A to FIG. 6K are schematic diagrams of Embodiment 5 of the present application;

FIG. 7A to FIG. 7H are schematic diagrams of Embodiment 6 of the present application;

FIG. 8A to FIG. 8H are schematic diagrams of Embodiment 7 of the present application;

FIG. 9A to FIG. 9K are schematic diagrams of Embodiment 8 of the present application;

FIG. 10A to FIG. 11F are schematic diagrams of Embodiment 9 of the present application;

FIG. 12 to FIG. 16 are schematic diagrams of Embodiment 10 of the present application;

FIG. 17A to FIG. 17B are schematic diagrams of an eleventh embodiment of the present application;

FIG. 18A to FIG. 18D are schematic diagrams of a twelfth embodiment of the present application;

FIG. 19A to FIG. 20D are schematic diagrams of a thirteenth embodiment of the present application;

FIG. 21A to FIG. 21B are schematic diagrams of Embodiment Fourteenth of the present application;

FIG. 22A to FIG. 23D are schematic diagrams of a fifteenth embodiment of the present application;

FIG. 24 to FIG. 25E are schematic diagrams of a sixteenth embodiment of the present application;

FIG. 26A to FIG. 26B are schematic diagrams of a seventeenth embodiment of the present application;

FIG. 27A to FIG. 27E are schematic diagrams of an eighteenth embodiment of the present application;

FIG. 28A to FIG. 28B are schematic diagrams of a nineteenth embodiment of the present application;

FIG. 29A to FIG. 29B are schematic diagrams of a twentieth embodiment of the present application.

### DETAILED DESCRIPTION

The present application discloses various embodiments or examples of implementing the thematic technological schemes mentioned. To simplify the disclosure, specific instances of each element and arrangement are described below. However, these are merely examples and do not limit the scope of protection of this application. For instance, a first feature recorded subsequently in the specification formed above or on top of a second feature may include an embodiment where the first and second features are formed through direct contact, or it may include an embodiment where additional features are formed between the first and second features, allowing the first and second features not to be directly connected. Additionally, these disclosures may repeat reference numerals and/or letters in different examples. This repetition is for brevity and clarity and does not imply a relationship between the discussed embodiments and/or structures. Furthermore, when a first element is described as being connected or combined with a second element, this includes embodiments where the first and second elements are directly connected or combined with each other, as well as embodiments where one or more intervening elements are introduced to indirectly connect or combine the first and second elements.

One of the cores of the application is to provide the VRM module for reducing the resonant frequency of the power input loop, so that the parasitic inductance of the power input loop is increased. The input capacitance can be further increased. The resonance frequency formed by the parasitic inductance and the input capacitance is far lower than the equivalent working frequency of the VRM module. The influence of resonance on the efficiency of the VRM module is eliminated, and the efficiency of the VRM module is greatly improved.

The application further provides a manufacturing method of the VRM module capable of reducing the power input loop and the resonance.

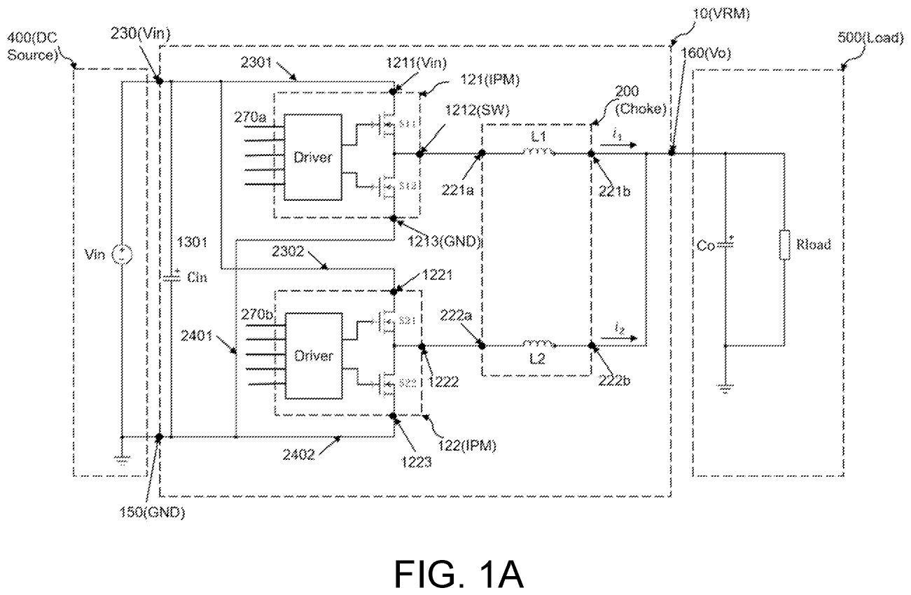

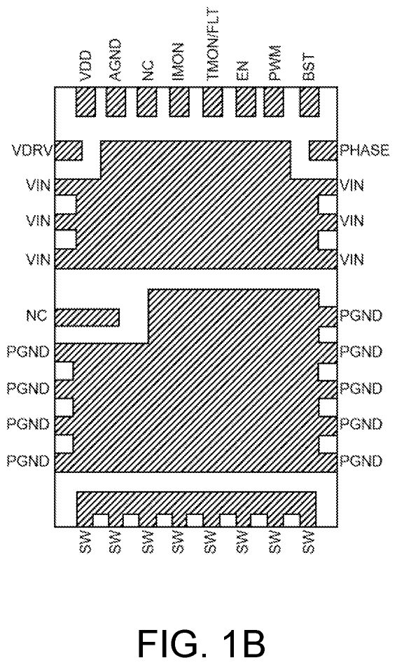

As shown in FIG. 1A, a complete two-phase VRM module 10 in the prior art comprises an IPM unit 121, an IPM unit 122, an intermediate assembly 200 (the windings can be coupled or not coupled), a VIN electrical connector 2301 and a VIN electric connecting piece 2302, a GND electric connecting piece 2401, a GND electric connecting piece 2402, an input capacitor 1301, a signal electric connecting piece 270a and a signal electric connecting piece 270b, wherein each of the IPM units 121/122 comprises two semiconductor switch devices which are respectively a high-end MOSFET and a low-end MOSFET. The two MOSFETs are connected in series to form a bridge arm. One end of the bridge arm is connected with the positive end of the input power supply, namely the input voltage terminal VIN 230, the other end of the bridge arm is connected with the ground end. That is, the grounding end GND 150. The midpoint of the bridge arm of the IPM unit 121/122 is the SW end 1212/1222 which is connected with the input terminal of the corresponding inductors. The output terminal of the inductors is connected with the load after being connected in parallel or not in parallel to provide energy for the load. The input capacitor is used for bypassing the ripple current of the high-frequency and ensuring the stability of the input voltage. The signal electric connecting piece 270a/270b is used for transmission of signals such as driving and control of the IPM unit 121/122.

FIG. 1B is a schematic diagram of pins of a standard package of the IPM unit 121/122 in FIG. 1A. The SW end is arranged at one end of the IPM unit. The connecting end of the control signal is arranged at the other end opposite to the SW end. The connecting ends of the VIN electric connecting piece and the GND electric connecting piece are sequentially arranged in the middle.

### Embodiment 1

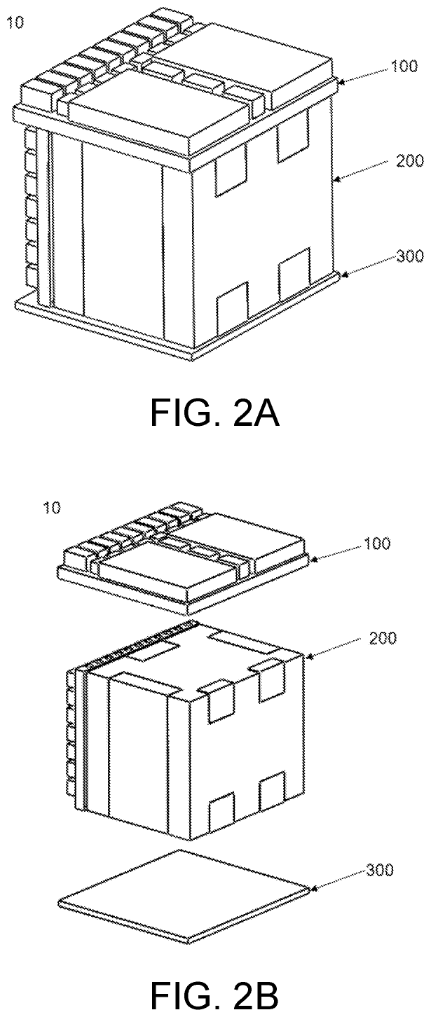

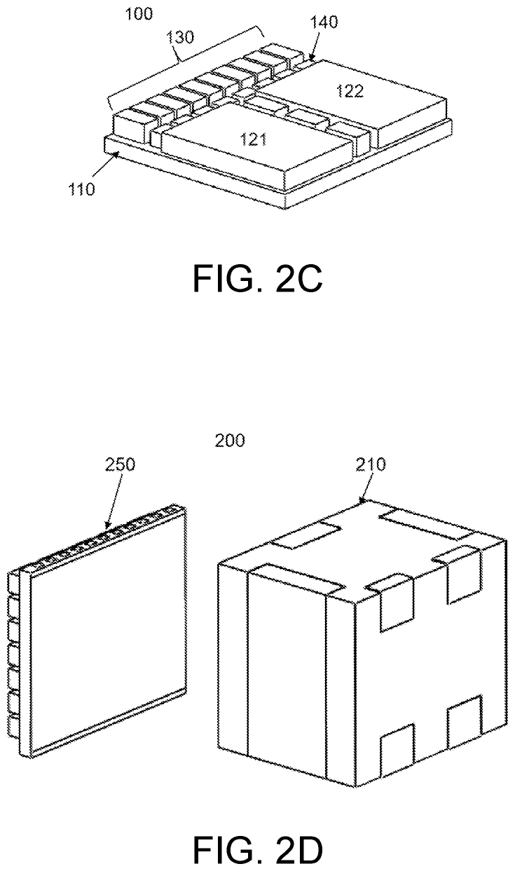

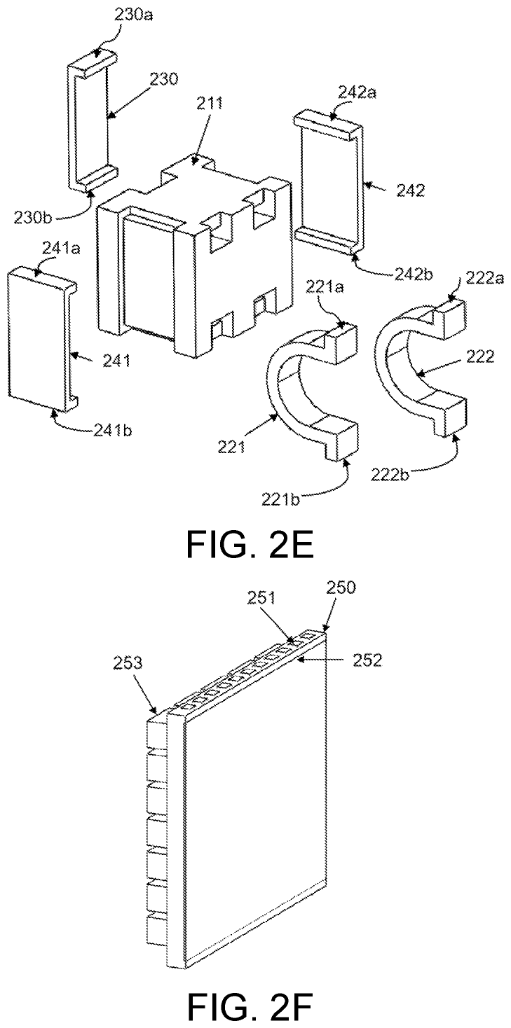

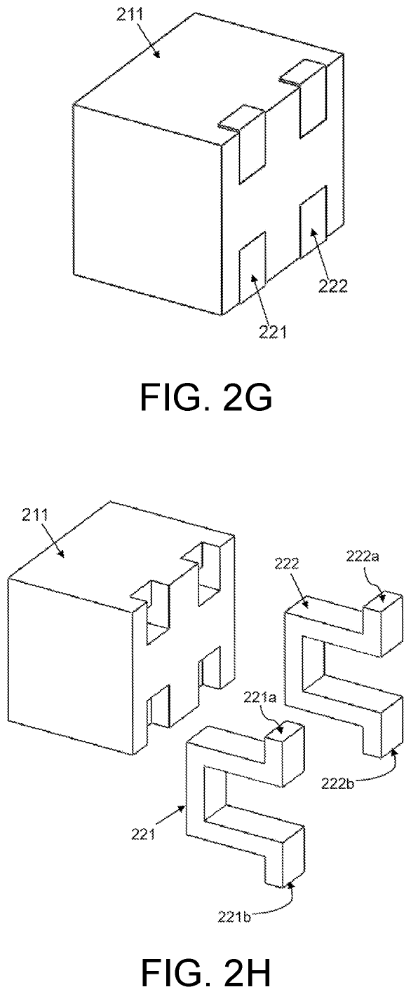

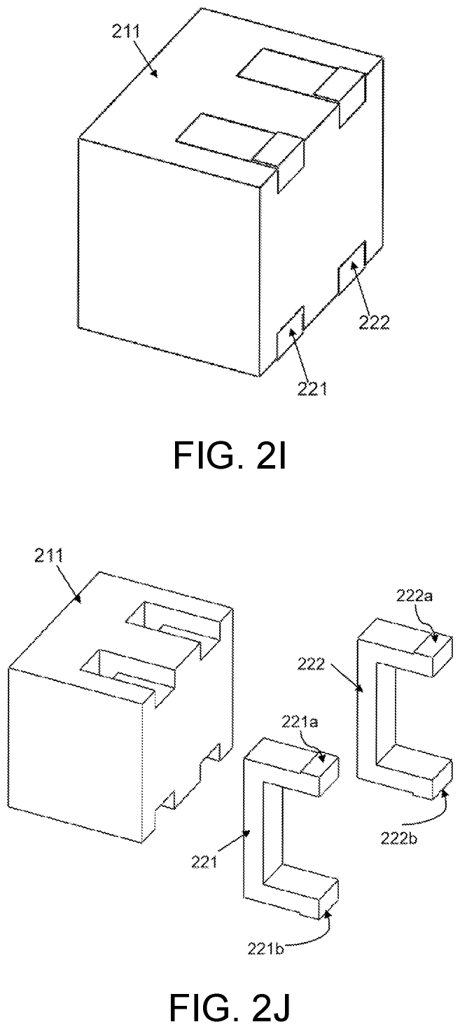

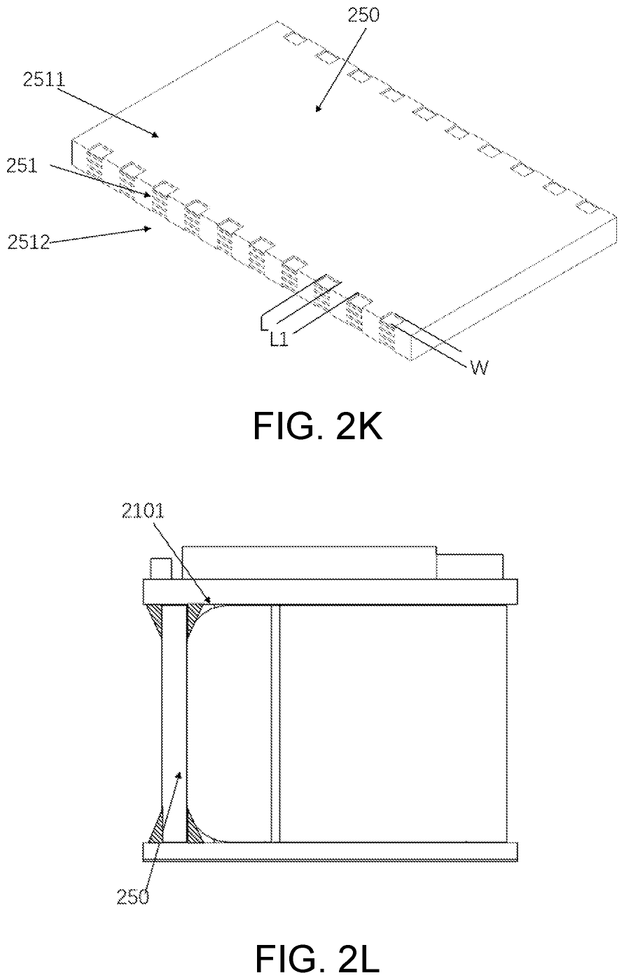

FIG. 2A is a schematic structural diagram of a two-phase VRM module 10. FIG. 2B is an exploded view of FIG. 2A. FIG. 2C is a schematic structural diagram of a top assembly 100. FIG. 2D is a structural exploded view of the intermediate assembly 200. FIG. 2E is a structural exploded view of the two-phase integrated inductor 210. FIG. 2F is a structural diagram of a vertical plate 250. As shown in FIGS. 2A and 2B, the two-phase VRM module 10 comprises a top assembly 100, an intermediate assembly 200 and a bottom assembly 300. The top assembly 100 comprises a first plate 110, an IPM unit 121, an IPM unit 122, a plurality of input capacitors 130 and other passive elements 140. The IPM unit 121/122 is placed close to the edge of the first plate 110 due to the connection point SW between the high-end MOSFET and the low-end MOSFET is arranged on the edge on the IPM unit 121/122. The IPM unit 121/122 is arranged on the edge of the first plate 110, so that the input end of the inductor is directly connected with the SW end of the IPM unit 121/122. The efficiency loss caused by transverse current is reduced. The other passive element 140 is mainly a passive element of a control signal loop in the IPM unit 121/122. The control signal of the IPM unit 121/122 is arranged at the other end opposite to the SW end. Since the passive element needs to be close to the IPM unit 121/122, good filtering and other effects can be achieved, so that the passive element is arranged close to the IPM unit 121/122. One part of the input capacitor 130 is arranged at the edge of the other end of the first plate 110 and is close to other passive elements 140. Part of the input capacitor 130 is arranged between the two IPM units 121/122. Due to the input capacitor 130 is also arranged close to the VIN input end of the IPM unit 121/122, the shorter path between the input capacitor and the VIN input end, the better the filtering effect is. The VIN input end on the IPM unit 121/122 is arranged on the side and close to the control signal.

As shown in FIG. 2D to FIG. 2F, the intermediate assembly 200 comprises a first power electric connecting piece 230, a second power electric connecting piece 241, a second power electric connecting piece 242, a two-phase integrated inductor 210, and a vertical plate 250.

The first power electric connecting piece is a VIN electric connecting piece 230 (functioning as a corresponding VIN electric connecting piece 2301/2302 in FIG. 1). The second power electric connecting piece is a GND electric connecting piece 241/242 (functioning as a GND electric connecting piece 2401/2402 in FIG. 1). The VIN electric connecting piece 230 is provided with a first pad 230a on the top surface of the intermediate assembly 200. A second pad 230b is provided on the bottom surface of the intermediate assembly 200. The GND electric connecting piece 241/242 is provided with a first pad 241a/242a on the top surface of the intermediate assembly 200. A second pad 241b/242b is provided on the bottom surface of the intermediate assembly 200.

A parasitic inductance exists in the power input loop formed by the VIN electric connecting piece 230, the input capacitor 130, and the GND electric connecting piece 241/242. If the resonant frequency of the power input loop is close to the equivalent working frequency of the two-phase VRM module 10 (if the PWM phases of the IPM unit 121 and 122 are the same, the equivalent working frequency of the two-phase buck circuit is equal to the switching frequency of one IPM unit; if the PWM phases of the IPM unit 121 and 122 shift by 180 degrees, the equivalent working frequency is equal to twice the switching frequency of the IPM unit). The amplitude of the resonant current and the resonant voltage generated by the resonance is increased. The normal work of the VRM module is interfered. The efficiency of the power circuit is reduced. Due to the fact that the resonant frequency of the power input loop is directly proportional to the negative binary of the parasitic inductance and the negative binary of the equivalent capacitance value of the capacitor, the increasing of the parasitic inductance and the increasing of the equivalent capacitance can reduce the resonant frequency of the power input loop. The resonant frequency is far lower than the equivalent working frequency of the two-phase buck circuit, so that the influence of resonance on the efficiency of the VRM can be avoid.

As shown in FIG. 2E, in the embodiment, the VIN electric connecting piece 230 and the GND electric connecting piece 241/242 are arranged on different side surfaces of the inductor. By using the corner portion of the magnetic core 211, the parasitic inductance of the power input loop is increased, so that the resonant frequency made by the parasitic inductance and the input capacitor 130 is far lower than the equivalent working frequency of the two-phase VRM module 10. The influence of resonance on the efficiency of the two-phase VRM module 10 is eliminated. The efficiency of the two-phase VRM module 10 is greatly improved.

In the embodiment, the VIN electric connecting piece 230 and the GND electric connecting piece 241/242 are sintered together with the magnetic core 211 through the metal sheet. In other embodiments, the metal copper sheet and the magnetic core 211 can also be assembled together. In some embodiments, the power pins (ie, the VIN electric connecting piece 230 and the GND electric connecting piece 241/242) may also be implemented by multiple vertical PCBs. In some embodiments, the PCB may also be a flexible PCB having a certain bending capability.

The two-phase integrated inductor 210 comprises a magnetic core 211, a first winding 221 and a second winding 222. The two ends of the first winding 221 and the second winding 222 are both provided on the surface without the power pins of the magnetic core 211, that is, the first side surface of the magnetic core 211. When assembling the top assembly 100, the first side surface corresponds to the edge of the IPM unit 121/122 on the first plate. The part between the two ends of each of the first winding 221 and the second winding 222 is arc-shaped or racetrack-shaped. The arc-shaped structure can achieve a small direct current impedance, which helps to reduce the direct current loss and improve the efficiency under heavy load. The first winding 221 is provided with a first pad 221a on the top surface of the magnetic core 211, being used for connecting the SW pad of the IPM unit 121 of the top assembly 100. The first winding 221 is provided with a second pad 221b on the bottom surface of the magnetic core 211, being used for connecting Vo+ Pad on the bottom assembly 300 to supply power to the load. The second winding 222 is provided with a first pad 222a on the top surface of the magnetic core 211, being used for connecting the SW Pad of the IPM unit 122 of the top assembly 100. The second winding is provided with a second pad 222b on the bottom surface of the magnetic core, being used for connecting Vo+ Pad on the bottom assembly 300 to supply power to the load. The advantages of this structure are that the first pad 221a/222a of the winding is vertically connected with the SW pad of the IPM unit 121/122, without transverse current flows. The second pad 221b/222b of the winding is vertically connected with Vo+ pad on the bottom assembly 300 without transverse current flow either. The path at the joint is shorter, the direct-current conduction loss is lower, and the efficiency of the two-phase VRM module 10 is further improved.

As shown in FIG. 2F, the vertical plate 250 comprises a signal electric connecting piece 251, a metal shielding layer 252 and a capacitor 253, wherein the signal electric connecting piece 251 is used for signal transmission between the top assembly and the bottom assembly. A certain facing area is formed between the signal electric connecting piece 251 and the first winding 221 or the second winding 222 of the inductor, so that a parasitic capacitor with a certain capacitance exists between the signal electric connecting piece 251 and the winding (although the magnetic core 211 is arranged in the middle, the magnetic core material is usually a ceramic with a dielectric constant. Therefore a certain parasitic capacitance exists). Because of the switching frequency is high, the voltage change rate on the winding is large. The rapidly changing voltage on the winding is coupled to the signal electric connecting piece 251 through the parasitic capacitor, so that electric field interference exists in the signal electric connecting piece 251. On the other hand, the rapidly changing voltage can also generate magnetic field interference through the magnetic core 211. The metal shielding layer 252 is arranged on the vertical plate 250. The metal shielding layer 252 is arranged between the signal electric connecting piece 251 and the magnetic core 211 and is electrically connected with the GND electric connecting piece 241/242 through the top assembly 100 or the bottom assembly 300, so that the electromagnetic interference is shielded. Ensuring that the signal electric connecting piece 251 is not subjected to electromagnetic interference, and reliable work of the IPM unit 121/122 is ensured. Details should be noted that the structural shape of the metal shielding layer 252 and the grounding form of the metal shielding layer 252 are not shown, but the technical features of the present embodiment are not affected. In some other embodiments, if only considering shielding magnetic field interference, the metal shielding layer 252 may not be grounded. The capacitor 253 may be an input capacitor. In other embodiments, the capacitor 253 may also be an output capacitor, or the vertical plate 250 is arranged with both an input capacitor and an output capacitor. In the embodiment, as shown in FIG. 2F, only one side of the vertical plate 250 is provided with the capacitor 253. In some other embodiments, to further increase the capacity of the input capacitor and reduce the parasitic inductance and the resonant frequency of the input capacitance, the capacitor 253 can be arranged on both the front surface and the back surface of the vertical plate 250. The equivalent series resistance of the input capacitor is reduced, and the efficiency is further improved. The vertical plate 250 is welded to the top assembly 100 and the bottom assembly 300 by means of upper and lower traces of the side wall. The details of the side wall wiring are not shown, but the technical features of the embodiment are not affected.

In some other embodiments, as shown in FIG. 2G and FIG. 2H, FIG. 2G shows another structure of the two-phase integrated inductor 210, and FIG. 2H is a structural exploded view of the two-phase integrated inductor 210 in FIG. 2G. Comparing with the two-phase integrated inductor 210 of FIG. 2E, the shape of the parts between the two ends of the first winding 221 and the two ends of the second winding 222 are different. The part between the two ends of the first winding 221 and the two ends of the second winding 222 shown in FIG. 2H is rectangular. The whole winding is in a “n” shape. A rectangular winding is easy to manufacture, and a magnetic core can be fully utilized to obtain a larger inductance. In addition, the two-phase integrated inductor 210 of the rectangular winding is easy to position in the integral forming and pressing process, and production and manufacturing of the two-phase integrated inductor 210 are facilitated. In some other embodiments, as shown in FIG. 2I and FIG. 2J, FIG. 2I shows another structure of the two-phase integrated inductor 210, and FIG. 2J shows a structural exploded view of the two-phase integrated inductor 210 in FIG. 2I. The whole winding in FIG. 2J is presented as a “C” shape. The winding of the “C” shape is easier to manufacture, and the beneficial effect thereof is the same as that of the “n”-shaped windings. The details are not described herein again.

As shown in FIG. 2K, the vertical plate 250 comprises a signal electric connecting piece 251 and a metal shielding layer 252 (integrated into the vertical plate 250, covered by an insulating layer, and thus not shown in the figure). The vertical plate 250 further comprises at least two metal wiring layers, a part of which is used for forming a signal electric connecting piece 251. The other part is used for forming a metal shielding layer 252 (ie, grounding). In some preferred embodiments, the signal electric connecting piece 251 can be electrically connected to at least a part of the metal shielding layer 252 through a via hole. In the present embodiment, preferably, the vertical plate 250 comprises four metal wiring layers. The four metal wiring layers extend to the board edge and are exposed to form a signal electric connecting piece 251. The signal electric connecting piece 251 located on the outermost layer which extends to the first side surface 2511 and the second side surface 2512 of the vertical plate, reserving a tin-climbing space for the welding procedure, to improve the product welding reliability. FIG. 2L shows the formed welding form. In order to achieve the welding form shown in FIG. 2L, the corner position corresponding to the inductor needs to be avoided. The inductor corner is made into a chamfer or an arc structure 2101. Preferably, the boss can be additionally arranged on the third side surface of the magnetic core, ensuring that a tin-climbing space is reserved between the vertical plate and the magnetic core. The width dimension W of the bonding pad corresponding to the first side surface 2511 and the second side surface 2512 is at least 0.1 mm. The preferred size is W=0.3+/−0.05 mm. The length dimension L of the bonding pad is at least 0.25 mm. The distance L1 of the bonding pad is at least 0.25 mm, ensuring that the short-circuited will not occur in the welding process.

### Embodiment 2

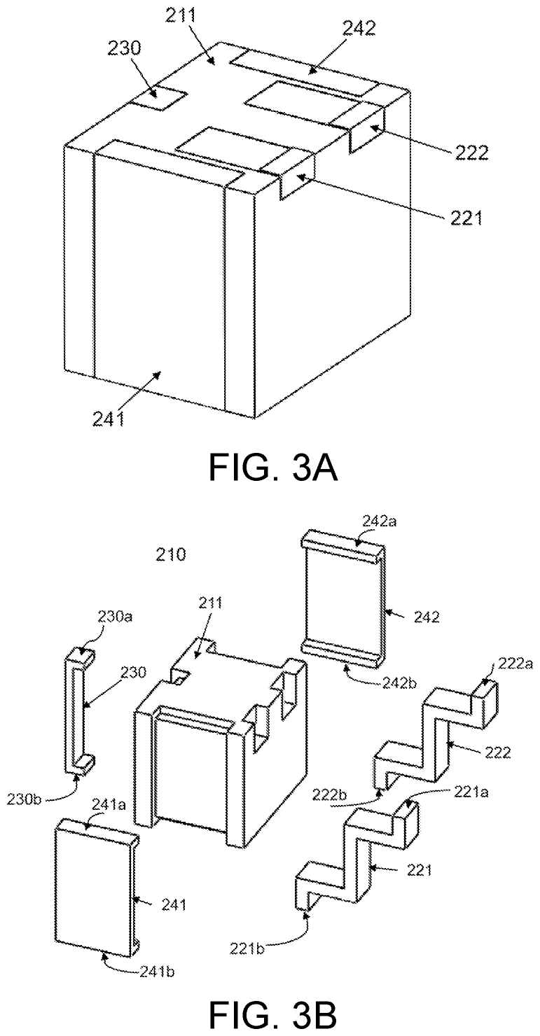

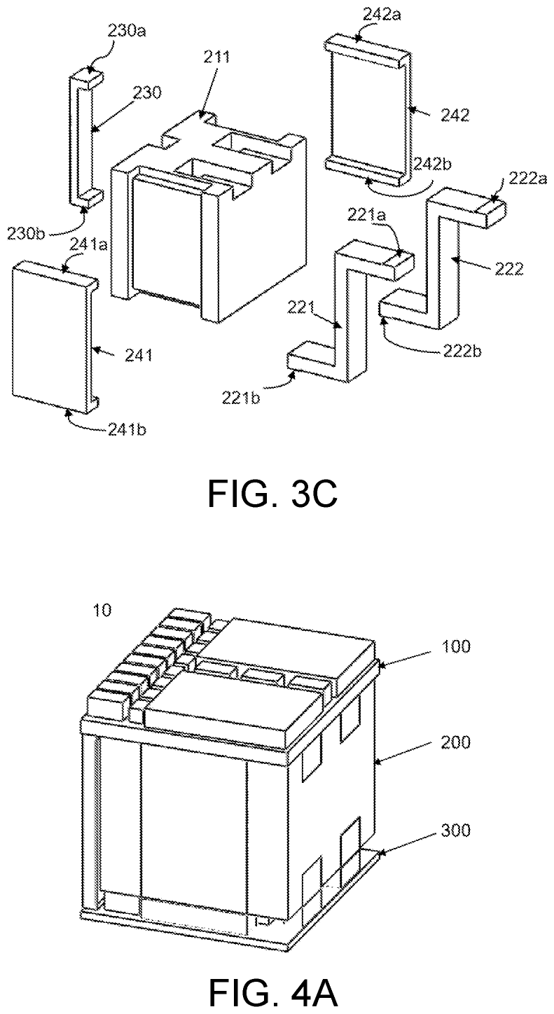

FIG. 3A shows the structural diagram of the intermediate assembly 200 according to the present embodiment. FIG. 3B shows the structural exploded view of the intermediate assembly 200. The structure of the intermediate assembly 200 of the present embodiment and the first embodiment is different. As shown in FIGS. 3A and 3B, the intermediate assembly 200 comprises a first power electric connecting piece 230, a second power electric connecting piece 241, a second power electric connecting piece 242, a two-phase integrated inductor 210 and a vertical plate 250. The two-phase integrated inductor 210 comprises a magnetic core 211, a first winding 221 and a second winding 222. Two ends of the first winding 221 and the second winding 222 are respectively arranged at a first side surface and a third side surface close to the magnetic core. The first side surface and the third side surface are oppositely arranged. A step shape is arranged between the two ends of the two windings, and the whole winding is in a step shape; (in some other embodiments, the two ends of the two windings can also be arranged in a linear mode, so that the whole winding is presented as a “Z” shape, as shown in FIG. 3C). The second pad 221b/222b of the winding is different from the second pad 221b/222b of the winding in the first embodiment, and the second pad 221b/222b in the embodiment is close to the third side surface of the magnetic core 211. That is, the second pad 221b/222b is close to the vertical plate 250, so that the output end of the winding can be adjacent to the output capacitor to reduce the loss when the output capacitor is arranged on the vertical plate 250. And the output capacitor approaches closer to the load, the better performance can be achieved.

### Embodiment 3

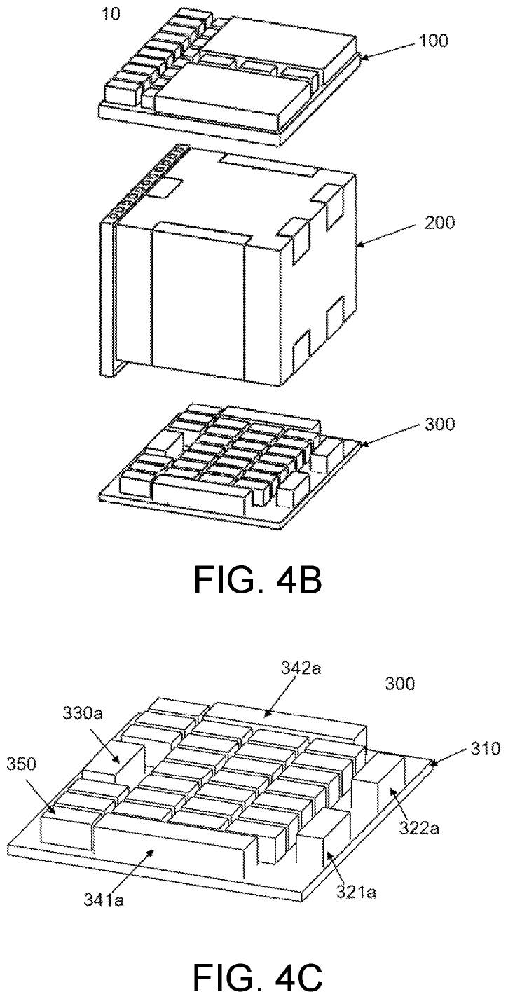

FIG. 4A shows the schematic structural diagram of a two-phase VRM module 10 according to an embodiment. FIG. 4B is an exploded view of FIG. 4A. And FIG. 4C shows the schematic structural diagram of a bottom assembly 300. The difference between the present embodiment and the first embodiment is that the structures of the vertical plate 250 and the bottom assembly 300 in the present embodiment.

The vertical plate 250 in the embodiment is only used for signal transmission. The technical effect of interference shielding is the same as that of the first embodiment. the input capacitor is not arranged in the embodiment. The vertical plate 250 has a larger space to further improve the anti-interference capability of the signal electric connector 251. And a better anti-interference effect is achieved. And of course, the vertical plate 250 in the embodiment can also adopt the way in the first embodiment that arranged the vertical plate with the input capacitor, and the technical effect is the same as that of the first embodiment.

As shown in FIG. 4C, the bottom assembly 300 in the embodiment increases the arrangement of the capacitor 350. The capacitor 350 can be connected in parallel with the output ends of VRM module. The dynamic performance of the output voltage of the two-phase VRM module 10 is improved. The capacitor 350 on the bottom assembly 300 can also be connected in parallel with the input ends of VRM module, so that the ripple of the input current is reduced, and the efficiency of the two-phase VRM module 10 is improved. Or the capacitor 353 on the bottom assembly 300 is partially used for being connected in parallel with the input, and some parts are connected with the output in parallel. The performance of the two-phase VRM module 10 is integrally improved.

As shown in FIG. 4C, a copper column 321a, a copper column 322a, a copper column 330a, a copper column 341a and a copper column 342a are further arranged on the bottom assembly 300 in the embodiment. The copper column 321a is used for being connected with a second bonding pad 221b of the first winding 221 and connecting a Vo+ Pad. The copper column 322a is used for being connected with a second bonding pad 222b of the second winding 222 and connecting a Vo+ Pad; The copper column 330a is used for connecting the second pad 230b of the first power electric connecting piece 230 and connecting the bottom assembly 300. The copper columns 341a/342a are used for connecting the second pads 241b/242b of the second power electric connecting piece and connecting the bottom assembly 300. In the embodiment, the total height of the vertical plate 250 is equal to the height of the Inductor 211 and the largest height of the copper columns 321a/322a/341a/342a, so that the top of the vertical plate 250 is flush with the top of the inductor 211. The bonding pad at the top of the vertical plate 250 and the bonding pad on the top assembly 100 are welded together. The bottom of the vertical plate 250 is flush with the bottom of the copper column 321a/322a/341a/342a. The bottom of the vertical plate 250 and the bonding pad on the bottom assembly 300 are welded together.

The structure of the two-phase integrated inductor 210 in the embodiment is the same as that of the embodiment, and details are not described herein again.

### Embodiment 4

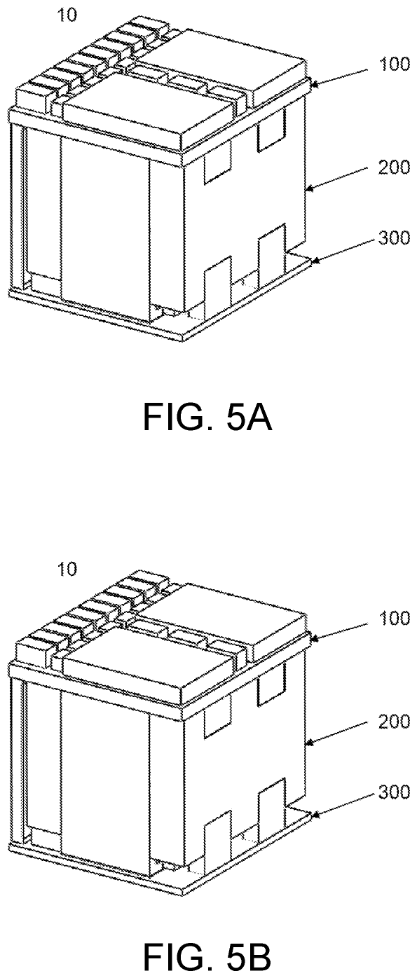

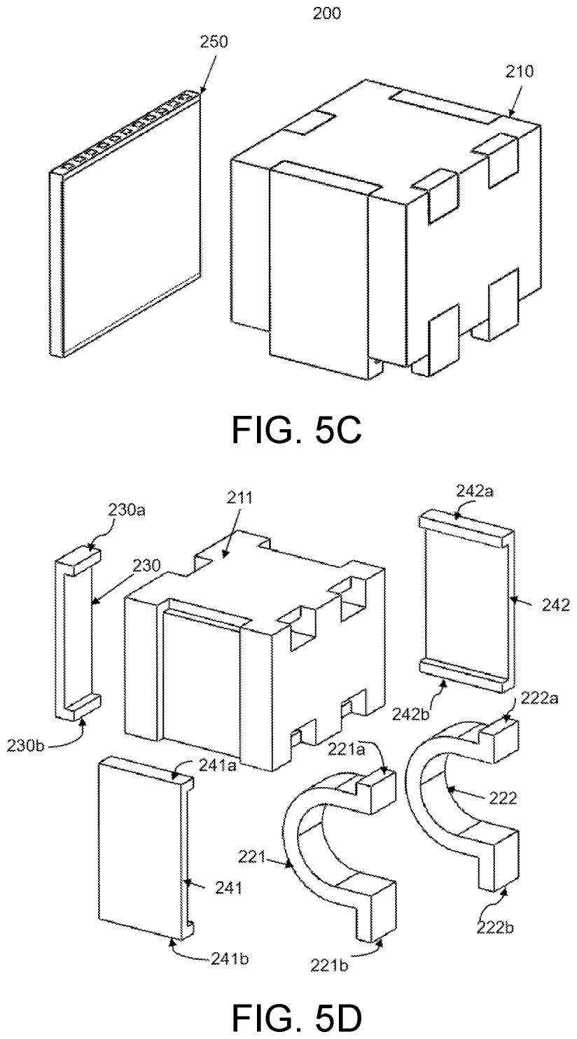

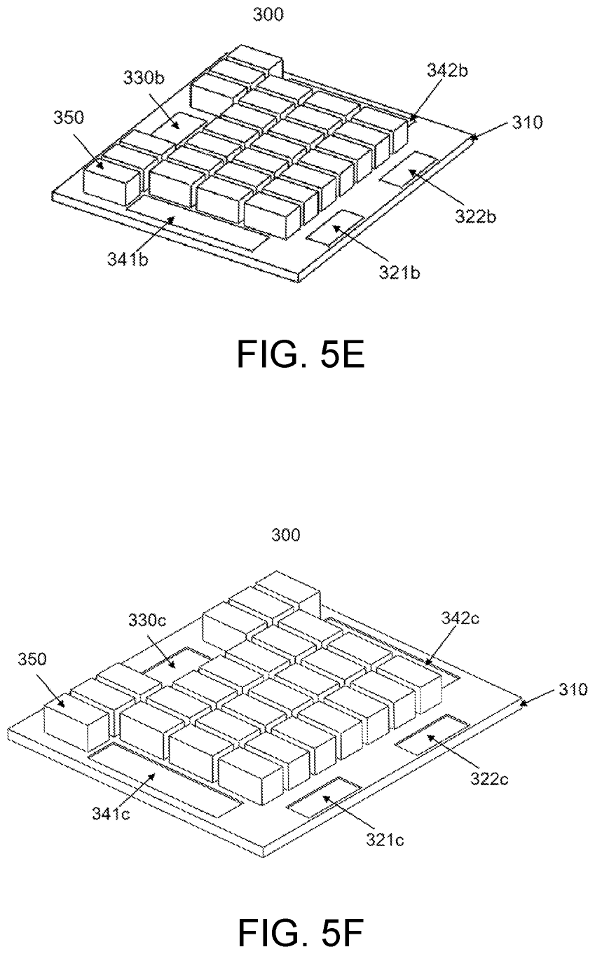

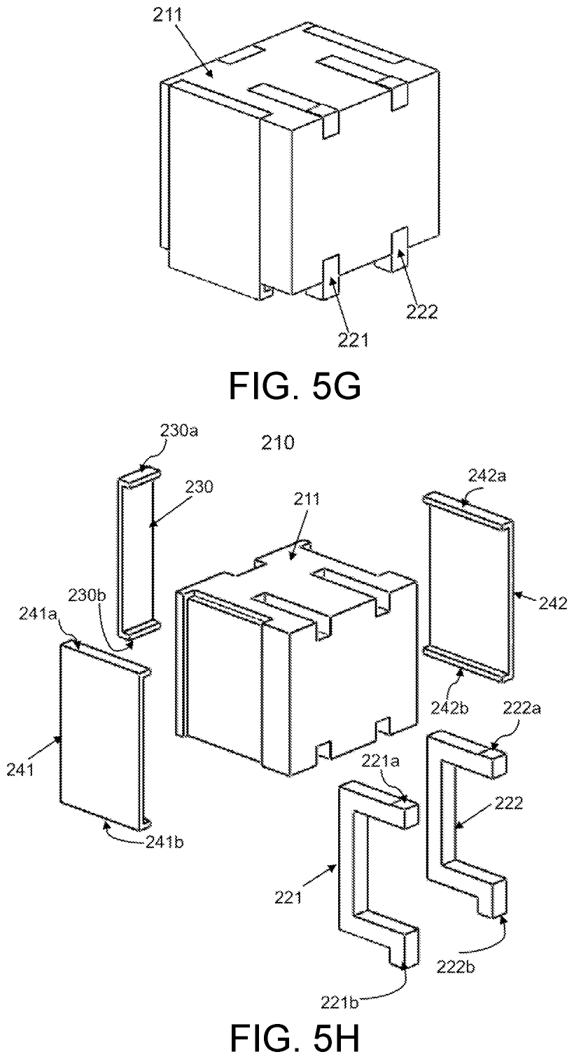

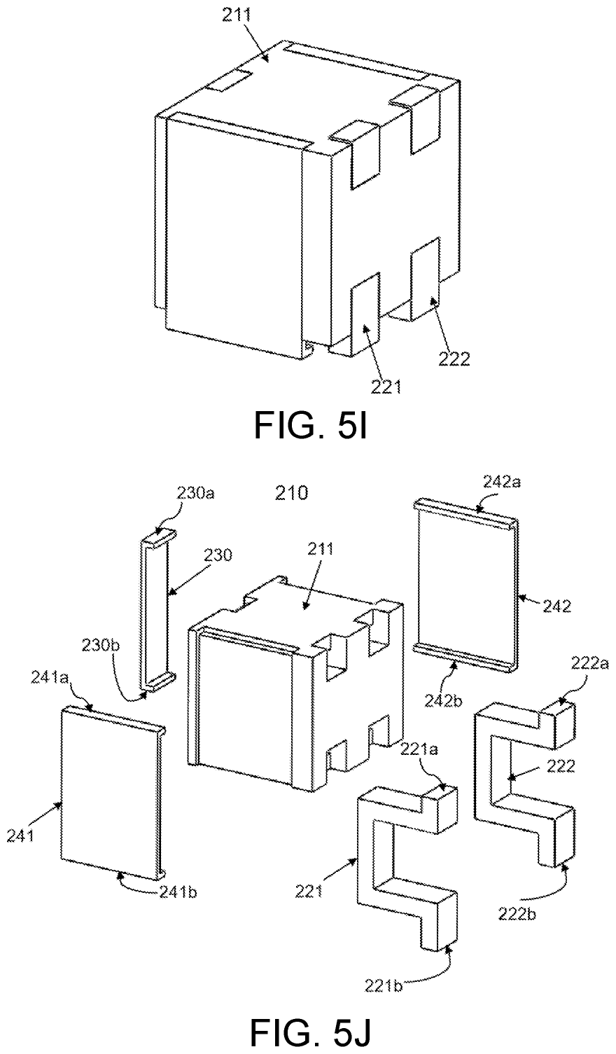

FIG. 5A shows the schematic structural diagram of a two-phase VRM module according to an embodiment. FIG. 5B shows the exploded view of FIG. 5A. FIG. 5C shows the schematic structural diagram of the intermediate assembly 200 in FIG. 5B. FIG. 5D shows the exploded view of the two-phase integrated inductor 210 in FIG. 5C. FIG. 5E shows the schematic structural diagram of the bottom assembly 300. As shown in FIGS. 5A and 5B, the two-phase VRM module 10 comprises a top assembly 100, an intermediate assembly 200 and a bottom assembly 300. There is the same technical effect in this embodiment as the third embodiment. The difference between this embodiment and the third embodiment is that the structure of the intermediate assembly 200 (specifically the winding therein) and the structure of the bottom assembly 300 in the embodiment. As shown in FIGS. 5C and 5D, the second pads 221b/222b of the windings protrude from the bottom surface of the magnetic core, and the second pad 230b of the first power electric connecting piece 230 and the second pad 241b/242b of the second power electric connecting piece 241/242 all protrude from the bottom surface of the magnetic core. As shown in FIG. 5E, the PCB in the bottom assembly 300 adopts the bonding pads 321b/322b/330b/341b/342b to replace the copper column (the copper pillars 321a/322a/330a/341a/342a in the third embodiment) is directly connected to a second pad 221b/222b/230b/241b/242b of the intermediate assembly 200 (comprising a two-phase integrated inductor 210 and a power pin). The advantage of this is that the connection point flowing large current is reduced, the direct current impedance increased due to the connection point is reduced, and the efficiency is improved.

In some other embodiments, as shown in FIG. 5F, groove 321c/322c/330c/341c/342c is provided with bonding pad in it on the bottom assembly 300. When the second pad 221b/222b/230b/241b/242b of the intermediate assembly 200 is respectively welded to the corresponding grooves 321c/322c/330c/341c/342c, the flatness tolerance is absorbed by the grooves 321c/322c/330c/341c/342c. Adopting the bottom assembly 300 shown in FIG. 5F, so that the assembly of the two-phase VRM module 10 can be more convenient and reliable.

FIG. 5G to FIG. 5J are embodiments corresponding to other winding shapes, only the structure is shown here, and the related beneficial effects are not described again.

### Embodiment 5

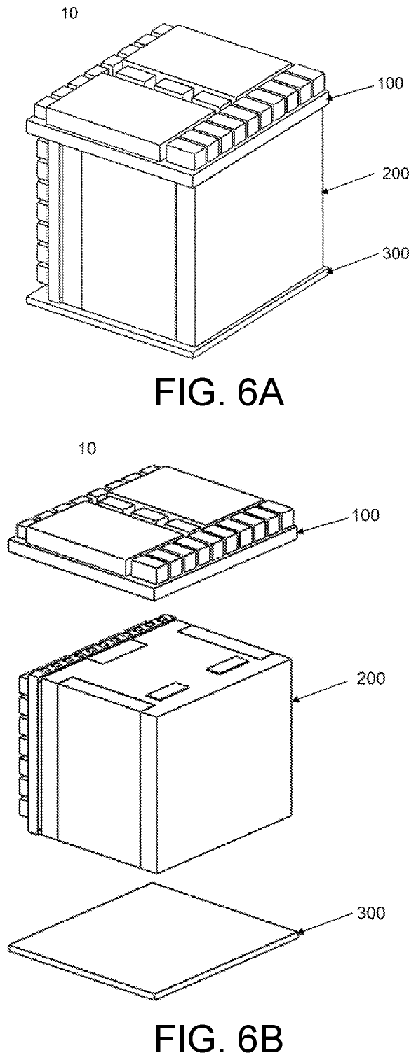

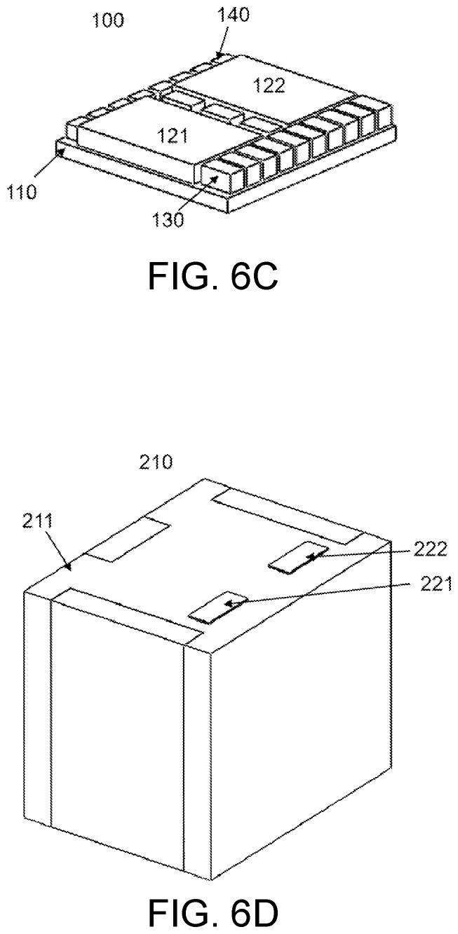

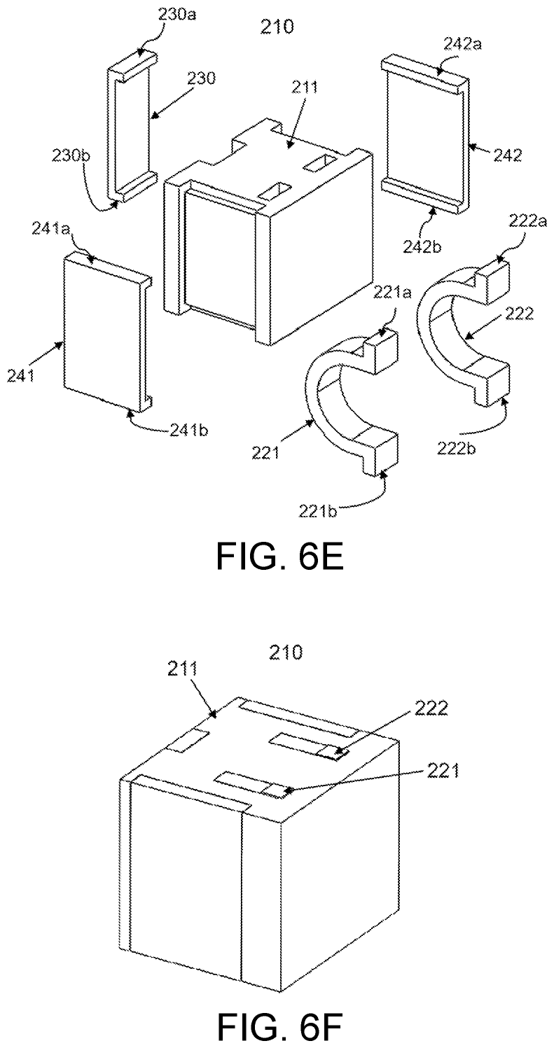

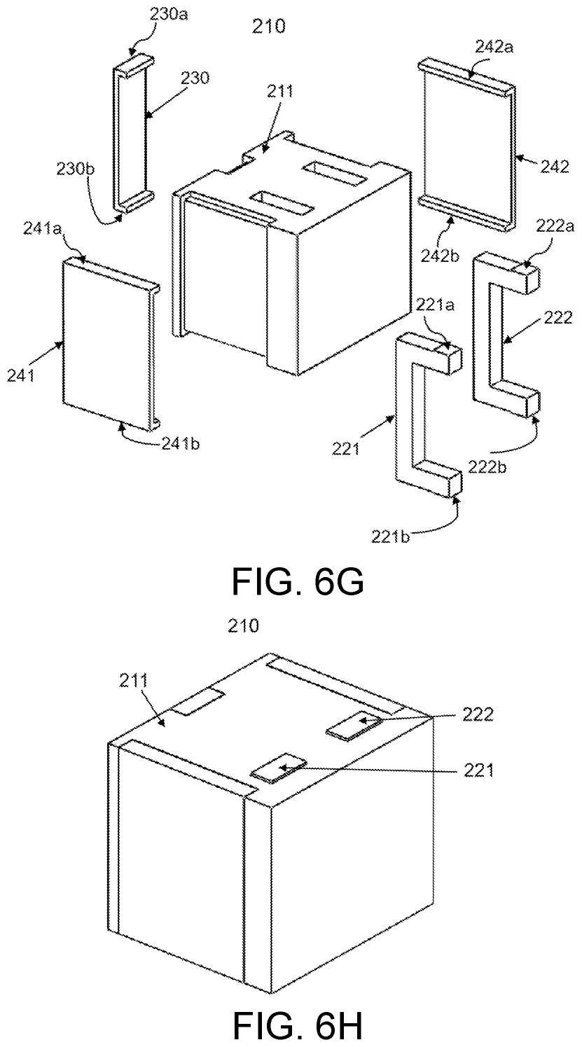

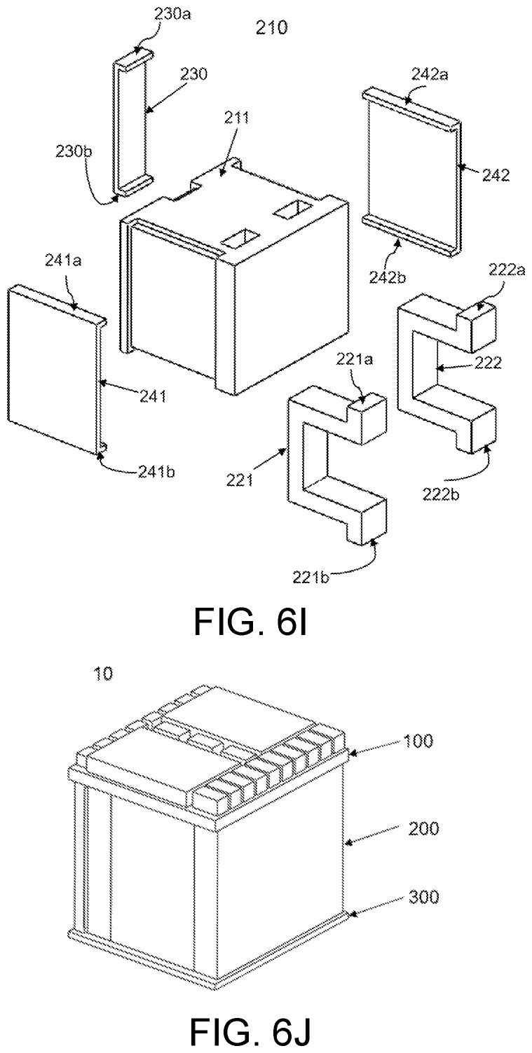

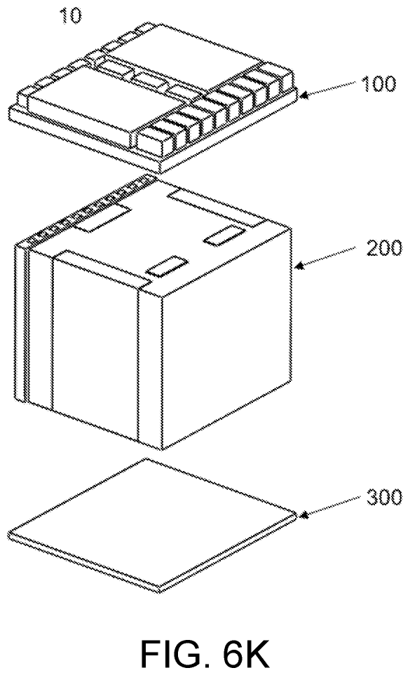

FIG. 6A shows the schematic structural diagram of a two-phase VRM module 10 according to an embodiment. FIG. 6B shows the exploded view of FIG. 6A. FIG. 6C shows the schematic structural diagram of the top assembly 100 in FIG. 6B. FIG. 6D shows the schematic structural diagram of the intermediate assembly 200 in FIG. 6B. FIG. 6E shows the structural exploded view of the two-phase integrated inductor 210 shown in FIG. 6D. The embodiment shares the same technical feature and effect with the embodiment 1. The difference is that the IPM units 121/122 are arranged in the middle area of the top surface of the top assembly 100. In order to enable the first pads 221a/222a of the winding to be directly and vertically connected with the SW end of the IPM unit 121/122, the first pads 221a/222a of the winding are arranged in the middle area of the top surface of the magnetic core 211 (the position is still closer to the first side surface than to the center of the top surface of the magnetic core 211). The second pads 221b/222b of the winding are correspondingly arranged in the middle area of the bottom surface of the magnetic core 211, so that the length of the winding is reduced. Meanwhile, any part of the winding is surrounded by the magnetic core 211, so that higher inductance and lower direct-current impedance can be realized. The efficiency of the two-phase VRM module 10 is improved.

As shown in FIGS. 6A and 6B, the two-phase VRM module 10 comprises a top assembly 100, an intermediate assembly 200 and a bottom assembly 300. The top assembly 100 comprises a first plate 110, IPM units 121/122, an input capacitor 130 and other passive elements 140. And the IPM unit 121 and the IPM unit 122 are arranged in the middle area of the top surface of the first plate 110.

The two-phase integrated inductor 210 shown in FIG. 6D and FIG. 6E shares the same technical feature and effect as Embodiment 1. In the two-phase integrated inductor 210 shown in FIG. 6D, the windings are provided inside the magnetic core. Specifically, the first pad 221a/222a of the winding is arranged in the top surface of the magnetic core 211. The second pad 221b/222b of the winding is arranged in the bottom surface of the magnetic core 211. the length of the winding is reduced, the direct-current impedance of the winding is reduced, and the inductance of the winding is increased, so that the efficiency of the VRM module is improved.

FIG. 6F to FIG. 6I are embodiments corresponding to other winding shapes, only the structure is shown here. the related beneficial effects are same, so it's not described again.

In some other embodiments, as shown in FIG. 6J and FIG. 6K, the vertical plate 250 is only used for signal transmission and is not provided with a capacitor, so that the vertical plate 250 can be more flexibly used for processing the quality of signal transmission. The anti-interference shielding function is achieved.

### Embodiment 6

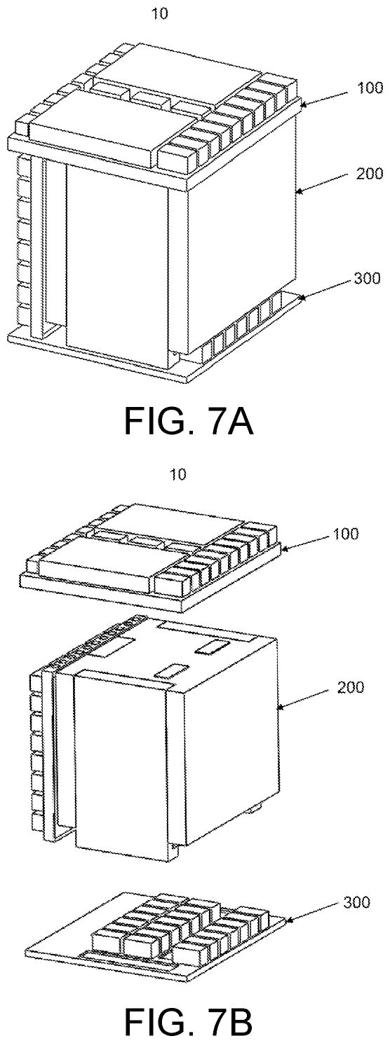

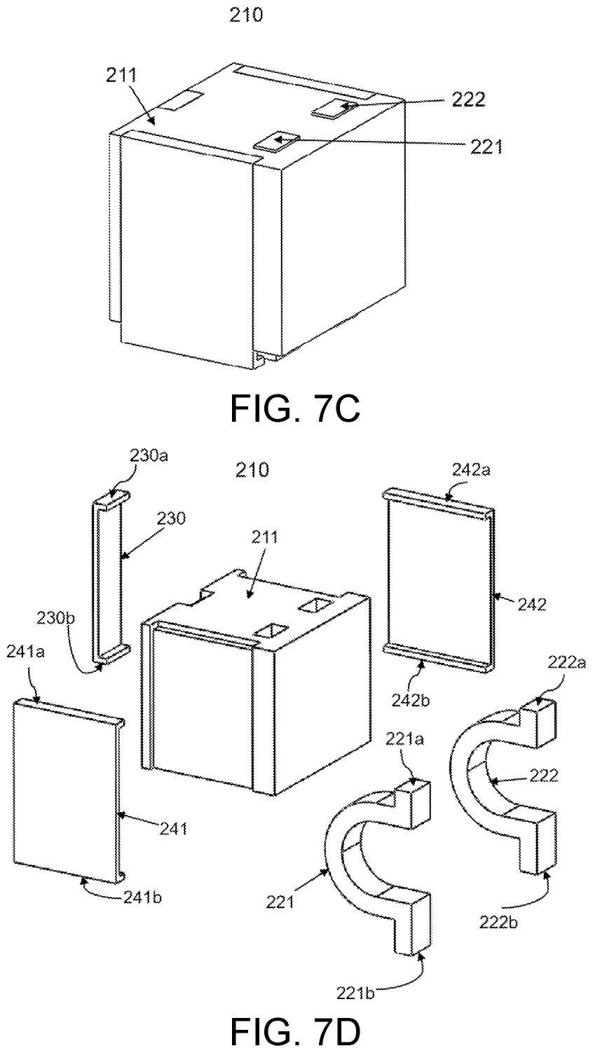

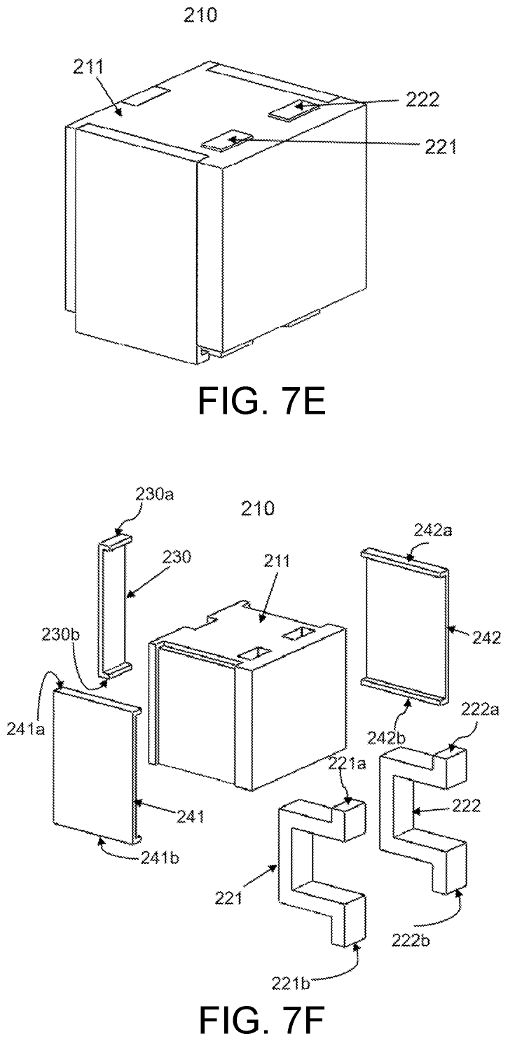

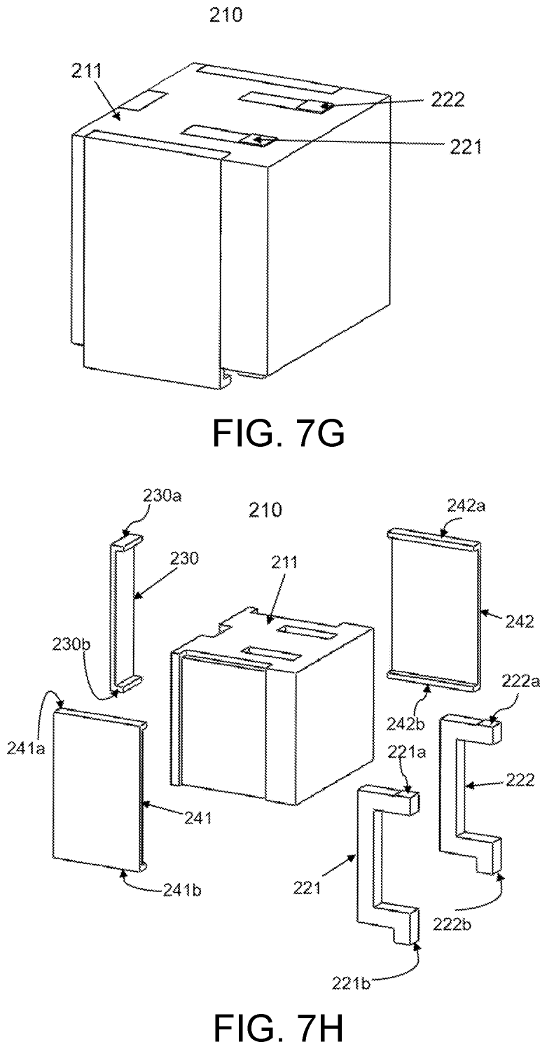

FIG. 7A shows the schematic structural diagram of a two-phase VRM module 10 according to an embodiment FIG. 7B shows the exploded view of FIG. 7A. FIG. 7C shows the schematic structural diagram of the two-phase integrated inductor 210 in FIG. 7B. FIG. 7D shows the structural exploded view of the two-phase integrated inductor 210 shown in FIG. 7C. Therefore, the second pad 221b/222b of the inductor winding protrudes from the bottom surface of the magnetic core. The second pad 230b of the first power electric connecting piece 230 protrudes from the bottom surface of the magnetic core. In some other embodiments, a combination of the third embodiment and the fifth embodiment may also be performed. The second pad 221b/222b/230b/241b/242b may also be disposed on the bottom surface and at the same height as the bottom surface. The copper pillars 321a/322a/330a/341a/342a are added to the bottom assembly 300 to connect the second pads 221b/222b/230b/241b/242b, and the effect is the same as that in the foregoing embodiments. The details are not described herein again.

Optionally, after adding the copper columns 321a/322a/330a/341a/342a to the bottom assembly, the output capacitor and the copper columns 321a/322a/330a/341s/342a are molded into a whole through a plastic packaging process. Then the bonding pads are engraved by laser and then connected with the second pads 221b/222b/230b/241b/242b.

FIG. 7E to FIG. 7H show another structure of the two-phase integrated inductor 210 in the present embodiment. The main difference thereof is the structure of the windings, which is described in foregoing embodiments. The details are not described herein again.

### Embodiment 7

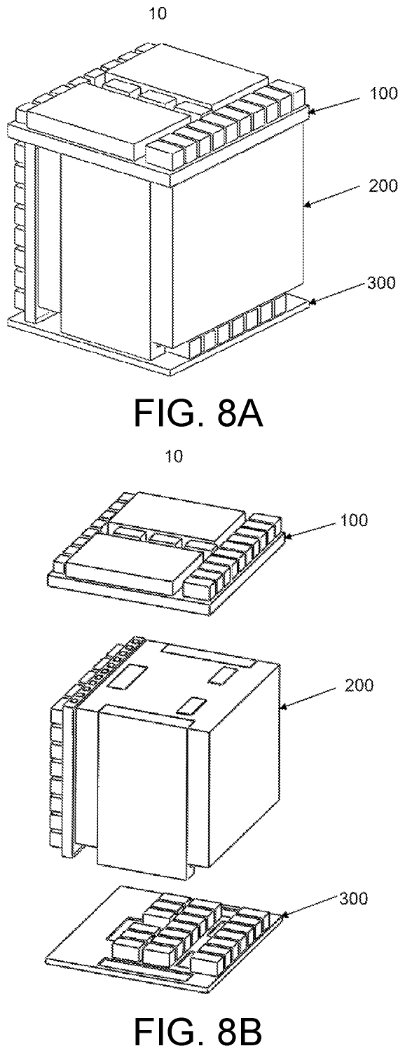

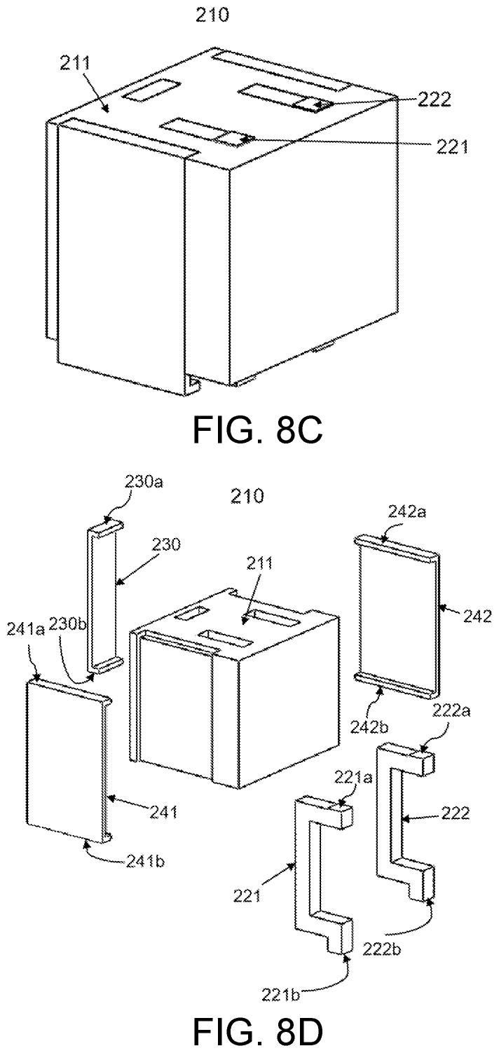

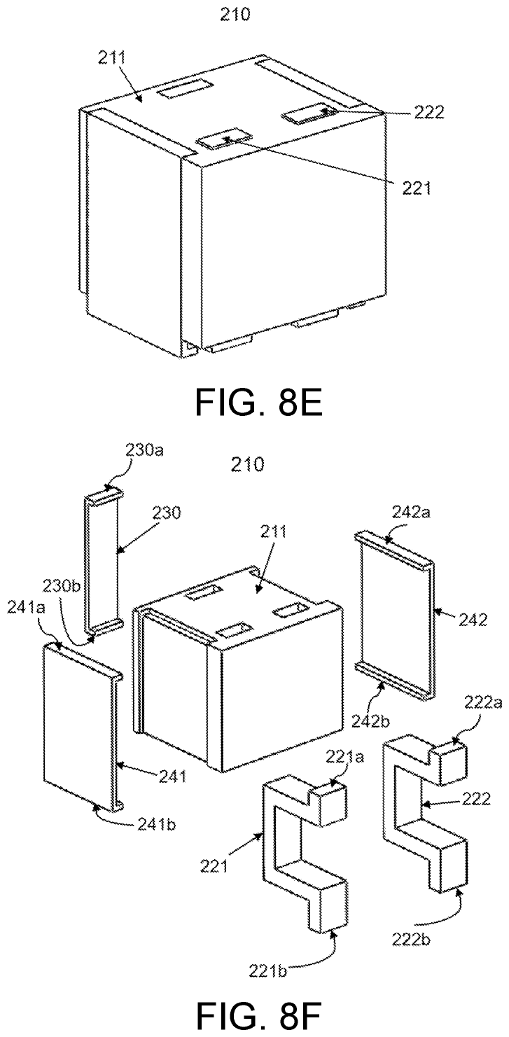

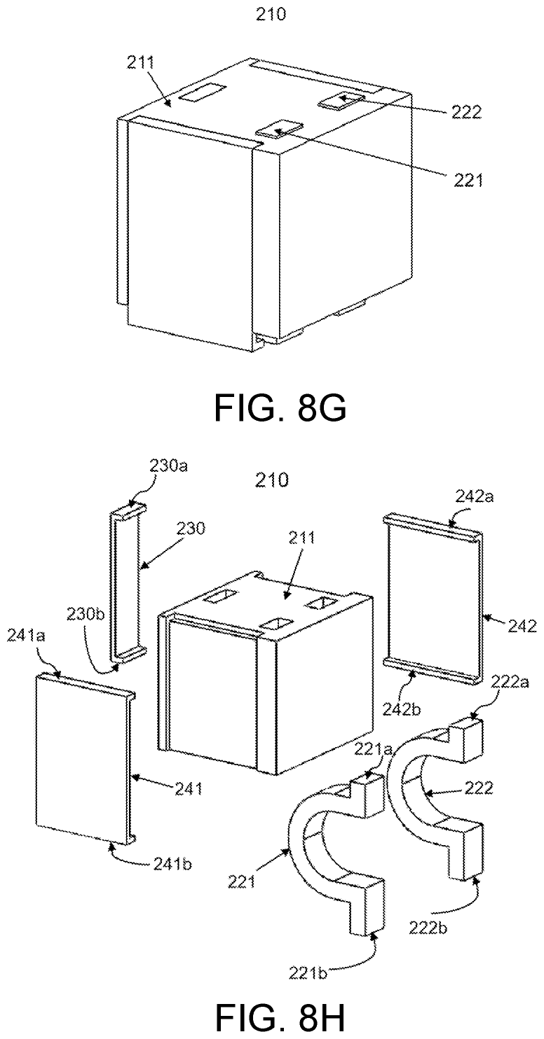

FIG. 8A shows the schematic structural diagram of a two-phase VRM module 10 according to an embodiment. FIG. 8B shows the exploded view of FIG. 8A. FIG. 8C shows the schematic structural diagram of the two-phase integrated inductor 210 in FIG. 8B. FIG. 8D shows the structural exploded view of the two-phase integrated inductor 210 shown in FIG. 8C. As shown in FIG. 8C and FIG. 8D, the first power electric connecting piece 230 is arranged inside the magnetic core 211. the first power electric connecting piece 230 has a larger inductance, so that the parasitic inductance of the power input loop is larger, and the resonant frequency of the parasitic inductance and the input capacitance is away from the working frequency of the IPM unit 121/122. The two-phase VRM module 10 works at a higher frequency, and higher efficiency and better dynamic performance are obtained. And meanwhile, the parasitic inductance can be adjusted by adjusting the width of the first power electric connecting piece 230, so that the resonant frequency of the resonant circuit is adjusted.

FIG. 8E to FIG. 8H show another structure of the two-phase integrated inductor 210 in the present embodiment. The main difference thereof is the winding structure, which is described in the forgoing embodiments. The details are not described herein again.

The technical features involved in the above embodiments can be combined with each other and used in the two-phase VRM module 10. For example, the vertical plate 250 is provided with an input capacitor. The first power electric connecting piece 230 needs to be electrically connected with the vertical plate 250, so that the first power electric connecting piece 230 can be integrated into the vertical plate 250. The vertical plate 250 is also integrated with only the signal electrical connection member 251, the first power electric connecting piece 230 and the metal shielding layer 252. The metal shielding layer 252 in the vertical plate may also be replaced by the first power electrical connection member 230.

### Embodiment 8

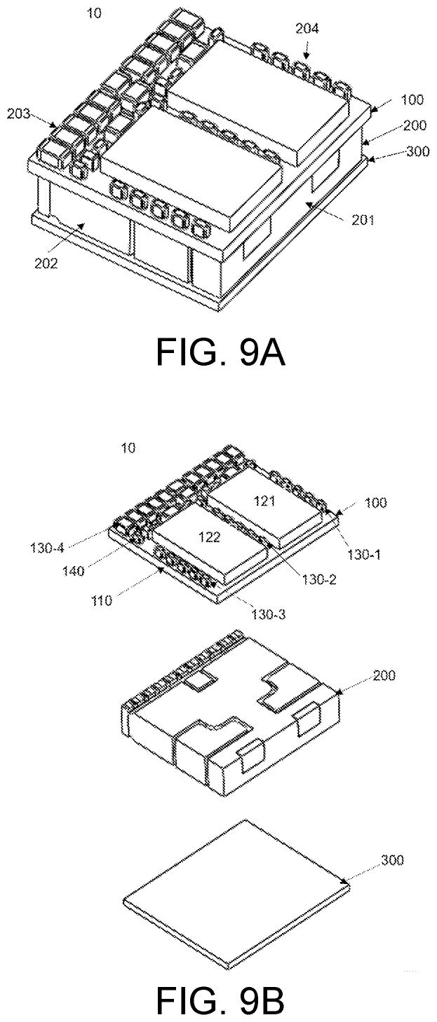

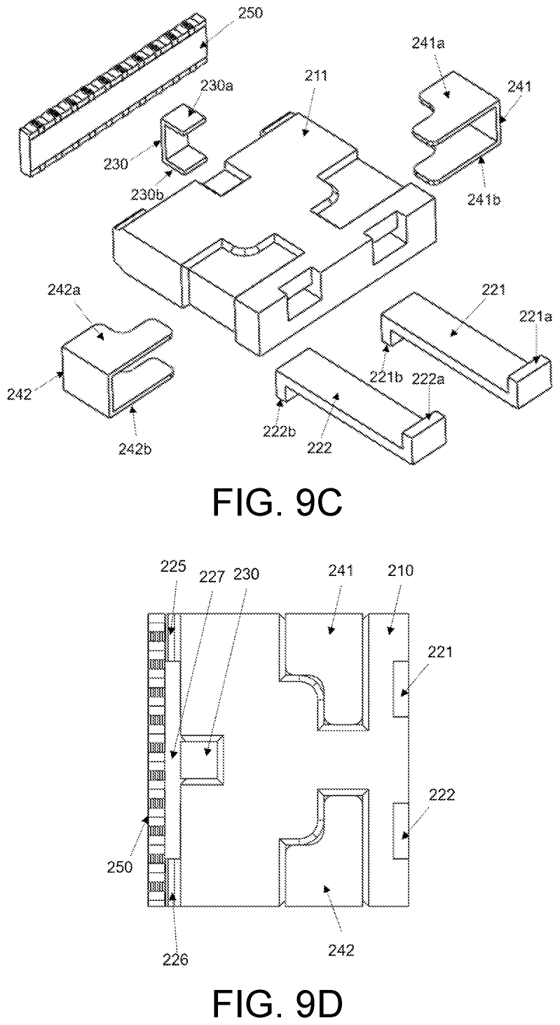

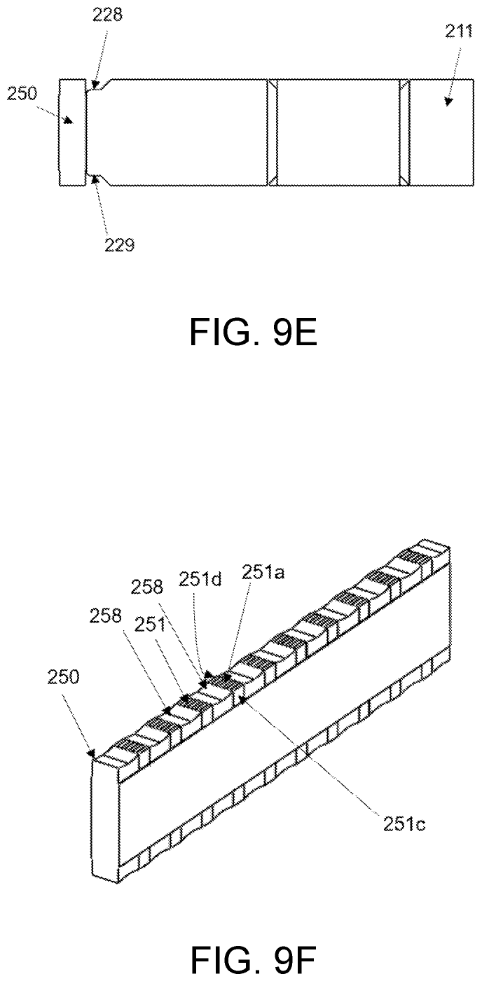

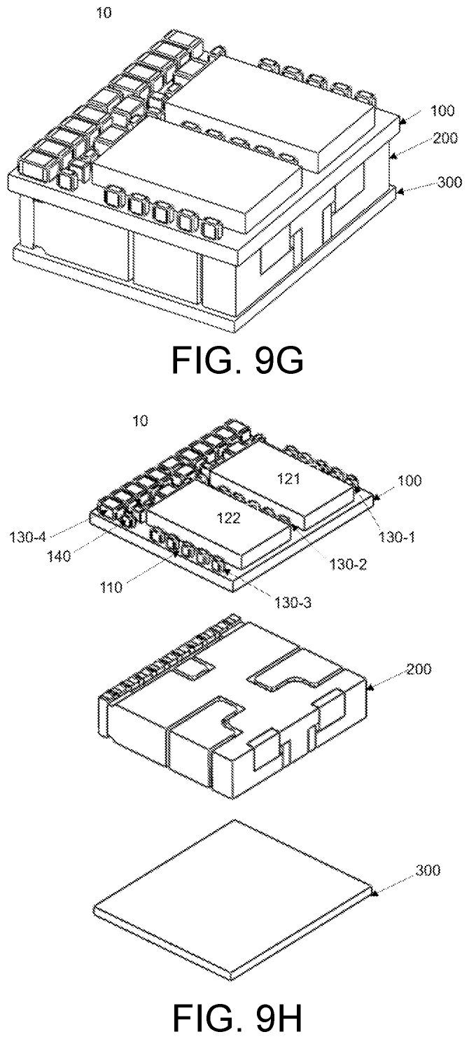

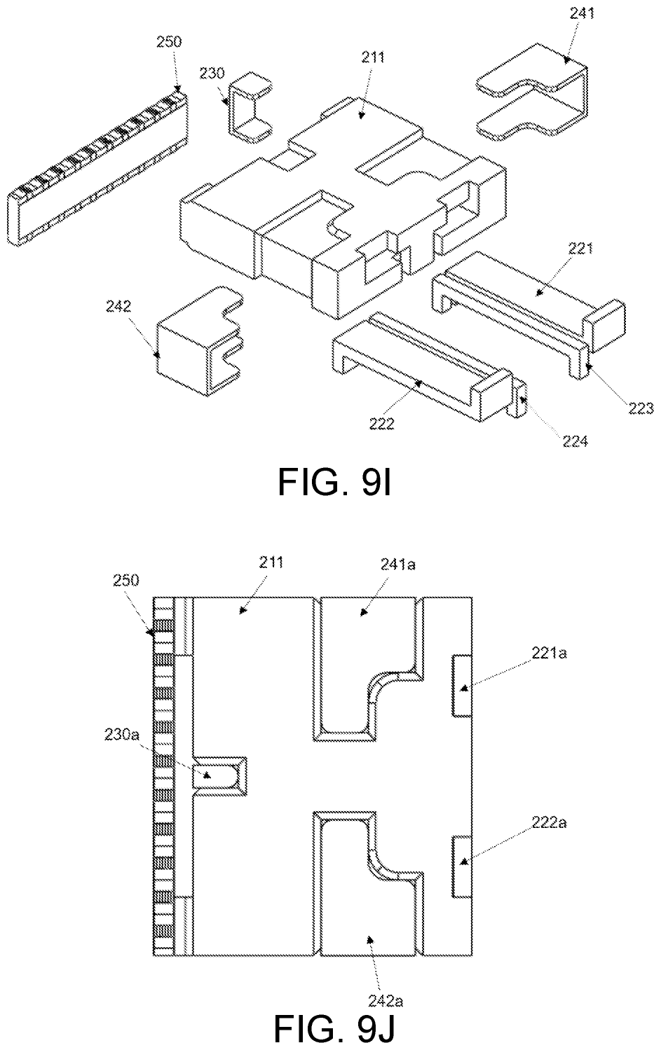

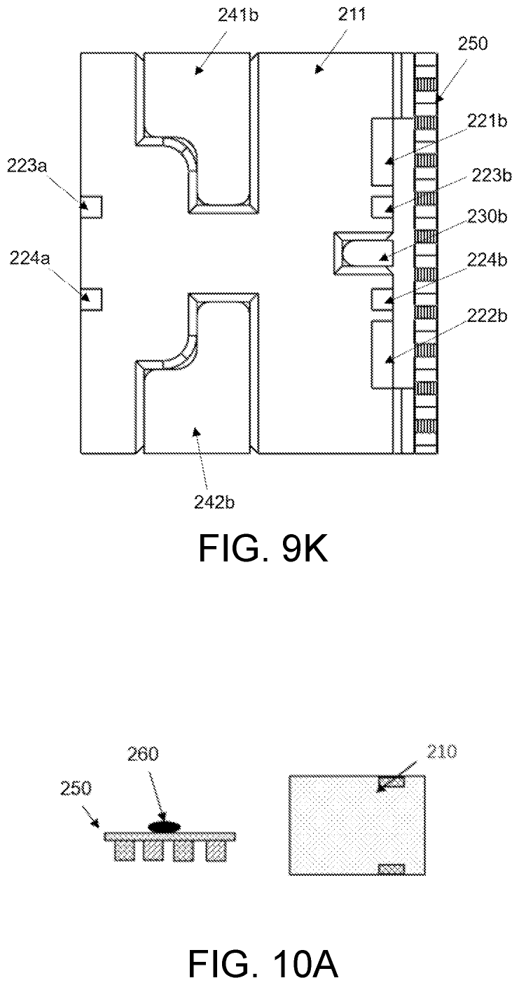

FIG. 9A shows an overall structure of a two-phase VRM module 10 of the present embodiment. FIG. 9B is an exploded view of FIG. 9A. As shown in FIGS. 9A and 9B, the two-phase VRM module 10 of the embodiment comprises a top assembly 100, a intermediate assembly 200 and a bottom assembly 300. The top assembly 100 comprises a first plate 110, IPM units 121/122, input capacitors 130-1 to 130-4 and other passive elements 140. The IPM unit 121/122 is arranged close to the first side edge of the first plate 110, namely, the position corresponding to the first side surface 201 of the intermediate assembly 200. The signal pin of the IPM unit 121/122 is arranged in the direction towards the third side edge of the first plate 110, namely, the position corresponding to the third side surface 203 of the intermediate assembly 200. The input capacitor 130 and the other passive elements 140 need to be close to the IPM units 121/122 to achieve good filtering and other effects, so that the other passive elements 140 are arranged at positions adjacent to the signal pins of the IPM units 121/122. The input capacitor 130-2 is arranged between the IPM unit 121 and the IPM unit 122. The input capacitor 130-1 and the input capacitor 130-3 are respectively adjacent to two sides of the IPM unit 121 combined with the IPM unit 122. The input capacitor 130-1 and the input capacitor 130-3 are respectively close to the second side edge and the fourth side edge of the first plate 110, that is, respectively correspond to the positions of the second side surface 202 and the fourth side surface 204 of the intermediate component 200. The input capacitor 130-4 is close to the third side edge of the first plate 110.

FIG. 9C shows an exploded view of the intermediate assembly 200 shown in FIG. 9B. As shown in FIG. 9C, the intermediate assembly 200 comprises a magnetic core 211, a first winding 221, a second winding 222, a VIN electric connecting piece 230, a GND electric connecting piece 241/242 and a vertical plate 250. As shown in FIG. 9C, there is no coupling relationship between the first winding 221 and the second winding 222, or only weak positive coupling exists. For example, the coupling coefficient is less than 0.2.

Both the first winding 221 and the second winding 222 are Z-shaped copper sheets. Both the two horizontally penetrate from the first side surface 201 of the magnetic core to the opposite third side surface 203. One end of each winding extends from the first side surface 201 to the top surface of the magnetic core, forming the first pads 221a and 222a on the top surface of the magnetic core. The other end of each winding extends from the third side surface 203 to the bottom surface of the magnetic core, and forming the second pads 221b and 222b on the bottom surface of the magnetic core.

The first pad 221a1/222al of the winding is vertically connected to the SW pad of the IPM unit 121/122 nearby. The GND electric connecting piece comprises two C-shaped copper sheets which are respectively buckled on the second side surface 202 and the fourth side surface 204 of the intermediate assembly 200. Specifically, the GND electric connecting piece 242 wraps part of the second side surface 202 of the intermediate assembly 200, forms a first pad 242a on the top surface of the intermediate assembly 200, and forms a second pad 242b on the bottom surface of the intermediate assembly 200. The GND electric connecting piece 241 covers a portion of the fourth side surface 204 of the intermediate assembly 200, forms a first pad 241a on the top surface of the intermediate assembly 200, and forms a second pad 241b on the bottom surface of the intermediate assembly 200. The first pad 241a1/242al of the GND electric connecting piece is vertically connected to the GND end of the IPM unit 121/122 nearby. Due to the current flowing through the winding and the current flowing through the GND electric connecting piece are both large currents, the winding and GND electric connecting piece are vertically connected to the SW end and GND end of the IPM to reduce the loss caused by the lateral current, thereby improving the transmission efficiency of the module.

The Vin electric connecting piece 230, also a copper sheet with the “C” shape, covers a portion of the third side surface 203 of the intermediate assembly 200, forms a first pad 230a on the top surface of the intermediate assembly 200, and forms a second pad 230b on the bottom surface of the intermediate assembly 200. Both the VIN electric connecting piece 230 and the GND electric connecting piece 241/242 are C-shaped copper sheets bent from a rectangular copper sheet, which are easy to assemble with the magnetic core 211, thereby simplifying the manufacturing process and improving the reliability of the module. In the embodiment, the tail ends of the first pads 241a and 242a and the second pads 241b and 242b of the GND electric connecting piece are arc-shaped. The shape can be designed according to the actual device layout. The contact area of the first pad and the second pad is increased as much as possible, reducing the contact loss, and the assembly reliability of the module is improved.

FIG. 9D is a top view of the intermediate assembly 200 shown in FIG. 9B. FIG. 9E is a side view of the intermediate assembly 200. FIG. 9F is a schematic structural diagram of the vertical plate 250. As shown in FIG. 9D to FIG. 9F, the third side surface 203 of the magnetic core 211 is provided with bosses 225 and 226. A groove 227 is provided between the bosses 225 and 226. The vertical plate 250 is assembled with the magnetic core 210 through bosses 225 and 226. The vertical plate 250 and the bosses 225 and 226 are usually bonded with epoxy resin. The vertical plate 250 is provided with a signal electric connecting piece 251. the signal electric connecting piece 251 is subjected to solder mask spacing through the PCB base material 258. The height of the PCB base material 258 is lower than the height of the signal electric connecting piece 251, so that the signal electric connector 251 can be reliably welded. The side surface shape of the PCB base material 258 can be semi-arc shape or square shape. Furthermore, the side surface pads 251c and 251d of the signal electric connecting piece 251 are exposed on the two opposite side surfaces, so that there are three surfaces on one end of the signal electric connecting piece 251 which can be used for welding tin climbing. Namely, the section 251a and the side surfaces pads 251c/251d. The bosses 225 and 226 of the magnetic core 211 are further provided with chamfers or avoidance grooves 228/229. The avoidance grooves are arranged at the positions, closing to the top surface and the bottom surface of the bosses. The grooves 227 and the avoidance grooves 228 and 229 are used for avoiding the side surface pads 251c of the vertical plates 250, ensuring that the side surface pads 251c of the vertical plates 250 have enough tin-climbing spaces, so that reliable welding is realized.

FIG. 9G is another embodiment similar to the embodiment shown in FIG. 9A. FIG. 9H is a structural exploded view of FIG. 9G. FIG. 9I is a structural exploded view of the intermediate assembly 200 shown in FIG. 9H. FIG. 9J is a top view of the intermediate assembly 200. FIG. 9K is a bottom view of the intermediate assembly 200. As shown in FIG. 9G to FIG. 9K, the difference between the embodiment and the embodiment shown in FIG. 9A is only that the first auxiliary winding 223 and the second auxiliary winding 224 are added to the intermediate assembly 200 in the embodiment. The first winding 221 and the first auxiliary winding 223 are coupled with each other. The second winding 222 and the second auxiliary winding 224 are mutually coupled to realize the TLVR function, so that the dynamic sensing of the module is reduced, and the dynamic performance of the module is improved. the auxiliary winding 223 is provided with first pads 223a and 223b on the bottom surface of the magnetic core. The auxiliary winding 224 is provided with second pads 224a and 224b on the bottom surface of the magnetic core. The other features are the same as those in the embodiment shown in FIG. 9a, and are not repeated again.

### Embodiment 9

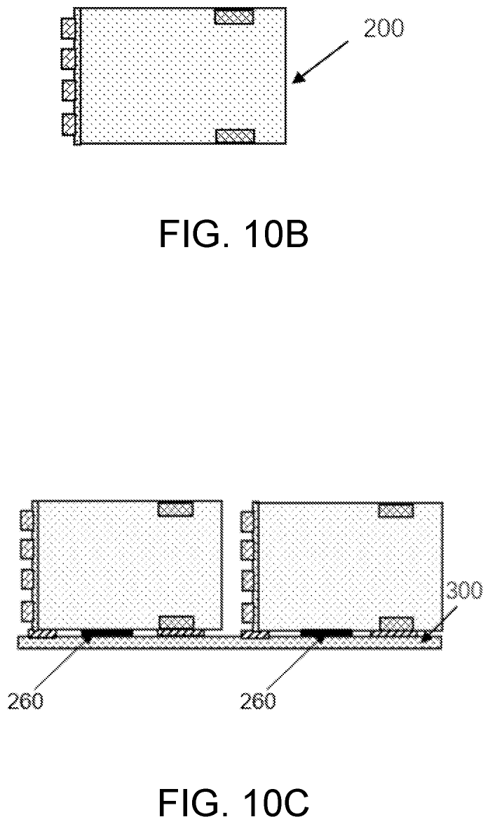

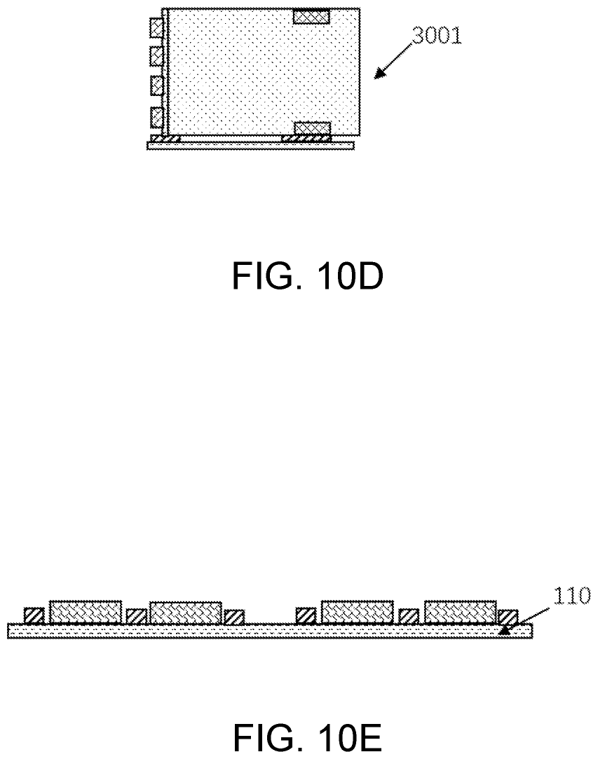

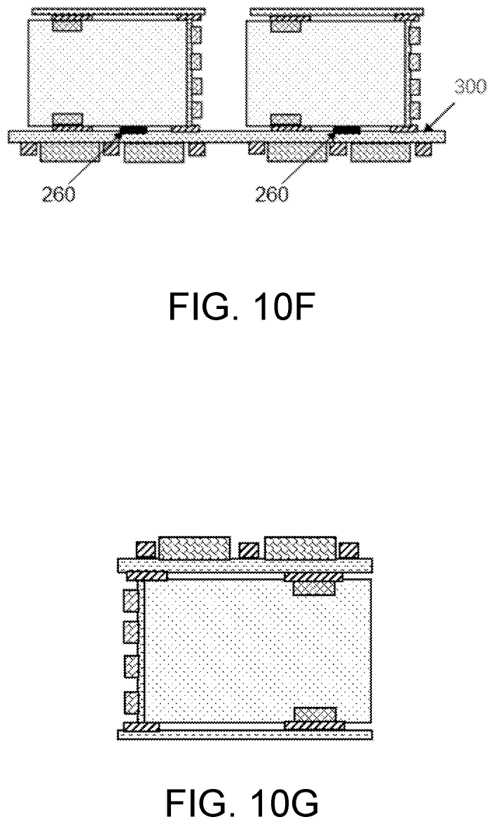

The embodiment shows the process flow of the two-phase VRM module, and as shown in FIGS. 10A to 10G.
Step 1, preparing a vertical plate 250, and mounting an input capacitor on the surface; preparing a two-phase integrated inductor 210, wherein two metal windings, a first power electric connecting piece and a second power electric connector are integrated in the inductor, and glue 260 is dispensed on the vertical plate 250, as shown in FIG. 10A;
Step 2, positioning the vertical plate 250 and the two-phase integrated inductor 210 through a tool clamp to promote the two assemblies to be adhered into a whole, namely the intermediate assembly 200, as shown in FIG. 10B;
Step 3, the intermediate assembly 200 is used as a component dispensing glue 260 and welded to a panel (After depaneled, that is the bottom assembly 300), as shown in FIG. 10C;
Step 4, After being depaneled, independent units 3001 are formed, as shown in FIG. 10D; the depanel process comprises Tape sawing, JIG sawing, Router, V-Cut and etc;
Step 5, welding elements such as an IPM unit and a capacitor to a top surface bonding pad of another panel (After being depaneled, that is the first plate 110), as shown in FIG. 10E;
Step 6, the unit 3001 is dispensed with the glue 260 and welded to the bottom surface bonding pad of the first plate 110, as shown in FIG. 10F;
Step 7: depaneling to form the VRM module according to the embodiment, as shown in FIG. 10G.

Particularly, after the vertical plate 250 and the two-phase integrated inductor 210 are adhered into a whole, the upper surface and the lower surface of the vertical plate 250 must have enough flatness to ensure that the unit 3001 and the bottom assembly and the top assembly are well welded. The tolerance of the vertical plate 250 is usually within +/−0.1 mm. The tolerance of the two-phase integrated inductor 210 is controlled within +/−0.075 mm. To form a good flatness with the two-phase integrated inductor 210 and the two-phase integrated inductor 210, the vertical plate 250 and the two-phase integrated inductor 210 need to be subjected to size measurement and classify in advance. The height difference between the vertical plate 250 and the two-phase integrated inductor 210 within 0.05 mm will be assembled together to form the integrated inductor 210.

According to the embodiment, dispensing glue 260 between the magnetic core and the panel; gluing and reflow soldering can be synchronously carried out; the overall reliability of the module can be improved through gluing and fixing; for example, under the conditions of reflow soldering, vibration, falling, repairing and the like, or the two-phase VRM module is hung on the back face of the mainboard; the connection strength among the top assembly, the bottom assembly, the vertical plate and the integrated inductor is enhanced.

In a preferred embodiment, the height of the vertical plate 250 is higher than that of the two-phase integrated inductor 210. After the vertical plate 250 is assembled into a whole, the pads of the vertical plate 250 is flush with the pads of the two-phase integrated inductor 210 in a grinding mode, so that the flatness of the pads is good. Then, a layer of nickel-tin layer is added to the pads in a rolling plating mode, so that subsequent welding is facilitated.

Next, the manufacturing process of the vertical plate 250 is described. The main purpose is to adopt the planar machining mode of the PCB, and the end face after being de-paneled serves as pads for connecting the top assembly and the bottom assembly. Taking the four-layer plate as an example, the specific process is as follows:

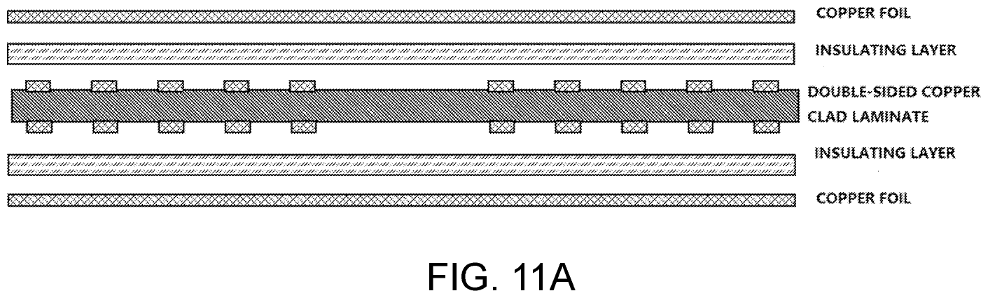

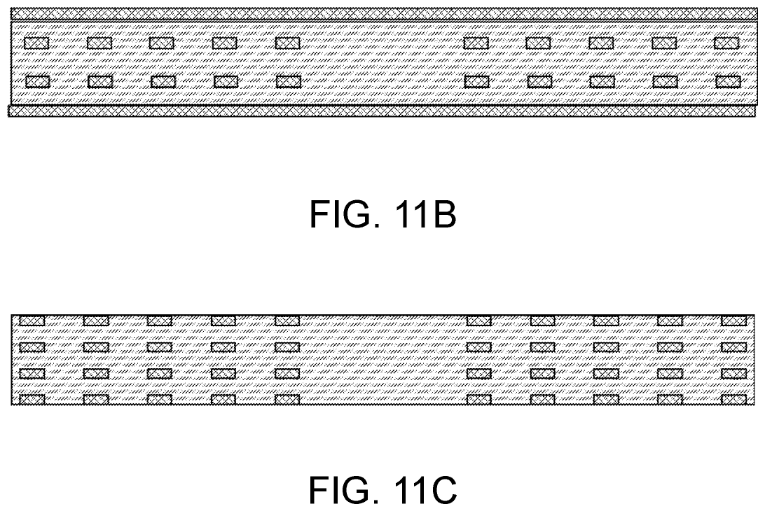

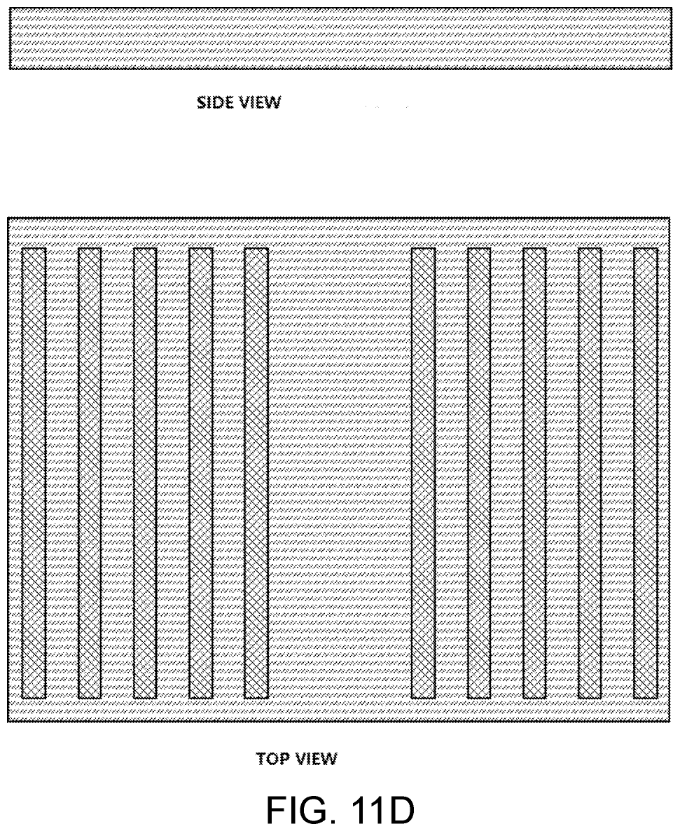

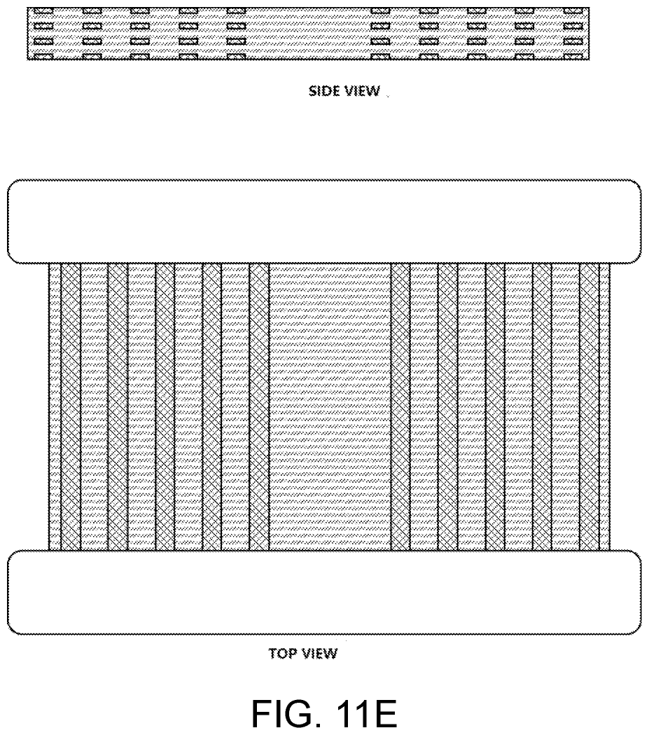

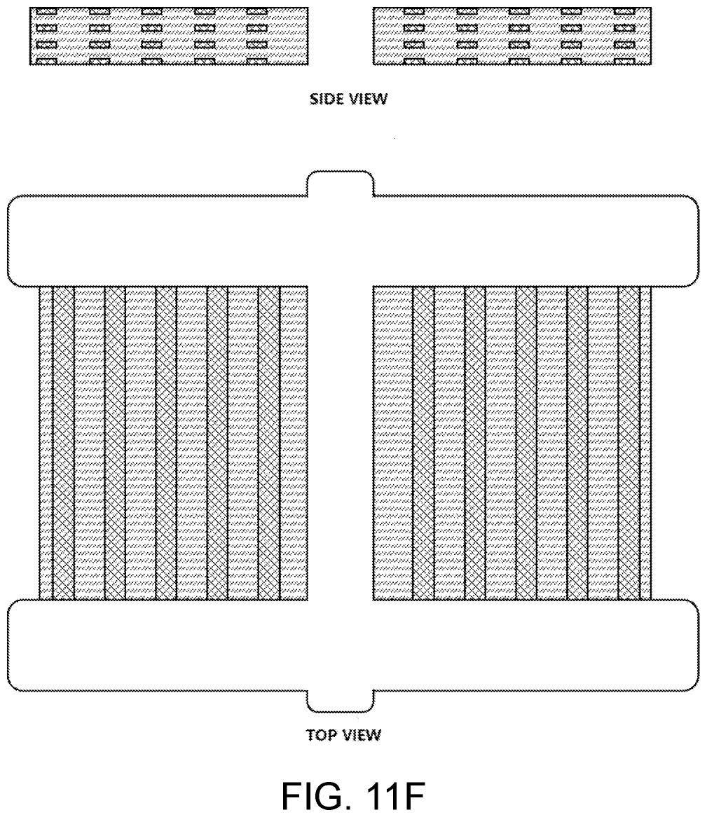

Step 1, a four-layer PCB is formed. As shown in FIG. 11A, preparing a double-sided copper-clad laminate, and two copper foils etching the desired trace on the two copper foils; preparing an insulating layer material and a copper foil, and simultaneously pressing the insulating layer and the copper foil from above and below, forming a PCB with four-layers PCB, as shown in FIG. 11B; and interconnecting of the four layers is realized through drilling, copper deposition and electroplating, and forming independent signal wires through an etching process, as shown in FIG. 11C, wherein the cross-sectional view of the PCB is shown in FIG. 11A-FIG. 11C.

In order to clearly describe the forming process of the board edge bonding pad, FIG. 11D to FIG. 11F show the appearance diagram of the PCB. Due to the fact that the PCBs are machined in a large plate. Many units are arranged on the large plate. Each unit represents the vertical plate 250 in the embodiment, so that batch production can be achieved. The efficiency of production is improved. FIGS. 11D-11F illustrate a subsequent process by taking two units as an example.

Step 2, forming a signal electric connector, the signal wires are exposed between the units through a groove milling process, and then gold deposition treatment is carried out, so that the exposed signal wires are coated with gold. Due to the signal wire is copper and is very easy to be oxidated, the exposed end surface can be depositing gold on the copper foil to ensure the weldability, as shown in FIG. 11E;

Step 3: de-paneling, that is, the vertical plate 250 of the present embodiment is formed, as shown in FIG. 11F.

### Embodiment 10

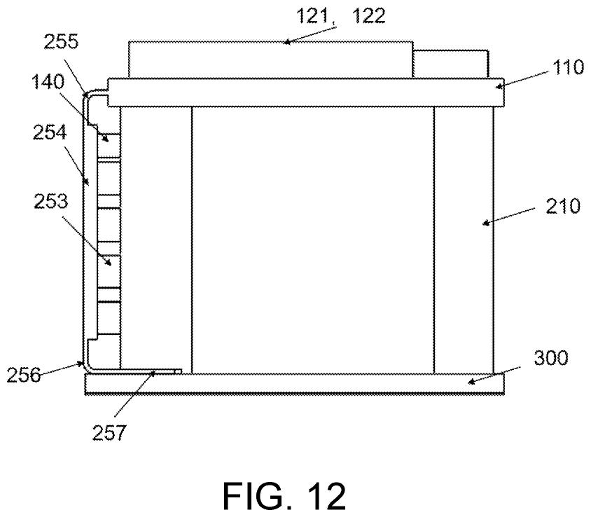

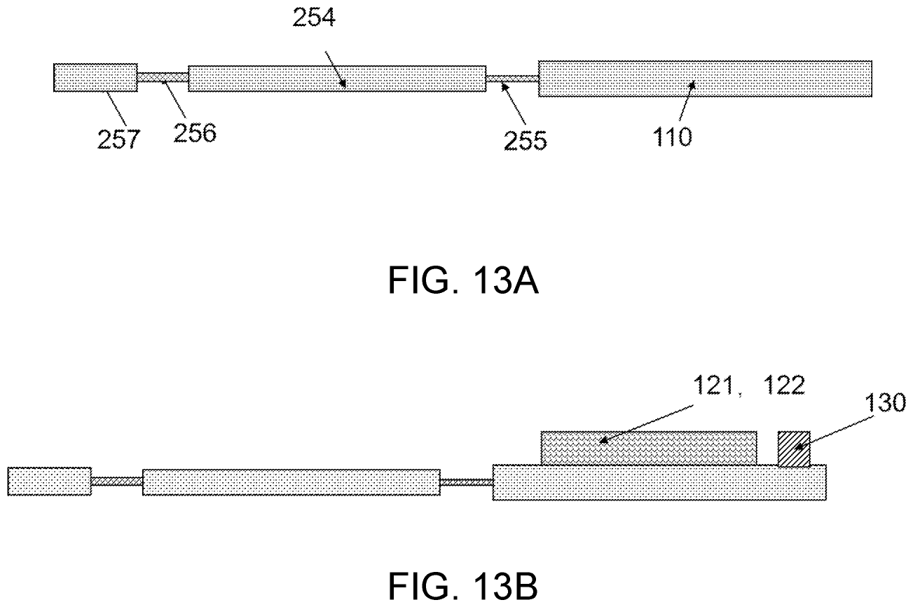

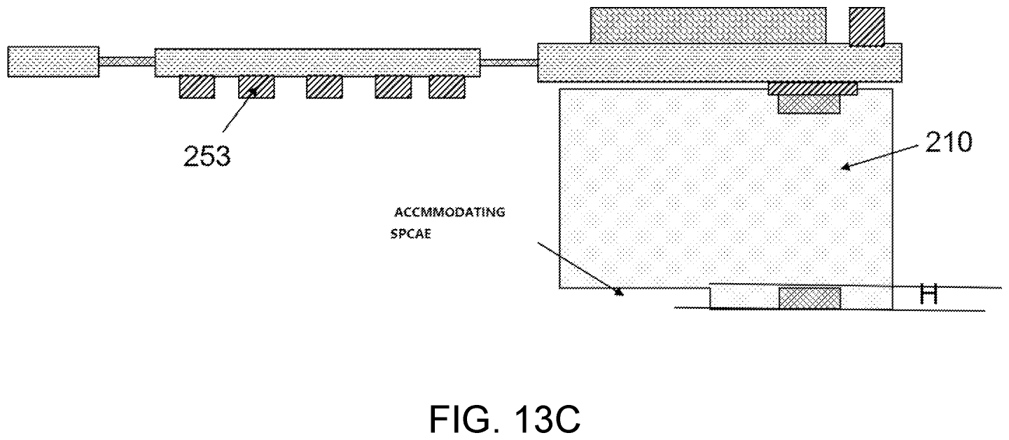

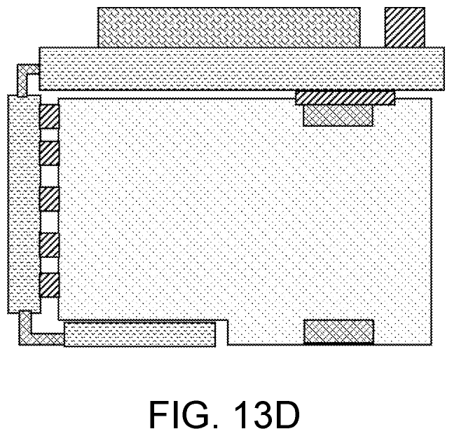

From the process of embodiment 9, it is challenging of the coplanarity of the bonding pads after the vertical plate 250 and the two-phase integrated inductor 210 being assembled. According to the structure provided by the embodiment, the challenge caused by coplanarity can be effectively avoided, and as shown in FIG. 12. Differing from the above embodiment, in the embodiment, a rigid-flexible combined plate is used. The top assembly 100 and the vertical plate 254 are combined into the rigid-flexible combined plate. The top assembly 100 and the vertical plate 254 are connected through a flexible adapter plate 255, a section of flexible adapter plate 256 and a section of rigid adapter plate 257 are additionally arranged at the other end of the vertical plate 254. The rigid adapter plate 257 can be bent to the bottom surface of the two-phase integrated inductor 210 through the flexible adapter plate 256. The specific process is as follows:
Step 1, a panel of rigid-flexible combined plate is prepared. The panel comprises a first plate 110, a vertical plate 254, a rigid adapter plate 257 and a flexible adapter plate 255/256 between the three rigid plates, as shown in FIG. 13A. The rigid-flexible combined plate is of a connecting piece structure (not shown in the figure);
Step 2, an IPM unit 121/122 and an input capacitor 130 are attached to the top surface of the rigid-flexible board, as shown in FIG. 13B;
Step 3, a two-phase integrated inductor 210 and a capacitor 253 are attached to the bottom surface of the rigid-flexible plate. The capacitor 253 can be an input capacitor or an output capacitor or a driving capacitor and the like, as shown in FIG. 13C;
Step 4, de-paneling, wherein the process is not shown in the figures;
Step 5, bending, the vertical plate 254 is attached to the side walls of the two-phase integrated inductor 210. The rigid adapter plate 257 is limited in the accommodating space, as shown in FIG. 13D. The height H (shown in FIG. 13C) of the accommodating space is formed through a mold, the precision is high, the thickness of the rigid adapter plate 257 is thin, and the tolerance is small, so that the adapter plate can be well matched with the accommodating space in height;
Step 6, welding with a PCB in a panel, wherein the PCB can form a bottom assembly 300;
Step 7, de-paneling and forming the two-phase VRM module shown in FIG. 12

Differing from the above embodiment, the vertical plate 254 is subjected to two times of welding, so that the signal or power transmission from the top assembly to the bottom assembly 300 can be realized. It will face the coplanarity problem each time of welding. According to the embodiment, the first plate 110 and the vertical plate 254 are directly achieved together through the PCB process. The coplanarity problem encountered in welding process is solved. Due to the fact that the containing space of the two-phase integrated inductor 210 is formed by hot pressing of the mold, the precision of the welding of the vertical plate 254 and the bottom assembly 300 is high. The two-phase integrated inductor 210 can be well matched with the adapter plate 257 in the height direction, so that the coplanarity of the vertical plate 254 and the two-phase integrated inductor 210 on the bottom bonding pad can be very good. Failure caused by welding cannot exist when the vertical plate 254 and the bottom assembly 300 are welded.

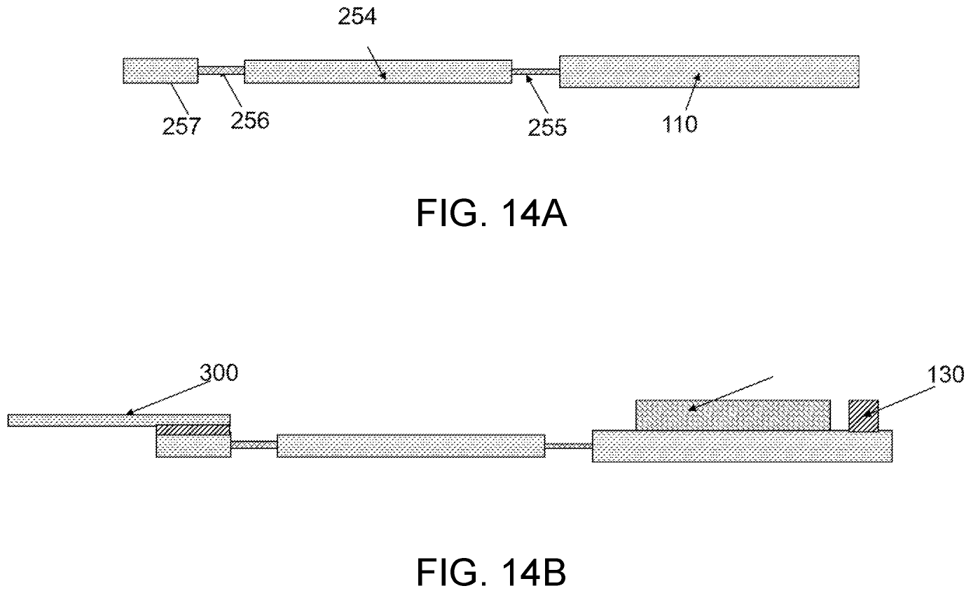

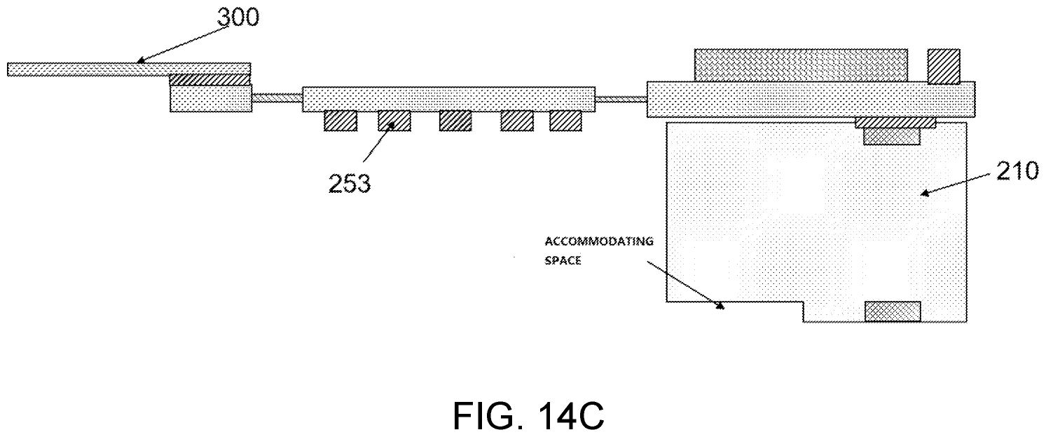

In a preferred embodiment, in order to further avoid the coplanarity problem, the process comprises the following steps:
Step 1, preparing a panel of rigid-flexible combined plate, which comprises a first plate 110, a vertical plate 254, a rigid adapter plate 257 and a flexible adapter plate 255/256 (as shown in FIG. 14A) between the three rigid plates;
Step 2, an IPM unit 121/122, an input capacitor 130 and a bottom assembly 300 are attached to the top surface of the rigid-flexible combined plate, as shown in FIG. 14B;
Step 3, a two-phase integrated inductor 210 and a capacitor 253 are attached to the bottom surface of the rigid-flexible combined plate, and the capacitor 253 can be an input capacitor, an output capacitor, a driving capacitor and the like;
Step 4, de-paneling and forming the rigid-flexible combined plate;
Step 5, pasting solder at the bottom surface of the bottom assembly 300 and bending the rigid-flexible combined plate, so that the bonding pad at the bottom of the bottom assembly 300 coincides with the bonding pad at the bottom of the two-phase integrated inductor 210. the welding of the bottom assembly 300 and the bottom bonding pad of the two-phase integrated inductor 210 is completed. The solder paste can also be disposed on the bonding pads at the bottom of the two-phase integrated inductor 210, and bending the rigid-flexible combined plate, ensuring each bonding pads of the two-phase integrated inductor 210 is overlapped with the corresponding pad on the rigid-flexible combined plate, and finishing the welding process. In this step, some flux can be used.

The preferred embodiment is different from the previous embodiment. The bottom assembly 300 and the rigid adapter plate 257 are synchronously welded when a device is welded on the top surface of the first plate 110, at the moment, the integrated inductor is not introduced for welding. The tolerance can be absorbed through the flexible adapter plate 255/256 during welding the integrated inductor, so that the problem of coplanarity in welding of the inductor not exist in the process shown in the preferred embodiment.

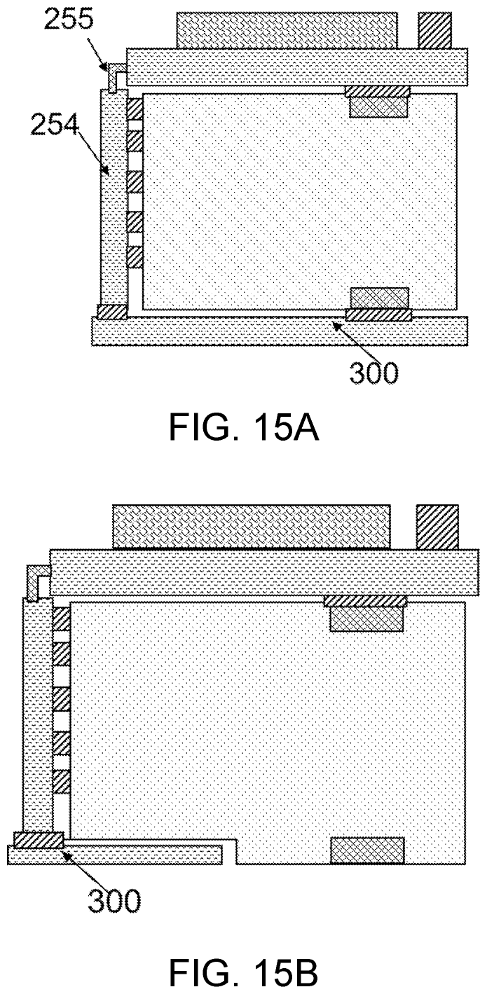

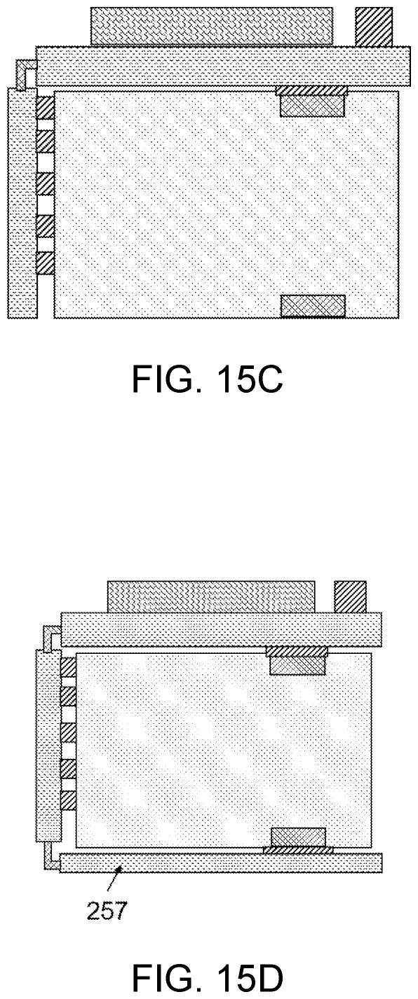

A derivative structure of FIG. 12 is shown in FIG. 15A to 15D. Compared with the structure shown in FIG. 12, in the structure shown in FIG. 15A, a flexible adapter plate 256 and a rigid adapter plate 257 are removed, so that in the welding process with the bottom assembly 300, the height tolerance of the vertical plate 254 and the two-phase integrated inductor 210 is absorbed through the flexible plate 255. Comparing with the structure shown in FIG. 15A, in the structure shown in FIG. 15B, the bottom assembly 300 is directly arranged in the accommodating space of the integrated inductor, so that the overall height of the module is reduced. Compared with the structure shown in FIG. 15B, in the structure shown in FIG. 15C, the bottom assembly 300 is removed, and the height of the module is further reduced. Comparing with FIG. 15A to FIG. 15C, the height of the module shown in FIG. 15B and FIG. 15C is smaller than that of FIG. 15A. It is more flexible in defining the lead-out of the module pin in FIG. 15A. As shown in FIG. 15D, the rigid adapter plate 257 is bent to the bottom of the module to replace the bottom assembly 300, so that the whole module can realize electrical connection from top to bottom only by one plate.

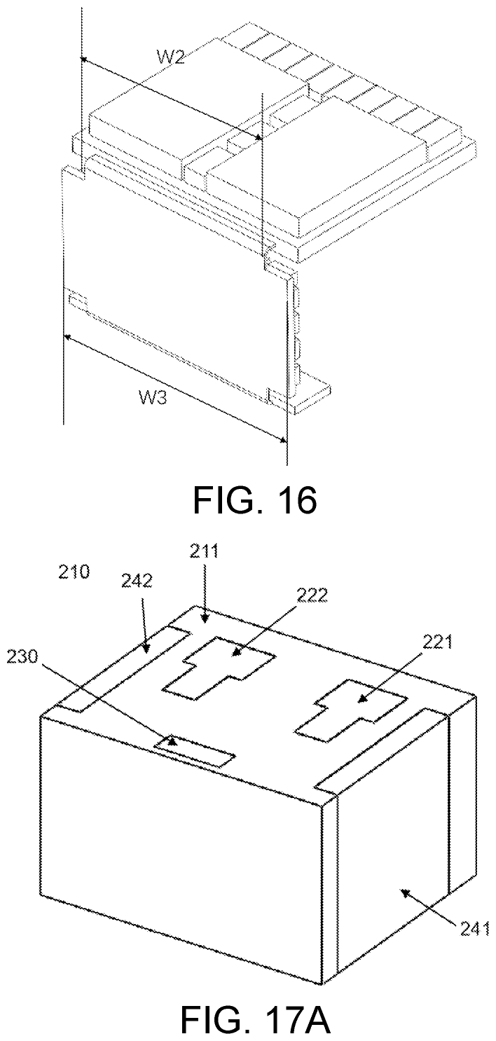

In order to facilitate the structure shown in FIG. 15A to FIG. 15D, the width W2 of the flexible adapter plate can be set to be smaller than the width W3 of the vertical plate 254, as shown in FIG. 16. In this way, the precision of the horizontal direction of the bent vertical plate 254 can be improved through the limiting vertical plate 254 in the bending process. The height tolerance of the flexible adapter plate and the integrated inductor is absorbed through the flexible adapter plate 255.

### Embodiment 11

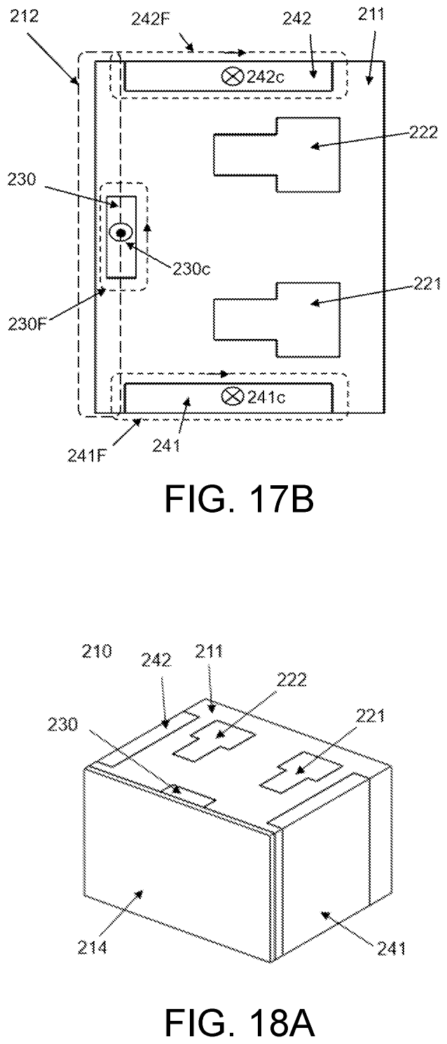

FIG. 17A shows the schematic structural diagram of a two-phase integrated inductor 210 in the embodiment. FIG. 17B shows the top view, and a direction of current flowing through the pads 230C/241C/242C and a direction of the magnetic field around the pads 230F/241F/242F are marked. The embodiment shares the same technical effect as the seventh embodiment, and the first power electric connecting piece 230 is horizontally surrounded by the magnetic material of the magnetic core 211. The difference between the embodiment and the seventh embodiment is that the magnetic core in the embodiment comprises at least two magnetic materials with different relative magnetic permeability. As shown in FIG. 17B, the portion in the dotted line frame is a first magnetic core region 212. The relative permeability of the material of the first magnetic core region 212 is different from that of other parts of the magnetic core 211. In general, the relative magnetic permeability of the first magnetic core region 212 is lower than the relative magnetic permeability of other parts of the magnetic core 211; that is, at least part of the magnetic core material surrounding the first power electric connecting piece 230 has relatively low relative magnetic permeability. The purpose of this arrangement is that the parasitic inductance of the loop formed by the first power electrical connection 230 and the second power electrical connection 241 and 242 can be flexibly adjusted as needed, so that the parasitic inductance can be adjusted flexible, and the resonant frequency of the parasitic inductance and the input capacitance is far lower than the working frequency of the IPM unit. In the present embodiment, if the phases of the two IPM units are same, the resonant frequency is less than or equal to 0.5 times the working frequency of the IPM unit. If the phases of the two IPM units are shifted by 180 degrees, the resonant frequency is less than or equal to the working frequency of the IPM unit. Therefore, so that the ripple current generated by the IPM unit on the parasitic inductance is effectively filtered out.

### Embodiment 12

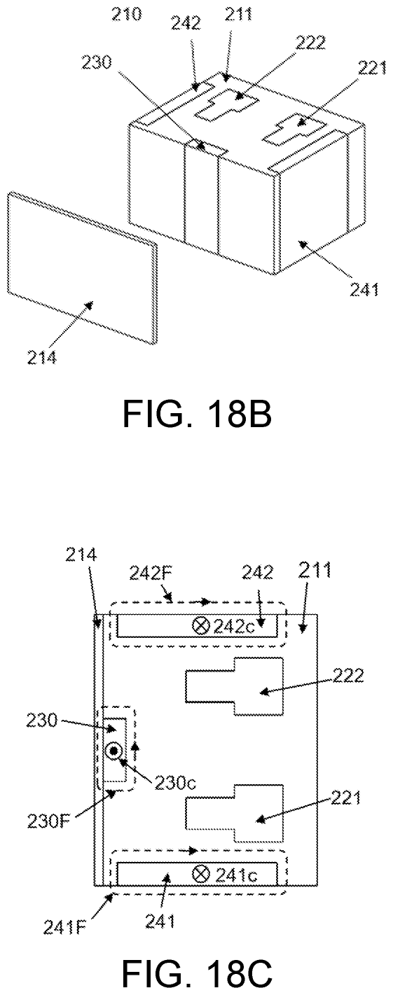

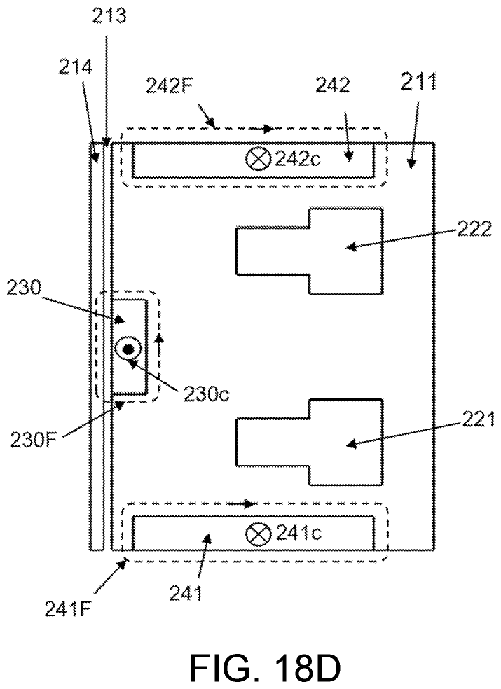

FIG. 18A shows the schematic structural diagram of a two-phase integrated inductor 210 according to an embodiment. FIG. 18B shows the exploded view of FIG. 18A. FIG. 18C shows the top view. A direction of the current flowing through the pads 230C/241c/242c and a direction of the magnetic field around the pads 230F/241f/242f are marked in the figure. The difference between the embodiment and the first embodiment lies in that as shown in FIG. 18A and FIG. 17B. The embodiment comprises a magnetic core 211 and a sheet-shaped magnetic core 214, and the two parts are assembled into a whole. The magnetic core 211 is integrally pressed and formed with the first winding 221, the second winding 222, the first power electric connecting piece 230 and the second power electrical connector 241 and 242. Here, one sidewall of the first power electric connecting piece 230 is exposed to a third side surface of the magnetic core 211; the magnetic core 211 is then adhered with the sheet-shaped magnetic core 214 through glue. FIG. 18D is a top view of a preferred embodiment, that is, an air gap 213 is provided between the sheet-shaped magnetic core 214 and the magnetic core 211. The inductance of the first power electric connecting piece 230 in the magnetic core can be adjusted by adjusting the size of the air gap 213, so that the parasitic inductance of the loop formed by the first power electric connecting piece 230 and the second power electric connecting piece 241 and 242 can be flexibly adjusted according to the application requirement. The resonance frequency of the parasitic inductance and the input capacitor is far lower than the working frequency of the IPM unit. In the embodiment, the manufacturing process of the two-phase integrated inductor 210 is simple and the cost is reduced.

### Embodiment 13

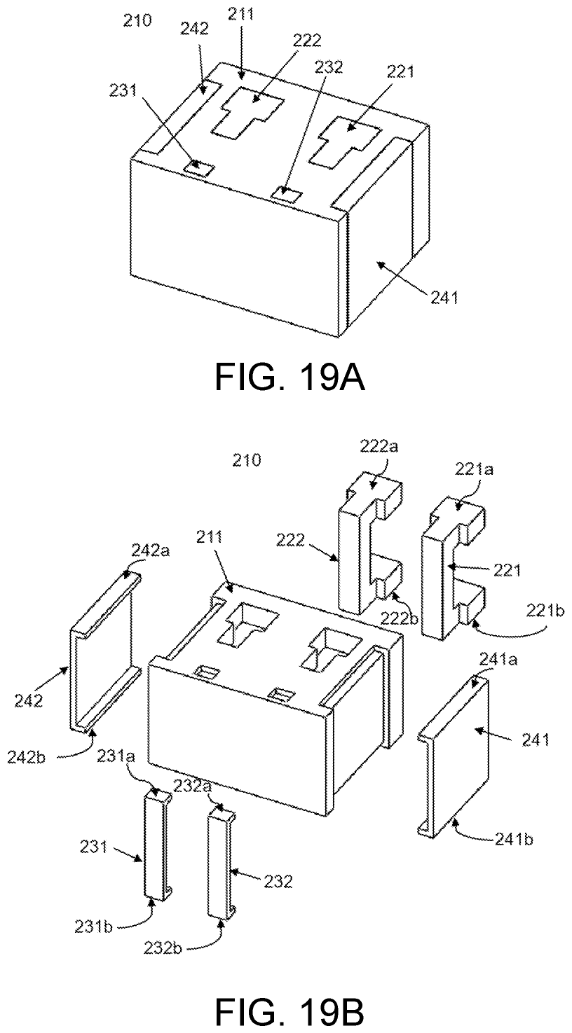

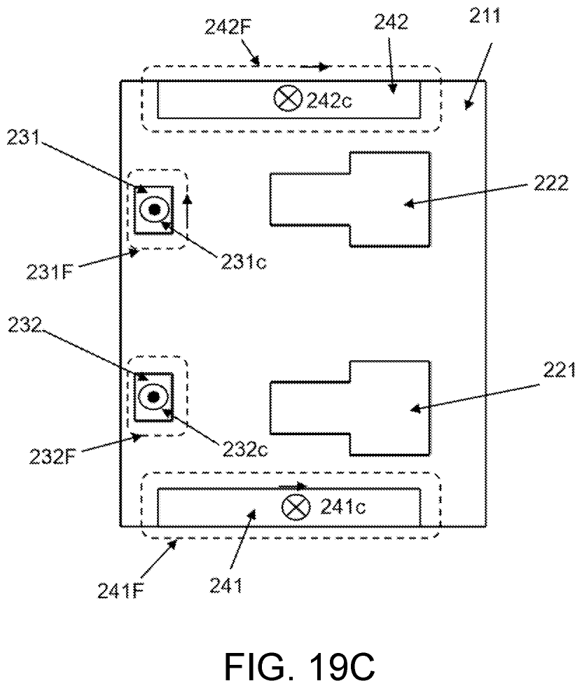

FIG. 19A shows the schematic structural diagram of a two-phase integrated inductor 210. FIG. 19B shows the exploded view of FIG. 19A. FIG. 19C shows the top view. A direction of current flowing through the pads 231c/232c/241c/242C and a direction of the magnetic field around the pads 231F/232F/241F/242F are marked. The present embodiment shares the same technical effect as Embodiment 7. The difference between the embodiment and the seventh embodiment is that the embodiment comprises two first power electrical connector 231 and 232. The two ends of the first power electrical connector 231/232 are respectively connected in parallel on the top assembly and the bottom assembly. When the first power electrical connector is changed from one to two connected in parallel, the parasitic inductance can be reduced to half. Therefore, the parasitic inductance of the power input loop is adjusted by increasing the number of the first power electric connecting pieces, so that the resonance frequency of the parasitic inductance and the input capacitor is far away from the working frequency of the IPM unit. Meanwhile, the manufacturing process of the two-phase integrated inductor 210 is simple in the embodiment.

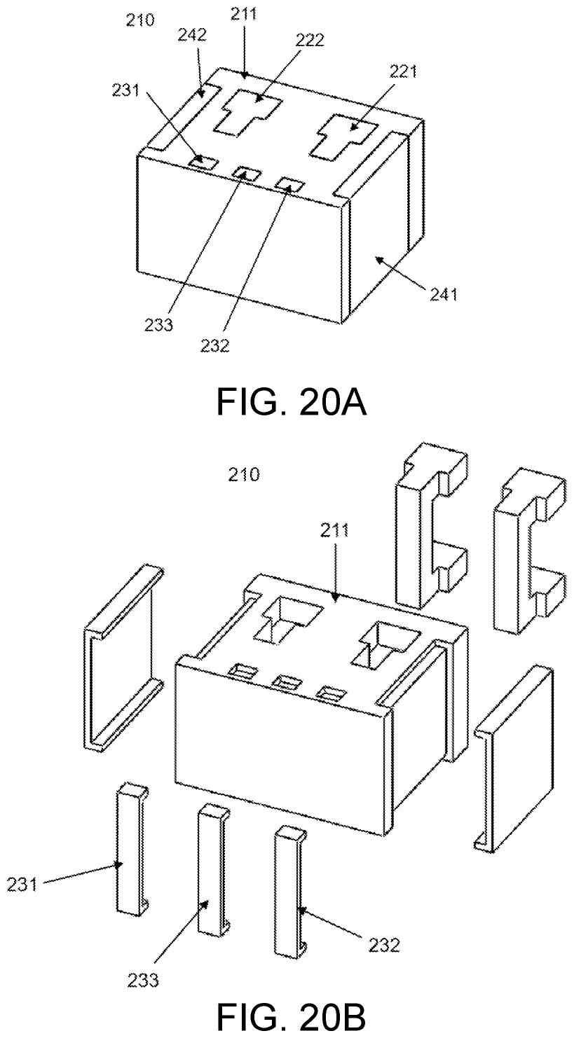

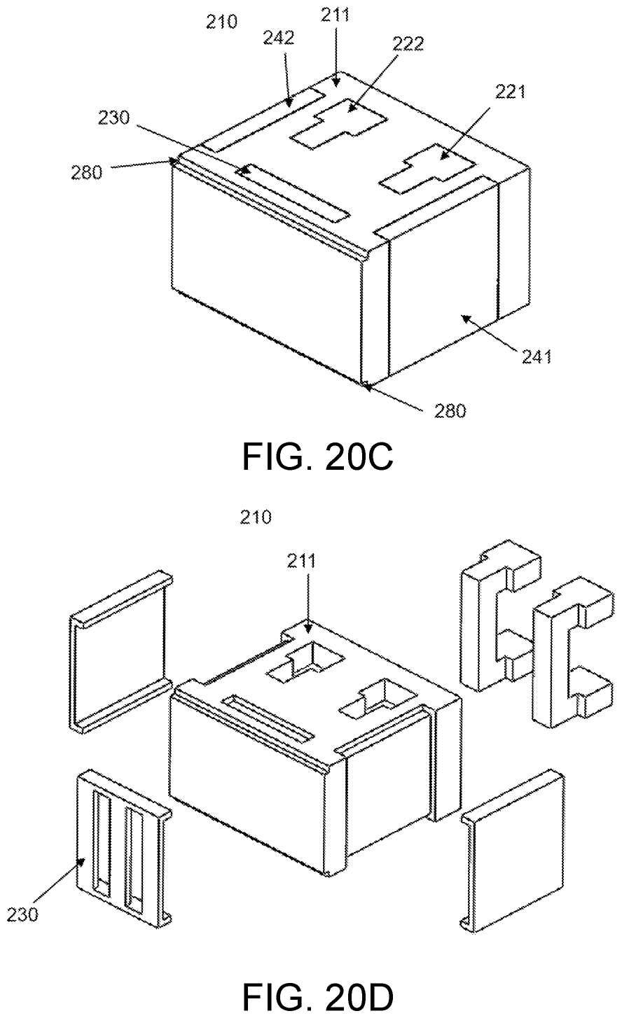

In some other embodiments, as shown in FIG. 20A and FIG. 20B, a parallel first power electric connecting piece 233 is further added on the basis of FIG. 19A. Therefore, the overall parasitic inductance can be reduced to one third. The adjustment range of the parasitic inductance of the power input loop is further increased, so that the resonant frequency of the parasitic inductance and the input capacitor is far away from the working frequency of the IPM unit.

In some other embodiments, as shown in FIG. 20C and FIG. 20D, on the basis of FIG. 20A, the ends of the three first power electric connecting pieces 231/232/233 at the same position are shorted together in the two-phase integrated inductor 210, so that the parallel failure caused by welding can be reduced, and the production efficiency can also be improved.

### Embodiment 14

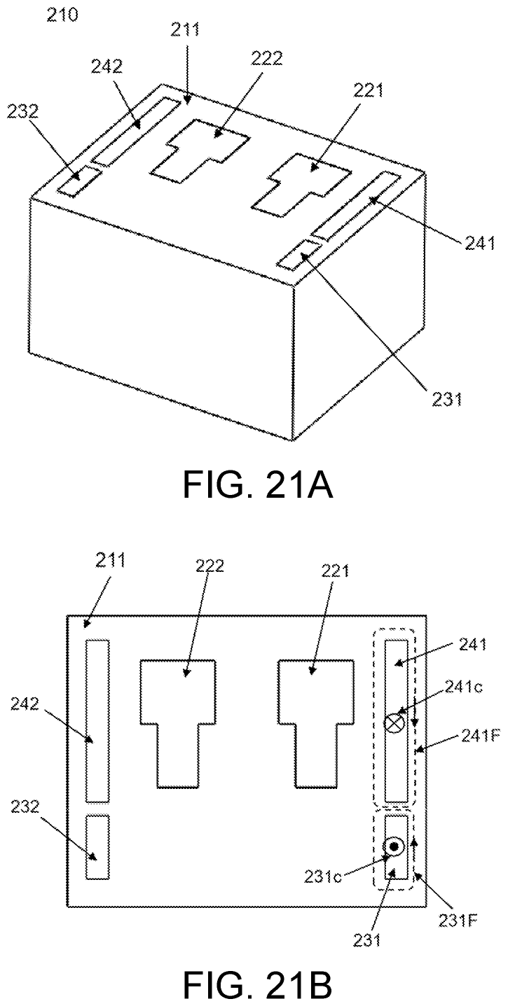

FIG. 21A shows the schematic structural diagram of a two-phase integrated inductor 210 of the embodiment. FIG. 21B shows the top view. A direction of the current flowing through the pads 231c/241c and a direction of the magnetic field around the pads 231F/241F are marked. As shown in FIG. 21A, the first power electric connecting piece 231 in the present embodiment is disposed in a portion of the magnetic core 211 adjacent to the second side surface. The second power electric connecting piece 241 is also disposed in a portion of the magnetic core 211 adjacent to the second side surface. The first power electric connecting piece 231 and the second power electric connecting piece 241 are both horizontally surrounded by the magnetic material of the magnetic core 211. Although the first power electric connecting piece 231 and the second power electric connecting piece 241 are horizontally surrounded by the magnetic material of the magnetic core 211, the parasitic inductance of the power input loop rises. However, because the first power electric connecting piece 231 is adjacent to the second power electric connecting piece 241, the increasing value of the parasitic inductance is limited in an acceptable range. Similarly, the first power electric connecting piece 232 is disposed in a portion of the magnetic core 211 adjacent to the fourth side surface. The second power electric connecting piece 242 is also disposed in a portion of the magnetic core 211 adjacent to the fourth side surface. Finally, the parasitic inductance generated after parallel connection of the two power input loop is controlled. Here, the first power input loop comprises the first power electric connecting piece 231 and the second power electric connecting piece 241, the second power input loop comprises the first power electric connecting piece 232 and the second power electric connecting piece 242. The resonant frequency of the equivalent parasitic inductance and the input capacitor is far away from the working frequency of the IPM unit.

### Embodiment 15

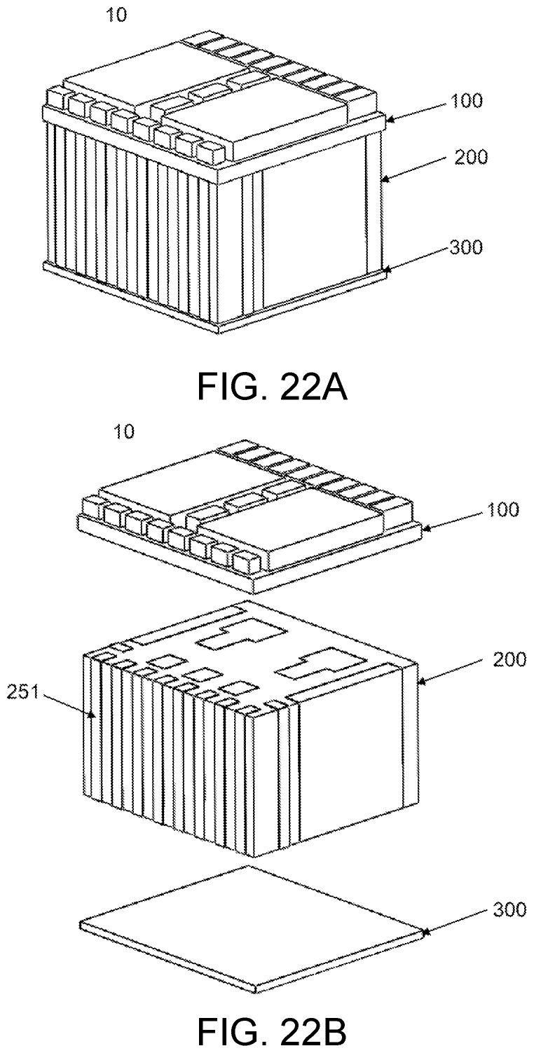

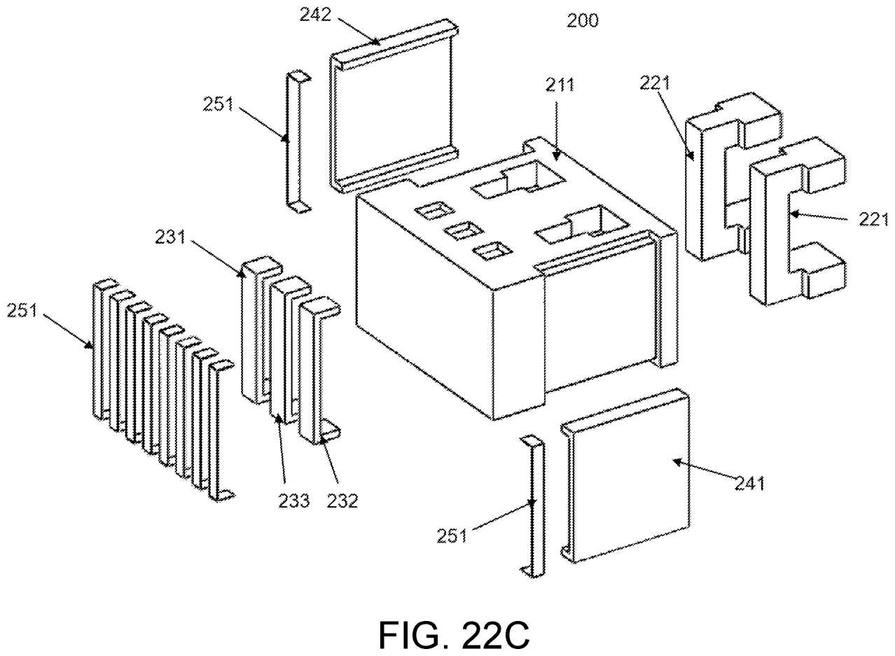

FIG. 22A shows the schematic structural diagram of a two-phase VRM module 10 according to an embodiment. FIG. 22B shows the exploded view of FIG. 22A. FIG. 22C shows the exploded view of the intermediate assembly 200. The present embodiment shares the same technical effect as Embodiment 7. The difference between the present embodiment and Embodiment 7 lies in the function of the signal electric connecting piece 251 which is implemented by the electroplating process, instead of the process of erecting a PCB (ie, the vertical plate 250) in Embodiment 7. Because the vertical PCB needs to be welded to the top assembly 100 and the bottom assembly 300 through the ends after assembling with the integrated inductor. Due to the fact that the assembly tolerance exists, there is risk of getting poor quality in the welding process. In this embodiment, the signal electrical connector 251 is formed by electroplating, so that the assembly tolerance can be eliminated, and the welding quality is ensured, and the reliability of the product is improved. the first power electrical connector 231/232/233 is arranged in the magnetic core 211, so that the third side surface, part of the second side surface and the part of the fourth side surface of the intermediate assembly 200 can be used for arranging the electroplated signal electric connecting piece 251. The distance between any two signal electric connecting piece 251 is guaranteed, so that good electroplating quality is achieved.

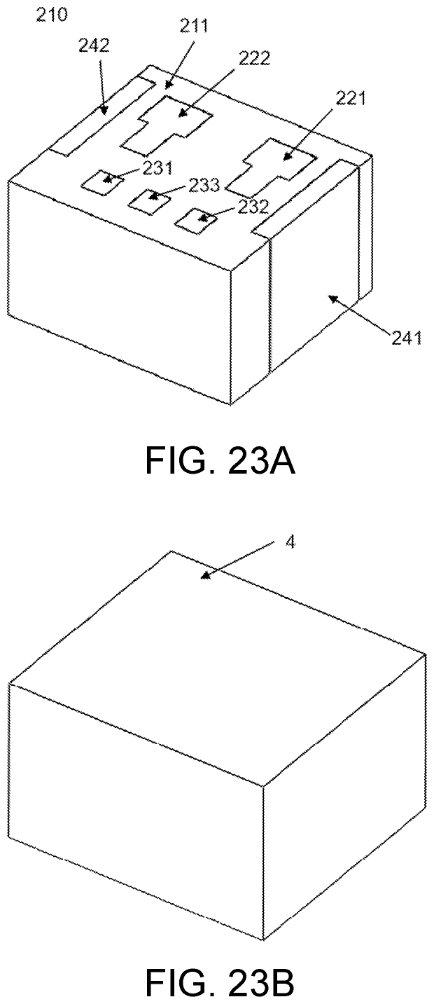

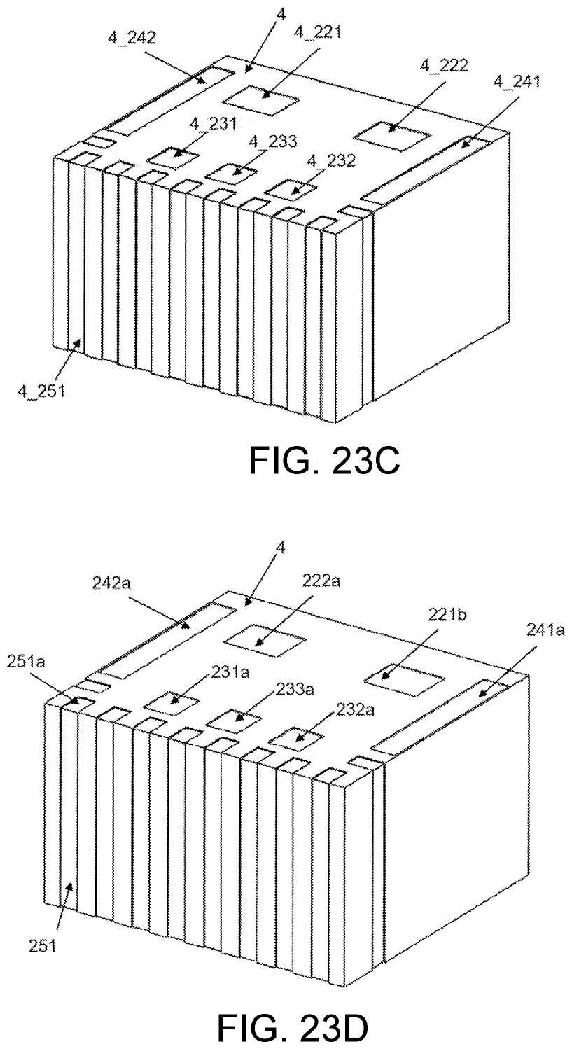

Next, the electroplating process of the signal electric connecting piece 251, the power connector and the winding pad is set forth in FIG. 22A:
Step 1: as shown in FIG. 23A, a magnetic core 211, a first winding 221, a second winding 222, a first power electrical connector 231, a first power electric connecting piece 232, a first power electrical connector 233, a second power electric connecting piece 241 and a second power electric connecting piece 242 are integrally pressed and formed a bare inductor;
Step 2, after the bare inductor prepared in Step 1 is infiltrated and baked, a layer of glue needs to be sprayed, and the process is called Coating. As shown in FIG. 23B, the cross section of the windings which exposed outside the magnetic core 211, and the cross section of the first power electrical connector 231/232/233 and the second power electric connecting piece 241/242 which exposed outside the magnetic core are all wrapped by coating glue 4. The thickness of the coating glue 4 is 20 um or above. In the embodiment, the effect of coating is to prevent external water vapor from entering the magnetic core, preventing the magnetic core from being oxidized and rusting and failing.
Step 3: as shown in FIG. 23C, the coating glue of some positions need to be removed. The positions include position 4_251 requiring to dispose the signal electric connecting piece 251, the positions requiring to dispose pads of the first power electric connecting piece 231/232/233 and the second power electric connecting piece 241/242(such as positions 4_231, 4_232, 4_233, 4_241 and 4_242), the positions requiring to dispose pads of the first winding 221 and the second winding 222(such as 4_221 and 4_222). The coating glue at the positions can be removed through laser. The part of the coating glue 4 is removed to expose the body of the magnetic core 211, such as the position 4_251. Or, the copper cross section is exposed, such as positions 4_231, 4_232, 4_233, 4_241, 4_242, 4_221 and 4_222.
Step 4: The inductor obtained in Step 3 is subjected to an electroplating process. Acid pickling needs to be carried out before electroplating, so that the electroplating surface is kept clean; baking is needed after electroplating, and moisture absorbed by the magnetic core in the electroplating process is eliminated. Electroplating three layers of metal is usually needed in the process. For example, the first electroplating layer is copper, the second electroplating layer is nickel, the third electroplating layer is tin. After electroplating is completed, a finished product inductor shown in FIG. 23D can be obtained. Electroplating implements the pads of the signal electric connecting piece 251, the pads 231a/232a/233a/231b/232b/233b (231b/232b/233b not shown) of the first power electric connecting piece 231/232/233, the pads 241a/242a/241b/242b(241b/242b not shown) of the second power electric connecting piece 241/242, and the pads 221a/222a/221b/222b (221b/222b not shown) of the first winding 221 and the second winding 222. The integrity of the coating layer 4 still needs to be maintained at the part without the need for electroplating.

### Embodiment 16

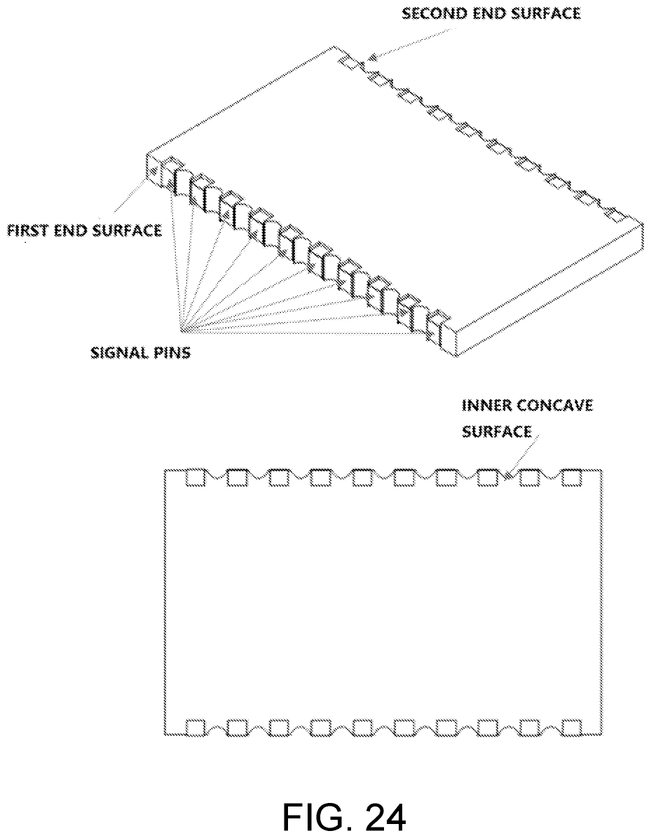

FIG. 24 shows the schematic structural diagram of a vertical plate 250 in the embodiment, wherein the upper figure in FIG. 24 is a perspective view and the lower figure in FIG. 24 is a top view. The vertical plate 250 of the present embodiment can be applied to the above embodiments (in addition to the fifth embodiment). The signal PIN (ie, the end portion or the pads of the signal electric connecting piece) is located on the first end face and the second end face of the vertical plate 250. The first end face is used for connecting with the top assembly 100. The second end face is used for connecting with the bottom assembly 300. The first end face and the second end face comprise a plurality of signal PINs, the signal PINs on the two end faces are connected through wiring in the vertical plate 250. The signal PIN located on the first end face/the second end face extends to the side surface of the vertical plate 250 from the end face to which the signal PIN belongs. Compared with the embodiment shown in FIG. 11A to 11F (the same potential signal PINs are separated by the dielectric layer). The welding end face of he signal PIN is enlarged, so that the signal PIN can be better connected with the top assembly 100 and the bottom assembly 300, and the reliability is improved. The first end face and the second end face of the vertical plate 250 further comprise a plurality of inner concave faces. The inner concave faces are located between the signal PINs and separate the adjacent signal PINs, especially the signal PINs with different signals. A good exhaust channel can be provided for the reflow soldering process, and short circuits between the signal PINs are avoided.

In a preferred embodiment, the signal PINs which are closest to the short side can extend towards the short side to increase the welding area of the signal PINs The stress of the bonding pad on the edge is larger than the stress of the bonding pad on the inner side due to the array type bonding pad, so that the welding reliability can be further improved in this embodiment.

Next, the processing flow of the vertical plate 250 shown in FIG. 24 is described as follows:

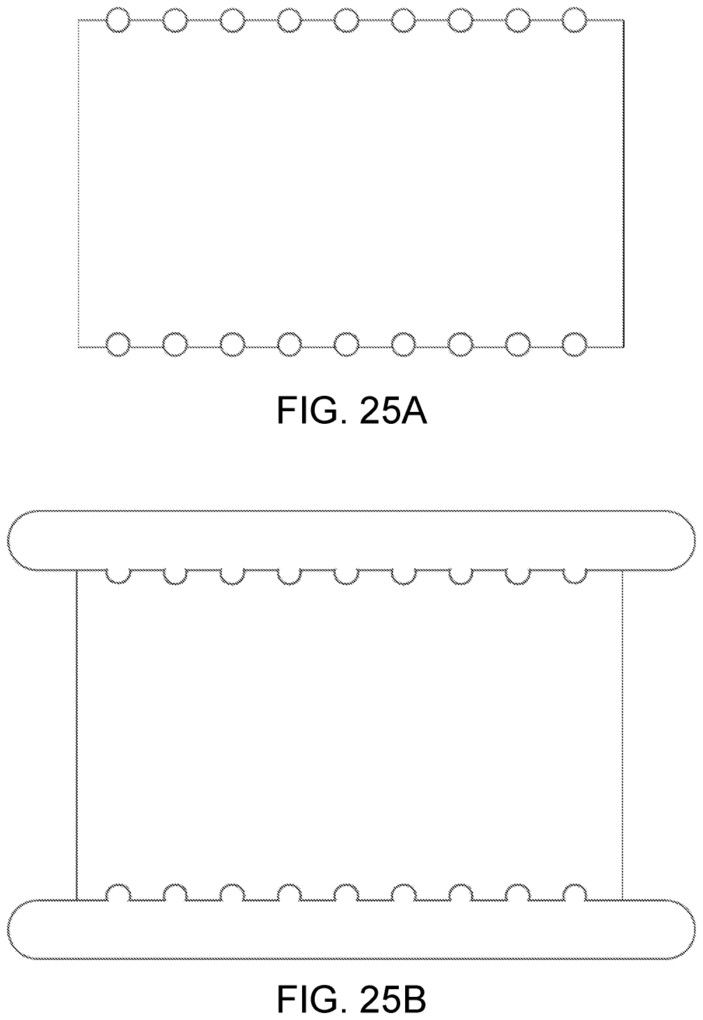

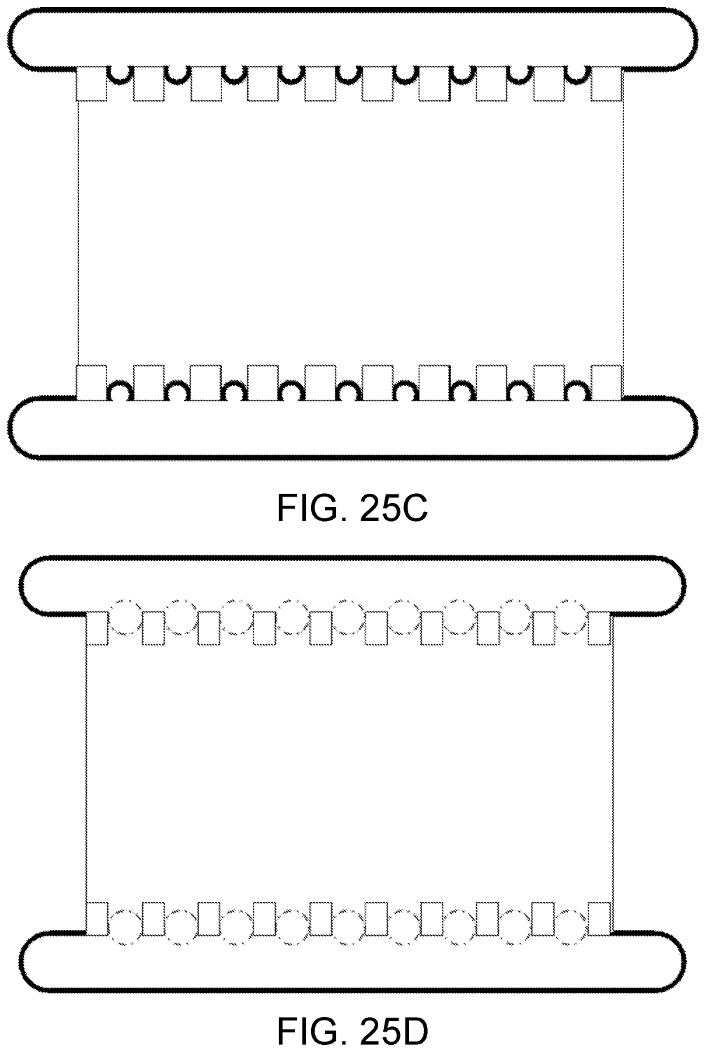

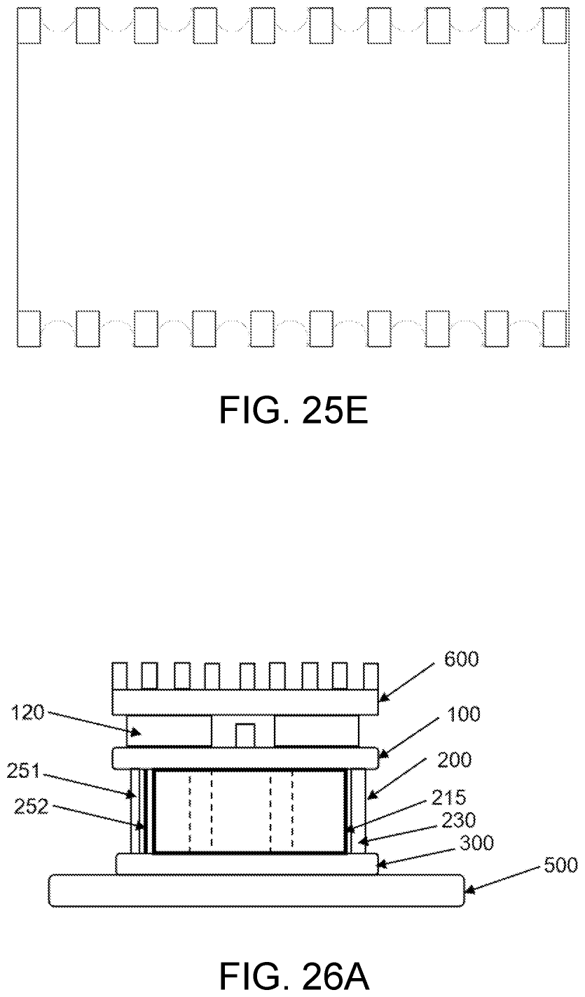

Step 1, drilling a plate edge after lamination; laminating the core plate, the PP sheet and the base copper, carrying out high-temperature curing and integrated forming, and then forming a plurality of through holes at the edge of each unit through a drilling process, as shown in FIG. 25A;

Step 2, groove milling is carried out on the edge of the plate; a groove is milled in the edge of each unit to form a penetrating slotted hole, as shown in FIG. 25B;

Step 3, metalizing of the plate edge; electroplating a whole plate through a metal chemical process; and forming a desired circuit pattern through an etching process. Due to the fact that the copper foil in the slotted hole cannot be damaged, the copper foil of the slotted hole needs to be protected in the etching process, and electroplating tin on the surface before etching to serve as a protective layer, as shown in FIG. 25C;

Step 4, drilling at a plate edge; removing the metal in each hole through a drilling process by taking the hole in the step 1 as a guide hole to form signal pins of different electrodes, wherein the drilling diameter of step 4 is larger than that of the step 1, as shown in FIG. 25d; Step 5, de-paneling and forming independent units, as shown in FIG. 25E.

### Embodiment 17

According to the VRM module in the application, the core structure of the VRM module is that the switching device is arranged on a first plate (equivalent to a top assembly) of the top surface. The passive device is arranged below the switching device. The lower part of the passive device supplies power to the load through an adapter plate or a direct connection load. The switch device serving as a heat source is arranged on the top surface and can directly dissipate heat through the radiator, so that the thermal resistance of the module in the vertical direction is extremely small. In the prior art, a switch device of the VRM module is arranged below. The passive device is arranged above. Heat generated in the working process of the switch device can only be dissipated through the load mainboard below. The heat dissipation capacity of the load mainboard is limited, so that the VRM module of a traditional structure limits the space for further improving the power density.

With the progress of the technology, all the power converter modules share the requirements of high efficiency, high power density and good heat dissipation capability; therefore, the VRM module structure can be applied to all power converter modules to improve the heat dissipation capability and the power density; and the power is pushed to a higher level.

However, according to the module structure, the switch device is arranged on the top surface. The passive device is arranged below the switch device. The load mainboard is arranged below the passive device. Therefore, transmission of input power and output power needs to be realized between the switch device on the top surface and the load mainboard on the bottom surface. The transmission of the input power and the output power is mainly realized through a winding or a power connector. Meanwhile, signal transmission needs to be achieved between the switch device and the load mainboard. For example, current detection IMON (such as input current, output current, current of the switch device and the like), temperature detection TMON (such as environment temperature and device temperature), voltage detection signal Vsense (such as input voltage, output voltage and the like), current sharing signal Isense and other signals. The signals are essentially analog signals. In the modular structure of the present application, the signals are to pass vertically to the top assembly and the load mainboard, ie, parallel with the passive devices arranging in the middle (eg, magnetic elements, inductors, transformers, capacitors, etc.). Due to the fact that the switching frequency is high, the voltage change rate on the winding is large. The rapidly changing voltage on the winding is coupled to the signal electric connecting piece through the parasitic capacitor, so that the signal electrical connector has electric field interference. On the other hand, the rapidly changing current can generate high-frequency magnetic field interference through the magnetic core. Therefore, the signal electrical connector needs to eliminate the interference of the electromagnetic field in a certain mode, and it is ensured that the signal has an anti-interference function.

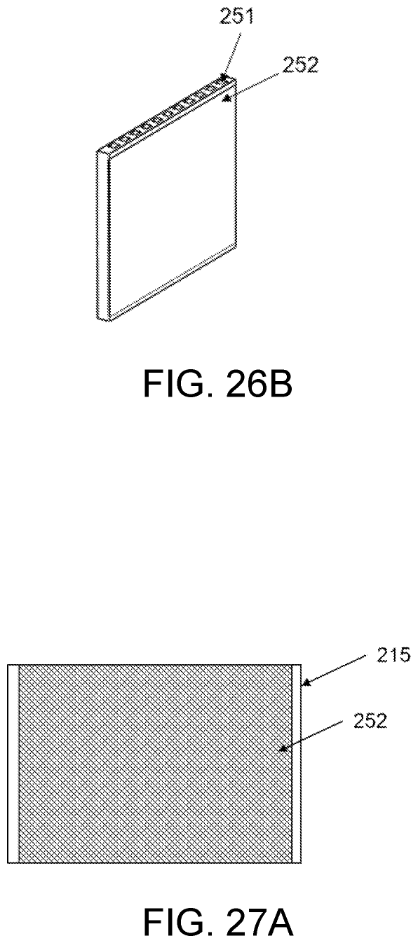

As shown in FIG. 26A, the top assembly 100 comprises a first plate. The switch device 120 is arranged on the first plate and can be a metal oxide field effect transistor (MOSFET), a diode (Diode) and the like. The intermediate assembly 200 is an integrated passive device, and comprises an inductor, a transformer, etc. For example, a two-phase integrated inductor 210, and the dotted line shows a winding therein; the side surface or the side part of the integrated passive device is provided with a power electric connecting piece for connecting the first plate and the load mainboard 500, which comprises a first power electric connecting piece and a second power electric connecting piece; the bottom assembly 300 comprises an adapter plate which is arranged between the integrated passive device and the load mainboard. In some embodiments, the function of the bottom assembly 300 can be integrated on the intermediate assembly 200; the signal electric connecting piece 251 and the metal shielding layer 252 are arranged on one side surface of the intermediate assembly 200 (the signal electric connecting piece 251 and the power electric connecting piece can be arranged on the opposite, same or adjacent side surfaces in the actual module structure in order to conveniently show the signal electric connecting piece 251 and the metal shielding layer 252 on the left side of the intermediate assembly 200); the metal shielding layer 252 can be connected with any one of static potential connecting point such as PGND, AGND, VIN, VO, VDD and VDRV in the module, realizing shielding of an electric field; therefore, the anti-interference capability of the signal electrical connector 251 is realized; the signal electric connecting piece 251 and the metal shielding layer 252 may be integrated into one PCB by means of a PCB process to achieve a shielding function, as shown in FIG. 26B. In the power converter module, a flexible PCB or a rigid-flexible printed circuit board (PCB) process of the embodiments shown in FIG. 11A to FIG. 15D may also be used to achieve the function of electromagnetic shielding.

### Embodiment 18

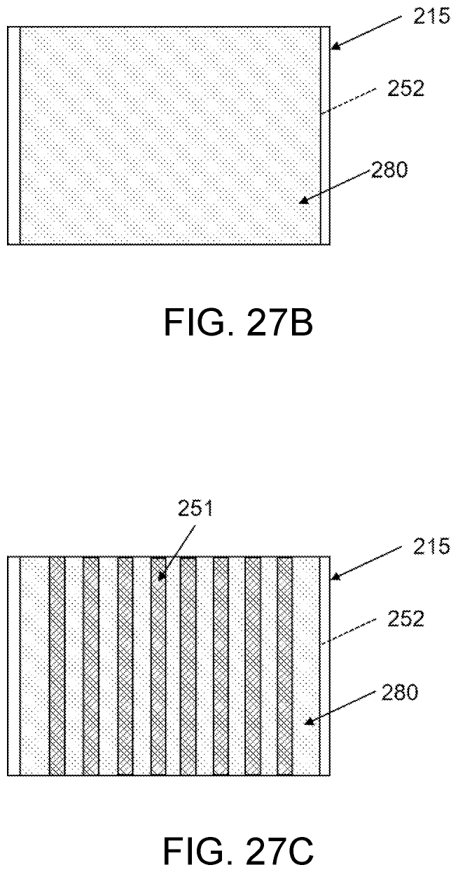

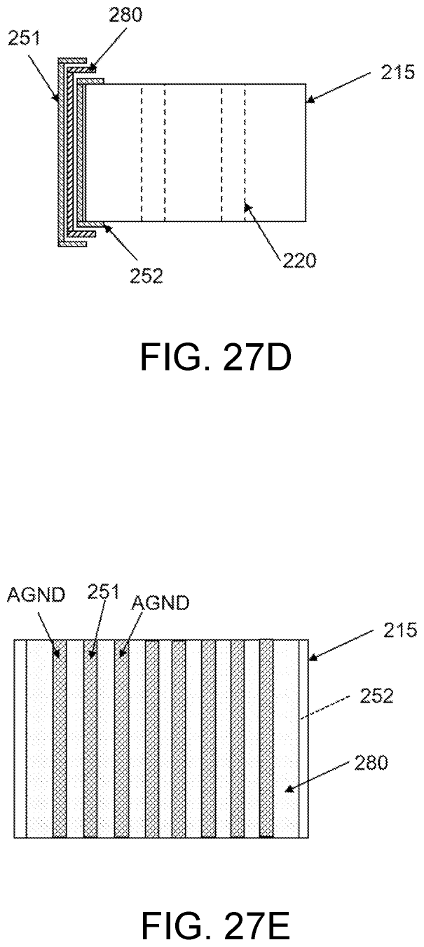

The embodiment is a setting mode of the signal electric connecting piece and the shielding layer in FIG. 26A. As shown in FIG. 27A, a layer of metal is first electroplated on the passive device 215 as the metal shielding layer 252; and then a layer of insulating layer 280 is arranged on the surface of the metal shielding layer 252, as shown in FIG. 27B; and then the signal electric connecting piece 251 is electroplated on the insulating layer 280 to realize a signal connection function, as shown in FIG. 27C; FIG. 27D shows the side view. The metal shielding layer 252 shown in FIG. 27D can also be a whole copper foil and is adhered to the magnetic core to achieve the shielding effect; the signal electric connecting piece 251 can also be realized by pasting a metal sheet, and the dotted line frame in the figure is a winding area 220;

The AGND signal electric connecting piece is further added, the easily interfered signal is arranged at the position close to the AGND, the loop area of the signal electrical connector 251 is reduced, and as shown in FIG. 27E, the amplitude of magnetic field interference is reduced.

### Embodiment 19

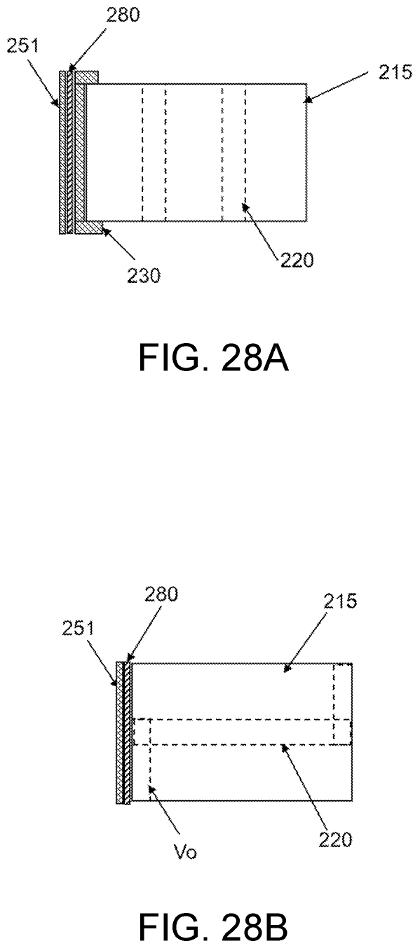

The embodiment is another arrangement mode of the signal electric connecting piece and the shielding layer. As shown in FIG. 28A, a side surface of the passive device 215 is integrated with a power electric connecting piece, such as a first power electric connecting piece 230 (ie, Vin+); and in some other embodiments, the first power electric connecting piece 230 may also be an output power electric connecting piece Vo+. An insulating layer 280 is arranged on the outer side of the first power electric connecting piece 230; and the signal electrical connector 251 is realized on the outer side of the insulating layer 280 in an electroplating mode. Vin+ or Vo+ serving as a static potential plays a role of a shielding layer; or as shown in FIG. 28B, the output end of the winding is close to the side surface where the signal electric connecting piece 251 is located, the insulating layer 280 is arranged on the outer side of the side surface, the signal electric connecting piece 251 is achieved in the same mode on the insulating layer 280, and the output end of the winding serves as a static potential connecting point, so that the electric field shielding effect is achieved; and the arrangement has the advantages that the space is saved and the power density can be further improved.

### Embodiment 20

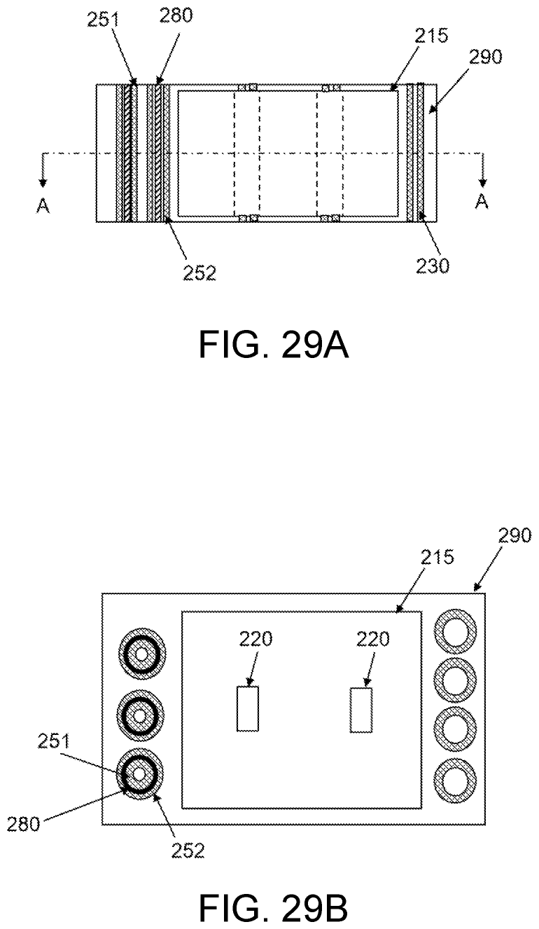

The embodiment is another arrangement mode of the signal electric connecting piece and the shielding layer. FIG. 29B shows the cross-sectional view of the position A-A in FIG. 29A. As shown in FIG. 29A, the passive device 215 (the integrated inductor) is completely embedded in the PCB 290; and the first power electric connecting piece 230 realizes the transmission between the top assembly and the bottom assembly in a through hole mode; and the signal electric connecting piece 251 also realizes signal transmission in a through hole mode. In order to realize electromagnetic shielding on the signal electrical connector 251. As shown in FIG. 29B, electromagnetic shielding of the signal is realized in a two-time electroplating mode, that is drilling a through hole in the PCB, and the metal shielding layer 252 is electroplated; then a layer of insulating layer 280 is arranged; a signal electric connecting piece 251 is electroplated in the insulating layer 280; the electroplating layer 251 of the inner layer is completely surrounded by the electroplated layer 252 on the outer layer; the electroplated layer 252 of the outer layer is connected with the static potential connecting point, so that the shielding of the electromagnetic field can be realized; and the electromagnetic shielding effect is more thorough, and the process compatibility with the PCB is good.

What is claimed is:

1. A VRM module, comprising: an integrated inductor, a top assembly and a vertical plate;
wherein the integrated inductor comprises a magnetic core, a first winding and a second winding, wherein the integrated inductor is provided with a first side surface, a second side surface, a third side surface and a fourth side surface, and the second side surface and the fourth side surface are adjacent to the third side surface respectively; the vertical plate comprises a signal electrical connector; the vertical plate is arranged on the third side surface of the integrated inductor;
wherein the first winding and the second winding are respectively provided with a first winding bonding pad on a top surface of the integrated inductor, and the first winding and the second winding are respectively provided with a second winding bonding pad on a bottom surface of the integrated inductor; the first winding bonding pad is arranged on the first side surface or close to the first side surface;
wherein the top assembly is arranged on the top surface of the integrated inductor and is electrically connected with the first winding bonding pad, the top assembly comprises a semiconductor switching device, and the first winding bonding pad is vertically corresponding to the connecting end of the corresponding semiconductor switching device;
wherein the VRM module further comprises a first power electric connecting piece and a second power electric connecting piece, the first power electric connecting piece and the second power electric connecting piece form a first connecting piece bonding pad on the top face of the integrated inductor respectively, and the first connecting piece bonding pad is connected with the corresponding semiconductor switching device; the first power electric connecting piece and the second power electric connecting piece form a second connecting piece bonding pad on the bottom face of the integrated inductor respectively, the second connecting piece bonding pad is used for connecting input terminals with different potentials, and the input terminals is a power input terminals;
wherein an electrical loop formed by the first power electric connecting piece, the second power electric connecting piece, and the semiconductor switching device is disposed about at least a portion of the magnetic core.

2. The VRM module of claim 1, wherein the VRM module further comprises a bottom assembly,
wherein the bottom assembly is arranged on the bottom surface of the integrated inductor and is electrically connected with the second winding bonding pad and the second connecting piece bonding pad, and the bottom assembly is used for being connected with a load; the top assembly is in signal connection with the bottom assembly through a signal electric connecting piece,
wherein the first power electric connecting piece is arranged on the third side surface of the integrated inductor or is close to the third side surface of the magnetic core,
wherein the second power electric connecting piece is arranged on the second side surface and the fourth side surface, or the second power electric connecting piece is arranged at a position, close to the second side surface and close to the fourth side surface, of the magnetic core.

3. The VRM module of claim 2, wherein the first power electric connecting piece is a VIN electric connecting piece, the second power electric connecting piece is a GND electric connecting piece, a cross-sectional area of the GND electric connecting piece is greater than a cross-sectional area of the VIN electric connecting piece, and a common potential pad of a signal electric connecting piece in the vertical plate comprises at least two discontinuous metal surfaces.

4. The VRM module of claim 3, wherein an input capacitor and an output capacitor are further included, at least a part of the input capacitor is arranged on the top assembly and/or the vertical plate, and at least a part of the output capacitor is arranged on the bottom assembly and/or the vertical plate.

5. The VRM module of claim 4, wherein at least a part of the output capacitor is arranged on the vertical plate, and a second winding bonding pad is arranged close to the third side surface, or the output capacitor is not arranged on the vertical plate, and the second winding bonding pad is arranged close to the first side surface.

6. The VRM module of claim 2, wherein the bottom assembly comprises a plurality of copper columns, and the positions of the copper columns correspond to the positions of the second winding bonding pads and the second connection bonding pads respectively.

7. The VRM module of claim 2, wherein the second winding bonding pad and the second connecting piece bonding pad protrude out of the bottom surface of the magnetic core, and pads or grooves corresponding to the positions of the second winding bonding pad and the second connecting piece bonding pad are formed in the bottom assembly.

8. The VRM module of claim 2, wherein the VRM module further comprises at least one flexible adapter plate, and the top assembly is electrically connected with the vertical plate through at least one flexible adapter plate;
wherein the bottom assembly is electrically connected with the vertical plate through at least one flexible adapter plate,
or, the VRM module further comprises a rigid adapter plate, the rigid adapter plate is electrically connected with the vertical plate through at least one flexible adapter plate, the rigid adapter plate is arranged between the magnetic core and the bottom assembly, and the rigid adapter plate is electrically connected with the bottom assembly.

9. The VRM module of claim 2, wherein the second winding bonding pad is arranged on the first side surface or close to the first side surface, or the second winding bonding pad is arranged on the third side surface or close to the third side surface.

10. The VRM module of claim 9, wherein the first winding bonding pad is arranged close to the first side surface, and the second winding bonding pad is arranged close to the first side surface so that any part of the first winding and the second winding is surrounded by the magnetic core; and the first winding bonding pad is arranged close to the first side surface, and the second winding bonding pad is arranged close to the third side surface, so that any part of the first winding and the second winding is surrounded by the magnetic core.

11. The VRM module of claim 2, wherein the first power electric connecting piece is arranged at the position, close to the third side surface, of the magnetic core, that is, the first power electric connecting piece is arranged in the magnetic core and close to the third side surface.

12. The VRM module of claim 2, wherein the first power electric connecting piece and the second power electric connecting piece are both rectangular copper sheets.

13. The VRM module of claim 12, wherein tail ends of the first connecting piece bonding pad and the second connecting piece bonding pad are arc-shaped.

14. The VRM module of claim 12, wherein at least two bosses are arranged on the third side surface of the magnetic core, grooves are formed between the bosses, and the vertical plate and the magnetic core are assembled together through the bosses.

15. The VRM module of claim 14, wherein the boss of the magnetic core is provided with a chamfer, a groove or an avoidance groove, and the groove and the avoidance groove are used for avoiding a side surface pad of the vertical plate.

16. The VRM module of claim 12, wherein a solder resistant interval is formed between the signal electric connecting pieces of the vertical plate by means of a PCB substrate, and a height of the PCB substrate is lower than a height of the signal electric connecting piece.

17. The VRM module of claim 12, wherein the integrated inductor further comprises a first auxiliary winding and a second auxiliary winding, wherein the first winding and the first auxiliary winding are coupled to each other, and the second winding and the second auxiliary winding are coupled to each other to implement a TLVR function.

18. The VRM module of claim 11, wherein the magnetic core comprises at least two magnetic materials with different relative magnetic permeability, and a relative permeability of the magnetic material arranged in a first magnetic area is lower than that of other areas, wherein the first magnetic area is an area horizontally surrounding the first power electric connecting piece.

19. The VRM module of claim 18, wherein the magnetic core comprises a magnetic core main body and a sheet-shaped magnetic core, the sheet-shaped magnetic core is arranged on the third side surface of the magnetic core main body, and one side wall of the first power electric connecting piece is exposed to the third side surface of the magnetic core main body.

20. The VRM module of claim 19, wherein an air gap is formed between the sheet-shaped magnetic core and the magnetic core main body, and the air gap is used for adjusting the inductance of the first power electric connecting piece in the magnetic core by adjusting the size of the air gap.

21. The VRM module of claim 11, wherein there are at least two first power electric connecting pieces, and the first power electric connecting pieces are connected in parallel.

22. The VRM module of claim 21, wherein the ends at the same position between the first power electric connecting pieces are short-circuited together.

23. The VRM module of claim 21, wherein there are two first power electric connecting pieces, which are respectively arranged close to the second side surface and the fourth side surface; and the second power electric connecting piece is also arranged in the magnetic core and close to the second side surface and the fourth side surface respectively.

24. The VRM module of claim 11, wherein the vertical plate is only provided with a signal electric connecting piece, and the signal electric connecting piece is arranged on the third side surface by electroplating.

25. The VRM module of claim 2, wherein a first end face and a second end face of the vertical plate are provided with signal pins, the first end face is used for being connected with the top assembly, the second end face is used for being connected with the bottom assembly, signal pins on the two end faces are connected through wiring in the vertical plate, and signal pins located on the first end face and the second end face extend to the side surface of the vertical plate from the end face to which the signal pins belong.

26. The VRM module of claim 25, wherein the first end face and the second end face of the vertical plate further comprise a plurality of inner concave faces, and the inner concave faces are located between signal pin specific electrodes and used for isolating adjacent signal pins and providing a good exhaust channel in reflow soldering process.

27. The VRM module of claim 2, wherein the vertical plate only comprises a signal electric connecting piece and an insulating layer, the insulating layer is arranged on the outer side of the first power electric connecting piece, and the signal electric connecting piece is arranged on the outer side of the insulating layer in an electroplating mode; and the first power electric connecting piece serves as a static potential connecting point.

28. The VRM module of claim 2, wherein the integrated inductor is completely embedded in a PCB, and the first power electric connecting piece realizes the transmission between the top assembly and the bottom assembly by means of providing a through hole on the PCB; and the signal electric connecting piece implements signal transmission by means of a through hole.

29. The VRM module of claim 28, wherein the signal electric connecting piece implements signal transmission by means of forming a through hole in the PCB, electroplating a metal shielding layer in the through hole, then providing an insulating layer on the surface of the metal shielding layer, and then electroplating a signal electric connecting piece on the surface of the insulating layer, wherein the metal shielding layer is connected to the static potential connecting point.

30. A manufacturing method of the VRM module of claim 2, wherein the VRM module further provides a manufacturing method of the VRM module, the VRM module further comprises an input capacitor and an output capacitor;
wherein the first power electric connecting piece is arranged on the third side surface of the integrated inductor or arranged at the position, close to the third side surface, of the magnetic core, specifically, the first power electric connecting piece is arranged on the third side surface of the integrated inductor or arranged in the magnetic core or close to the third side surface;
wherein the manufacturing method comprises the following steps,
S1: preparing the integrated inductor, wherein the integrated inductor is integrally formed by the magnetic core, the first winding, the second winding, the first power electric connecting piece and the second power electric connecting piece;
The vertical plate is prepared, the signal electric connecting piece and a metal shielding layer are arranged on the vertical plate, a part of the input capacitor and/or the output capacitor are attached to the vertical plate, and the vertical plate is formed by depositing an upper passivation layer after copper foil is exposed through a PCB edge milling process;
S2: fixedly connecting the vertical plate and the integrated inductor through gluing, enabling at least one part of the metal shielding layer to be located between the signal electric connecting piece and the magnetic core, and controlling a flatness tolerance of the bonding pad assembled by the vertical plate and the integrated inductor to be within 50 μm;
S3: preparing a third PCB provided with at least part of an output capacitor, carrying out adhesive dispensing on the third PCB, welding an integrated inductor connected with a vertical plate obtained in the step S2 through reflow soldering, and fixing the integrated inductor on a third PCB in an adhesive manner;
S4: de-paneling the third PCB into an integrated inductor connected with a vertical plate and a bottom assembly;
S5: preparing a second PCB board, and welding the semiconductor switch component and at least a part of the input capacitor to the top surface pad of the second PCB board;
S6: dispensing glue on the bottom surface of the second PCB, welding the integrated inductor connected with the vertical plate and the bottom assembly obtained in the step S4 through reflow soldering, and fixing the integrated inductor on the bottom surface of the second PCB in an adhesive manner;
S7: de-paneling the second PCB to obtain the VRM module.

31. A manufacturing method of the VRM module of claim 8, wherein the VRM module further comprises an input capacitor, an output capacitor and a rigid adapter plate, the rigid adapter plate is electrically connected with the vertical plate through the at least one flexible adapter plate, the rigid adapter plate is arranged between the magnetic core and the bottom assembly, and the rigid adapter plate is electrically connected with the bottom assembly,
wherein the manufacturing method comprises the following steps:
S1: preparing a rigid-flexible combined plate, wherein the rigid-flexible combined plate comprises a second PCB, a first PCB, a rigid adapter plate and a flexible adapter plate, and the first PCB is provided with a signal electric connecting piece and a metal shielding layer;
The integrated inductor is prepared, and an accommodating space for accommodating a rigid adapter plate is formed in the bottom of the integrated inductor;
S2: mounting a semiconductor switching device and an input capacitor on the top surface of the rigid-flexible bonding plate;
S3: an integrated inductor is attached to the bottom surface of the rigid-flexible combined plate, and an input capacitor and/or an output capacitor are attached to the bottom surface of the rigid-flexible combined plate;
S4: de-paneling the first PCB and the second PCB to obtain an integrated inductor connected with the top assembly;
S5: bending the rigid-flexible combined assembly to enable the vertical plate to be attached to a third side surface of the integrated inductor and enable the rigid adapter plate to be limited in the containing space;
S6: preparing a third PCB provided with an output capacitor, and welding an integrated inductor to a third PCB;
S7: de-paneling the third PCB to obtain the VRM module.

32. A manufacturing method of the VRM module of claim 8, wherein the VRM module further comprises an input capacitor, an output capacitor and a rigid adapter plate, the rigid adapter plate is electrically connected with the vertical plate through the at least one flexible adapter plate, the rigid adapter plate is arranged between the magnetic core and the bottom assembly, and the rigid adapter plate is electrically connected with the bottom assembly,
wherein the manufacturing method comprises the following steps:
S1: preparing a rigid-flexible combined plate, wherein the rigid-flexible combined plate comprises a second PCB, a first PCB, a rigid adapter plate and a flexible adapter plate, and the first PCB is provided with a signal electric connecting piece and a metal shielding layer;
The integrated inductor is prepared, and an accommodating space for accommodating a rigid adapter plate is formed in the bottom of the integrated inductor;
S2: mounting a semiconductor switch device and an input capacitor on the top surface of the rigid-flexible combination plate, and welding a bottom assembly on the rigid adapter plate;
S3: mounting an integrated inductor on the bottom surface of the rigid-flexible combined plate, and mounting an input capacitor and/or an output capacitor on the bottom surface of the rigid-flexible combined plate;
S4: de-paneling the first PCB and the second PCB to obtain an integrated inductor connected with the top assembly;
S5: arranging solder at the bottom of the bottom assembly or the integrated inductor, bending the rigid-flexible combined assembly to enable the vertical plate to be attached to the third side surface of the integrated inductor, limiting the rigid adapter plate in the accommodating space, and completing welding.
